(19) United States
(12) Patent Application Publication
(10) Pub. No.: US 2012/0193619 A1
(43) Pub. Date: Aug. 2, 2012

(54) ORGANIC ELECTROLUMINESCENT ELEMENT AND LIGHTING DEVICE USING SAME

(75) Inventors: Hideo Taka, Inagi-shi (JP); Yoshiyuki Suzuri, Yonezawa-shi (JP); Shinya Otsu, Hino-shi (JP); Hidekane Ozeki, Hino-shi (JP); Maiko Kondo, Hino-shi (JP)

(73) Assignee: KONICA MINOLTA HOLDINGS, INC., Tokyo (JP)

(21) Appl. No.: 13/500,805

(22) PCT Filed: Oct. 14, 2010
(86) PCT No.: PCT/JP2010/068028

§ 371 Date: Apr. 6, 2012

(30) Foreign Application Priority Data
Oct. 14, 2009 (JP) 2009-237174

(51) Int. Cl. H01L 51/00

(52) U.S. Cl. 257/40; 257/E51.018

(57) ABSTRACT

An organic EL element having a high productivity and a multi-unit structure is produced by using an organic EL material which can meet the demands of an increased area and high productivity, uses a high-speed process at atmospheric pressure, that is, the non-discharge type coating process, and which has a high process adaptability. An organic electroluminescent element is provided, between a plurality of light-emitting units, with a charge generating layer which generates a hole and an electron by applying an electric field, wherein the charge generating layer comprises one or more layers, at least one layer of which is formed by means of the non-discharge type solution coating process, and the plurality of light-emitting units are formed by means of the non-discharge type solution coating process.

### TECHNICAL FIELD

The present invention relates to an organic electroluminescent element which has achieved improved luminance and prolonged lifetime by having a structure of laminating a plurality of light emitting units through a charge generating layer, and the present invention also relates a lighting device using the same.

### BACKGROUND ART

An organic electroluminescent element (hereinafter, it is called as an organic EL element) is an all solid element composed of electrodes and films of organic materials having only about 0.1 μm thick located between the electrodes. Since it can emit light with comparatively low voltage of 2 V to 20 V, it is a technology which is expected as a flat display panel and a lighting device for the next generation.

By discovery of an organic EL element using phosphorescence luminescence, it becomes theoretically possible to achieve an emitting efficiency of about 4 times larger than the element fluorescence luminescence. Therefore, the material development for that has been started and research and development about the layer composition of the light emitting element has been carrying out all over the world. (Refer to, for example, M. A. Baldo et al., Nature, vol. 395, pages 151-154 (1998); M. A. Baldo et al., Nature, vol. 403, No. 17, pages 750-753 (2000); U.S. Pat. No. 6,097,147; and S. Lamansky et al., J. Am. Chem. Soc., vol. 123, page 4304 (2001).)

In recent years, with the increased attractiveness of an organic EL element used as a surface emitting light source, it is increased the need of satisfying all of properties of “high efficiency, high luminance and long lifetime” considering the function as a product application. Although many inventions to these requests have been accomplished until now, generally, the life span and the luminance of organic EL element are in the relation of trade-off, and high luminance and long life cannot be compatible (refer to, for example, “Device Physics, Material chemistry, and Device Application of Organic Light Emitting Diodes”, pages 257-267 (2007), CMC publication).

As a technical resolving means to this dilemma, there was reported an organic EL element having a multi-unit structure which carried out series connection of the organic EL device by the charge generating layer (refer to, for example, Japanese Patent Nos. 3884564 and 3933591).

On the other hand, there are known roughly two kinds of methods for the production method of organic EL element: vacuum deposition film forming method under vacuum condition (thy process); and coating and film forming method of a solution (coating process). The coating process has been attracted attention from the viewpoints of achieving large size production and high productivity. There was known an organic EL element having a multi-unit structure produced with a coating process (refer to, for example, Patent documents 1, 2 and 3). Further, with respect to a coating process of a charge generating layer (hereafter, it is called as “CGL”) there was known a production method using an ink-jet method (refer to, for example, Patent document 4).

When an emission unit is produced with a coating process (non-vacuum process) and CGL is produced with a vacuum deposition (vacuum process), a vacuum process and a non-vacuum process will be repeated, and it is unproductive on the contrary. Moreover, although it seems to have succeeded in escaping from a vacuum process by adopting a coating for forming the charge generating layer with an ink-jet method, it is difficult to say that the ink-jet method is a coating process suitable for producing a organic EL element aiming at illumination, and a large area display from the viewpoints of high-speed film forming, and the viscosity of a solution, and drying property. Moreover, in the organic EL element which uses phosphorescence luminescence, and in the organic EL element which has a multi-unit structure carried out series connection thereof, precise control of a charge transport function is needed and the homogeneity of coating thickness and the surface smoothness of membrane are strongly required. It is known that local irregularity and macroscopic undulation of membrane will affect directly the basic properties of organic EL element such a: luminous efficiency of an element, luminescence life span of an element, driving voltage, and unevenness of luminescence. Therefore, the organic EL element which has the multi-unit structure produced by the coating process satisfying of the requirements of large size and high productivity has not been attained yet.

### PRIOR TECHNOLOGICAL DOCUMENTS

### Patent Documents

Patent document 1: WO 2007/091548
Patent document 2: JP-A No. 2007-059848
Patent document 3: JP-A No. 2008-277193
Patent document 4: JP-A No. 2005-251529

### SUMMARY OF THE INVENTION

### Problems to be Solved by the Invention

An object of the present invention is to achieve production of an organic EL element having a multi-unit structure with improved yield rate and high productivity without deteriorating the basic properties of an organic EL element by using organic EL materials having high process aptitude with a high speed process under an atmospheric condition, namely, with a non-discharge type coating process enabling to satisfy the requirement of large size and high productivity.

### Means to Solve the Problems

An object of the present invention described above has been achieved by the following constitutions.

1. An organic electroluminescent element comprising, between a plurality of light emitting units, one or more charge generating layers which generate a hole and an electron by applying an electric field,

wherein the charge generating layer is composed of at least one or more layers, at least one of the charge generating layers is produced by a non-discharge type solution coating process, and the plurality of light emitting units are produced by the non-discharge type solution coating process.

2. The organic electroluminescent element of the aforesaid item 1,

wherein at least one of the charge generating layers is an inorganic compound layer composed of an inorganic compound.

3. The organic electroluminescent element of the aforesaid items 1 or 2,

wherein at least one of the charge generating layers is an organic compound layer composed of an organic compound.

4. The organic electroluminescent element of the aforesaid items 1 or 2,

wherein, at least one of the charge generating layers is an inorganic-organic mixed layer composed of an inorganic compound and an organic compound mixed with each other.

5. The organic electroluminescent element of the aforesaid item 2,

wherein the inorganic compound layer is composed of a metal, an inorganic oxide, or an inorganic salt.

6. The organic electroluminescent element of the aforesaid item 2,

wherein the inorganic compound layer is an inorganic oxide film produced by a sol-gel method or a coating method using an inorganic oxide particle dispersion liquid.

7. The organic electroluminescent element of the aforesaid item 2,

wherein the inorganic compound layer is a metal film produced by a coating method using a metal particle dispersion liquid.

8. The organic electroluminescent element of the aforesaid item 2,

wherein the inorganic compound layer is treated with at least one of heating, light irradiation, microwave exposure and plasma treatment during or after the coating process.

9. The organic electroluminescent element of the aforesaid item 2,

wherein the inorganic compound layer contains an inorganic oxide selected from the group consisting of titanium oxide, zirconium oxide, tin oxide, zinc oxide and ITO.

10. The organic electroluminescent element of the aforesaid item 2,

wherein the inorganic compound layer contains Ag, Al, Cu or Ni.

11. The organic electroluminescent element of the aforesaid item 3,

wherein the organic compound in the organic compound layer contains an organic salt

12. The organic electroluminescent element of the aforesaid item 3,

wherein the organic compound in the organic compound layer contains a metal complex.

13. The organic electroluminescent element of the aforesaid item 3,

wherein the organic compound in the organic compound layer contains a nano carbon material.

14. The organic electroluminescent element of the aforesaid item 13,

wherein the nano carbon material is a fullerene derivative or a carbon nano tube derivative.

15. The organic electroluminescent element of the aforesaid item 3,

wherein the organic compound layer is a donor-acceptor mixed layer containing at least an organic donor compound and an organic acceptor compound mixed with each other.

16. The organic electroluminescent element of the aforesaid item 15,

wherein the organic donor compound is at least one selected from the group consisting of a phthalocyanine derivative, a porphyrin derivative, a tetrathiafulvalene (TTF) derivative, a tetrathiatetracene (TTT) derivative, a metallocene derivative, a thiophene derivative, an imidazole radical derivative, a condensed multi-ring aromatic hydrocarbon, an arylamine derivative, an azine derivative and a transition metal complex salt derivative.

17. The organic electroluminescent element of the aforesaid item 15,

wherein the organic acceptor compound is at least one selected from the group consisting of a quinone derivative, a polycyano derivative, a tetracyanoquinodimethane derivative, a dicyanoquinonediimine derivative, a polynitro derivative, a transition metal complex salt derivative, a phenanthroline derivative, an azacarbazole derivative, a quinolinol metal complex derivative, a pyridine derivative, an aromatic heterocyclic derivative, a fullerene derivative, a phthalocyanine derivative, a porphyrin derivative, a fluorinated heterocyclic derivative and a fluorinated aromatic hydrocarbon ring derivative

18. The organic electroluminescent element of the aforesaid item 3,

wherein the organic compound layer contains a compound which has an organic donor compound and an organic acceptor compound combined with each other through a covalent bond or a coordination bond,

the organic donor compound is at least one selected from the group consisting of a quinone derivative, a polycyano derivative, a tetracyanoquinodimethane derivative, a dicyanoquinonediimine derivative, a polynitro derivative, a transition metal complex salt derivative, a phenanthroline derivative, an azacarbazole derivative, a quinolinol metal complex derivative, a pyridine derivative, an aromatic heterocyclic derivative, a fullerene derivative, a phthalocyanine derivative, a porphyrin derivative, a fluorinated heterocyclic derivative and a fluorinated aromatic hydrocarbon ring derivative, and

the organic acceptor compound is at least one selected from the group consisting of a quinone derivative, a polycyano derivative, a tetracyanoquinodimethane derivative, a dicyanoquinonediimine derivative, a polynitro derivative, a transition metal complex salt derivative, a phenanthroline derivative, an azacarbazole derivative, a quinolinol metal complex derivative, a pyridine derivative, an aromatic heterocyclic derivative, a fullerene derivative, a phthalocyanine derivative, a porphyrin derivative, a fluorinated heterocyclic derivative and a fluorinated aromatic hydrocarbon ring derivative

19. The organic electroluminescent element of the aforesaid item 4,

wherein the inorganic compound composing the inorganic-organic mixed layer is a metal, an inorganic oxide or an inorganic salt.

20. The organic electroluminescent element of the aforesaid item 19,

wherein the metal is Ag, Al, Cu or Ni.

21. The organic electroluminescent element of the aforesaid item 19,

wherein the inorganic oxide is titanium oxide, zirconium oxide, tin oxide, zinc oxide or ITO.

22. The organic electroluminescent element of the aforesaid item 19,

wherein the inorganic salt is a metal azide compound, an alkali metal salt or an alkali earth metal salt

23. The organic electroluminescent element of the aforesaid item 19,

wherein the organic compound composing the inorganic-organic mixed layer is one selected from the group consisting of an organic salt, a metal complex, a nano carbon material, an organic donor compound, an organic acceptor compound and a compound which has the organic donor compound and the organic acceptor compound combined with each other through a covalent bond or a coordination bond

24. The organic electroluminescent element of the aforesaid item 4,

wherein the inorganic-organic mixed layer is formed by a coating method using a mixture liquid containing:

at least one selected from the group consisting of a metal particle dispersion liquid, an inorganic oxide particle dispersion liquid, an inorganic salt particle dispersion liquid and an inorganic salt solution; and

at least one of an organic compound particle dispersion liquid and an organic compound solution.

25. The organic electroluminescent element of the aforesaid item 4,

wherein the inorganic-organic mixed layer is treated with at least one of heating, light irradiation, microwave exposure and plasma treatment during or after the coating process.

26. The organic electroluminescent element of any one of the aforesaid items 1 to 25,

wherein the light emitting units each contain one or more organic electroluminescent layers, and at least one of the organic electroluminescent layers or at least one of the charge generating layers is composed of a polymer, an organic complex, or an inorganic oxide each having a high degree of covalent bond, hydrogen bond, or coordination bond therebetween.

27. The organic electroluminescent element of the aforesaid item 26,

wherein the high degree of covalent bond, hydrogen bond, or coordination bond between the polymer, the organic complex and the inorganic oxide is formed by at least one treatment of heating, light irradiation, electromagnetic wave exposure, electric filed application and plasma treatment during or after the coating process of a low molecular weight material to form a high molecular compound.

28. The organic electroluminescent element of the aforesaid item 26,

wherein among the one or more organic electroluminescent layers composing the light emitting units, the organic electroluminescent layer located under the charge generating layer is composed of the polymer, the organic complex, or the inorganic oxide each having a high degree of covalent bond, hydrogen bond, or coordination bond therebetween.

29. The organic electroluminescent element of the aforesaid item 28,

wherein among the one or more organic electroluminescent layers composing the light emitting units, the organic electroluminescent layer located under the charge generating layer is an electron transport layer.

30. The organic electroluminescent element of the aforesaid item 29,

wherein the electron transport layer is formed by the method comprising the steps of:

forming a layer of an organic compound with a low molecular weight and having a vinyl group, an epoxy group or an oxetane group with a coating process; and

subjecting the formed organic compound layer to at least one treatment of heating, light irradiation, electromagnetic wave exposure, electric filed application and plasma treatment during or after the coating process to form a high molecular compound by forming a covalent bond between molecules of the organic compound with a low molecular weight

31. The organic electroluminescent element of any one of the aforesaid items 1 to 29,

wherein the light emitting units emit a phosphorescent light.

32. A lighting device comprising the organic electroluminescent element of any one of the aforesaid items 1 to 29.

### Effects of the Invention

In the present invention, by producing a CGL with a non-discharge type coating process, it has been succeeded in reducing luminescence unevenness and thickness fluctuations, and suppressing luminescence deterioration in the early stage of the driving and voltage rise after prolonged driving compared with the product produced with a conventional technology using a discharge type coating process (an ink-jet method).

As a result, it has become possible to increase the non-vacuum process to a maximum degree, which is practical and exhibits a high production efficiency, by the present invention. Consequently, compared with the dry process which is now a main stream for production of an organic EL element, it has become possible to improve the production efficiency at a great rate. Moreover, as a further effect, with increase of the number of coating process, it could cover the minute dusts on the substrate. This enables to decrease the defects of the element and to achieve low cost by the improvement in the yield at the time of manufacturing.

According to the above effects, it has been achieved to provide an organic EL device produced by the production method of the organic EL element with high cost performance (improved production efficiency, low cost and improved production yield) by the present invention.

### BRIEF DESCRIPTION OF THE DRAWINGS

FIG. 1 is a schematic drawing to show an example of a display device constituted of an organic EL element.

FIG. 2 is a schematic drawing of display section A.

FIG. 3 is an equivalent circuit diagram of an image pixel.

FIG. 4 is a schematic drawing of a full color display device according to a passive matrix mode.

FIG. 5 is a schematic drawing of a lighting device.

FIG. 6 is a cross-sectional drawing of a lighting device.

FIG. 7 is a schematic structural drawing of a full color organic EL display device.

### EMBODIMENTS TO CARRYOUT THE INVENTION

In the organic EL element material of the present invention, that is, in the organic EL element incorporating, between a plurality of light emitting units, a charge generating layer which generate a hole and an electron by applying an electric field, at least one of charge generating layers is formed with a non-discharge type solution coating process. As a result, it can provide a production method of an organic EL element enabling to reduce luminescence unevenness and thickness fluctuations and suppressing luminescence deterioration in the early stage of the driving and voltage rise after prolonged driving. This production method can improve production efficiency and production yield. In addition, it can provide an organic EL element produced by the aforesaid production method, a display device and a lighting device each provided with the aforesaid organic EL element.

The non-discharge type solution coating process in the present invention indicates a method which is not accompanied by a flight and discharge of minute droplets of a coating solution. Namely, it refers to a method which does not include an ink-jet method. Preferably, it indicates a slit coating method, a cast method or a printing method. Most preferably cited non-discharge type solution coating process is a slit coating method.

Hereafter, the details of each structural element concerning the present invention are described one by one.

### <<Constituting Layers of Organic EL Element and Organic Compound Layer>>

The constituting layers of the organic EL element of the present invention are explained. In the present invention, preferred specific examples of the constituting layer of the organic EL element are described below, but the present invention is not limited to them.

(i) Anode/light emitting unit 1/CGL/light emitting unit 2/cathode.
(ii) Anode/light emitting unit 1/CGL 1/light emitting unit 2/CGL 2/cathode.
(iii) Anode/light emitting unit 1/CGL 1/[light emitting unit n−1/CGL n−1]ₙ₋₁/light emitting unit n/cathode.

Here, “light emitting unit 1” indicates a light emitting unit located at the most nearest position to the anode (the first), and “CGL 1” indicates a charge generating layer located at the most nearest position to the anode (the first). “Light emitting unit n−1” indicates an (n−1)th light emitting unit among (n−1) light emitting units. “Light emitting unit n” indicates an (n) th light emitting unit among (n) light emitting units. “CGL n−1” indicates an (n−1)th charge generating layer among (n−1) charge generating layers. “n” is an integer of 1 to 100. Each of the light emitting units may be the same or different with each other. When there are plural CGLs, each of the CGLs may be the same or different with each other.

The light emitting units of the organic EL element of the present invention and their layer compositions will now be described. The light emitting units of the present invention are composed of organic compound layers (organic EL layers) and preferred embodiments thereof will be described below, however, the present invention is not limited to these.

(i) hole transport layer/light emitting layer/electron transport layer
(ii) hole transport layer/light emitting layer/hole blocking layer/electron transport layer
(iii) hole transport layer/light emitting layer/hole blocking layer/electron transport layer/cathode buffer layer
(iv) anode buffer layer/hole transport layer/light emitting layer/hole blocking layer/electron transport layer/cathode buffer layer
(v) hole transport layer/light emitting layer 1/light emitting layer 2/electron transport layer
(vi) hole transport layer/light emitting layer 1/light emitting layer 2/hole blocking layer/electron transport layer
(vii) hole transport layer/light emitting layer 1/light emitting layer 2/hole blocking layer/electron transport layer/cathode buffer layer
(viii) anode buffer layer/hole transport layer/light emitting layer 1/light emitting layer 2/hole blocking layer/electron transport layer/cathode buffer layer
(ix) hole transport layer/light emitting layer 1/light emitting layer 2/light emitting layer 3/electron transport layer
(x) hole transport layer/light emitting layer 1/light emitting layer 2/light emitting layer 3/hole blocking layer/electron transport layer
(xi) hole transport layer/light emitting layer 1/light emitting layer 2/light emitting layer 3/hole blocking layer/electron transport layer/cathode buffer layer
(xii) anode buffer layer/hole transport layer/light emitting layer 1/light emitting layer 2/light emitting layer 3/hole blocking layer/electron transport layer/cathode buffer layer

### <<Organic Compound Layers>>

The organic compound layers relating to the present invention will be described.

It is preferable that the organic EL element of the present invention contains a plurality of organic compound layers as constituting layers. As the aforesaid organic compound layers, there can be cited, for example, a hole transport layer, a light emitting layer, a hole blocking layer and an electron transport layer among the above-described layer constitution. Further, when an organic compound is incorporated in a constituting layer of an organic EL element such as a hole injection layer or an electron injection layer, this layer is defined as an organic compound layer relating to the present invention.

Moreover, when an organic compound is incorporated in an anode buffer layer or a cathode buffer layer, the anode buffer layer and the cathode buffer layer each are also considered to form an organic compound layer.

In addition, the aforesaid organic compound layer includes a layer incorporating “an organic EL element material which can be used in a constituting layer of an organic EL element”.

It is preferable that the organic EL element of the present invention contains a white light emitting layer. And it is preferable that a display device and a light device are provided with this organic EL element. In the organic EL element of the present invention, all of the light emitting units existing in the organic EL element of the present invention may have a white light emitting layer, or white light may be achieved by the combination of the emission units each exhibiting a different luminescent color. Further, when one light emitting unit exhibits a white light, it may form a white light emitting layer by laminating one or more light emitting layers. Further, an intermediate layer may be formed between the light emitting layers.

Each layer which constitutes the organic EL element of the present invention will be described.

### <<Charge Generating Layer (CGL)>>

### <Constituting Layer of Charge Generating Layer>

The layer constitution of a charge generating layer of the present invention will be described. The layers shown in the following items (1) to (10) can be used as a charge generating layer of the present invention singly or by combining arbitrarily two or more.

In the present invention, a charge generating layer is formed at least one or more layer.

Although it is desirable that a charge generating layer has higher conductivity than a semiconductor, it is not limited to that.

A charge generating layer is a layer which generates a hole and an electron in an electric field, and the charge generating interface may be in the charge generating layer, or in the interface formed with other layer adjacent to the charge generating layer, or may be around the interface.

For example, when the charge generating layer is composed of one layer, the place of generating a hole and an electron may be in the charge generating layer or may be in the interface adjacent to the charge generating layer.

In the present invention, it is more preferable that the charge generating layer is composed of two or more layers, and it is still more preferable that the charge generating layer contains one of or both of p-type semiconductor layer and n-type semiconductor layer.

Although a charge generating layer may function as a hole injection layer, a hole transport layer, an electron transport layer, and an electron injection layer, and it can be uses as the same layer as described above, a charge generation layer refers to a layer where a hole and an electron are generated or a layer which has an interface with an organic electroluminescence layer which connects electrically two or more light emitting units in series.

The composition of the charge generating layer in the present invention is as follows.

1. Light emitting unit/bipolar layer (single layer)/light emitting unit
2. Light emitting unit/n-type layer/p-type layer/light emitting unit.
3. Light emitting unit/n-type layer/intermediate layer/p-type layer/light emitting unit.

The above-mentioned bipolar layer is a layer which can generate and convey a hole and an electron inside the layer by an external electric field.

An n-type layer is a transport layer in which electrons are a major carrier, and it is preferable to have higher conductivity than a semiconductor.

An p-type layer is a transport layer in which holes are a major carrier, and it is preferable to have higher conductivity than a semiconductor.

An intermediate layer may be provided when it is required in order to improve charge generating ability or long-term stability. Examples thereof include: a diffusion prevention layer of an n-type layer and a p-type layer, a reaction suppression layer between an n-type layer and a p-type layer, and a level adjustment layer which adjusts the electric charge level of an n-type layer and a p-type layer.

It may have further a bipolar layer, a p-type layer, and an n-type layer between a light emitting unit and a charge generating layer.

These layers may be provided when required in order to pour the generated electric charge into a light emitting unit promptly. In the preset invention, these layers are included in a light emitting unit, and these are not regarded as a charge generating layer.

Examples of a bipolar layer, a p-type layer, and an n-type layer as a specific charge generating layer are described below, however, it is not limited to these.

(1) Single electron transport material layer
(2) Mixed layer of plural sorts of electron transport materials
(3) Mixed layer of: an electron transport material; and an alkali or alkali earth metal salt (or a precursor of alkali or alkali earth metal)
(4) N-type semiconductor layer (an organic material, an inorganic material)
(5) N-type conductive polymer layer
(6) Single hole injection and transport material layer
(7) Mixed layer of plural sorts of hole injection and transport materials
(8) Mixed layer of a hole transport material and a metal oxide
(9) P-type semiconductor layer
(10) P-type conductive polymer layer

As above-mentioned, in the present invention, a charge generation layer indicates a layer which is formed at least one or more layers and has a function to pour a hole in the direction of a cathode of an element, and to pour an electron in the direction of an anode at the time of voltage impression.

Moreover, when a charge generating layer is formed from two or more layers, the layer interface of the charge generation layer formed from two or more layers may have an interface (a hetero interface, a homo interface), and may form multi dimensional interfaces, such as bulk hetero structure, island structure and phase separation.

Each of the two layers has preferably a thickness of 1 nm to 100 nm, and more preferably a thickness of 10 nm to 50 nm.

As for the light transmittance of the charge generating layer of the present invention, it is preferable to have high transmissivity to the light emitted from the light emitting layer. In order to fully take out a light and to obtain sufficient luminance, it is further preferable to has 50% or more transmissivity at the wave length of 550 nm, and more preferably to have 80% or more transmissivity.

As materials which constitutes the charge generation layer formed from two or more layers of the present invention as mentioned above, it can use an organic compound and an inorganic compound mentioned later singly or by combining two or more sorts.

As an organic compound of the present invention, it can be cited: a nano carbon material, an organometallic complex compound which functions as an organic semiconductor material (an organic acceptor, an organic donor), an organic salt, an aromatic hydrocarbon compound and its derivative, a hetero aromatic compound and its derivative.

As an inorganic compound of the present invention, it can be cited: a metal, an inorganic oxide, and an inorganic salt.

Although specific examples are shown below as each material which constitutes the charge generating layer of the present invention, the present invention is not limited to these.

### <Nano Carbon Material>

A nano carbon material indicates a carbon material having a particle size of 1 nm to 500 nm. Representative examples thereof are: a carbon nanotube, a carbon nanofiber, fullerene and its derivative, carbon nanocoil, carbon onion fullerene and its derivative, diamond, diamond type carbon and graphite.

Especially, fullerene and a fullerene derivative can be used suitably. The fullerene in the present invention indicates a closed polyhedral cage molecule having 20 or more carbon atoms with 12 pieces of pentagon and (n/2−10) pieces of hexagon, and the derivative thereof is called as a fullerene derivative. The number of carbon atoms is not limited in particular as long as it is 20 or more, however, preferably, the number of carbon atoms is 60, 70 or 84. Although specific examples of fullerene and a fullerene derivative are shown below, the present invention is not limited to these.

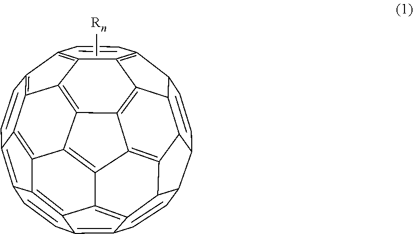

In fullerene derivative (1), R represents a hydrogen atom or a substituent, and “n” represents an integer of 1 to 12.

Preferable groups represented by R are as follows: an alkyl group (for example, a methyl group, an ethyl group, i-propyl group, a hydroxyethyl group, a methoxymethyl group, a trifluoromethyl group, t-butyl group, a cyclopentyl group, a cyclohexyl group, and a benzyl group), an aryl groups (for example, a phenyl group, a naphthyl group, p-tolyl group, and p-chlorophenyl group), a hetero aryl groups (for example, a pyrrole group, an imidazolyl group, a pyrazolyl group, a pyridyl group, a benzimidazolyl group, a benzothiazolyl group, a benzoxazolyl group, a triazolyl group, an oxadiazolyl group, a thiadiazolyl group, a thienyl group, and a carbazolyl group), an alkenyl group (for example, a vinyl group, a propenyl group, and a styryl group), an alkynyl group (for example, ethynyl group), an alkyloxy group (for example, a methoxy group, an ethoxy group, i-propoxy group, and a butoxy group), an aryloxy group (for example, a phenoxy group), an amino group, an alkylamino groups (for example, a dimethylamino group, a diethylamino group, and an ethyl methylamino group), an arylamino group (for example, an anilino group, and a diphenylamino group), a cyano group, a nitro group, a non-aromatic heterocyclic group (for example, a pyrrolidyl group, a pyrazolyl group, and an imidazolyl group), and a silyl group (for example, a trimethyl silyl group, t-butyldimethyl silyl group, a dimethylphenyl silyl group, and a triphenyl silyl group). These groups may further have a substituent

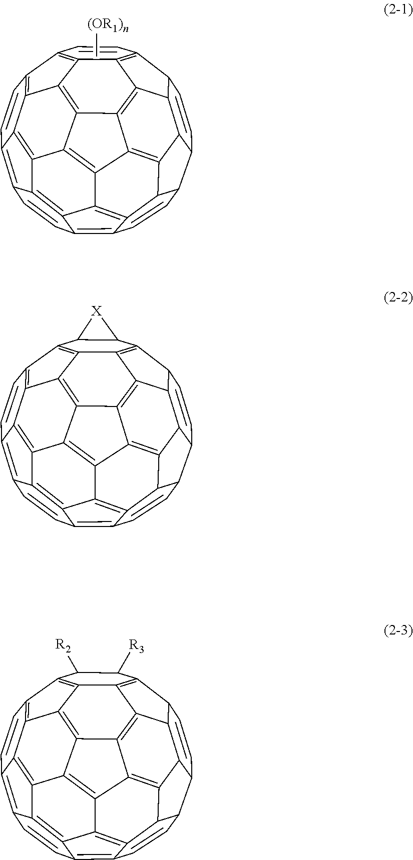

In fullerene derivatives (2-1) to (2-3), R₁, R₂ and R₃ each represents a hydrogen atom or a substituent which is the same as the aforesaid R, X represents a divalent group such as —(CR₁R2)ₘ—, or —CH₂—NR₁—CH₂—. Here, R₁, R₂ and R₃ each represents a hydrogen atom or a substituent, “n” represents an integer of 1 to 12, and “m” represents an integer of 1 to 4. The substituent indicates the same groups as represented by the aforesaid R.

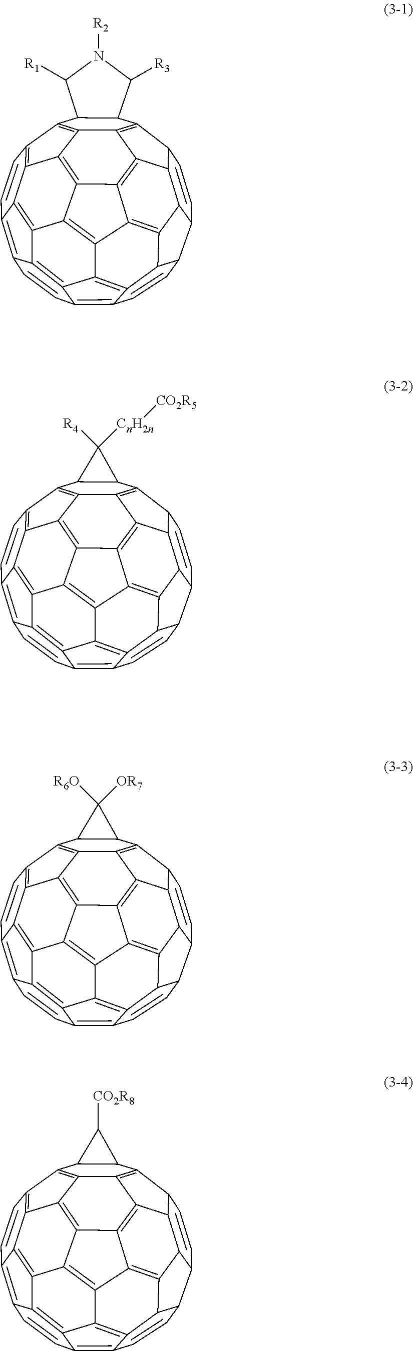

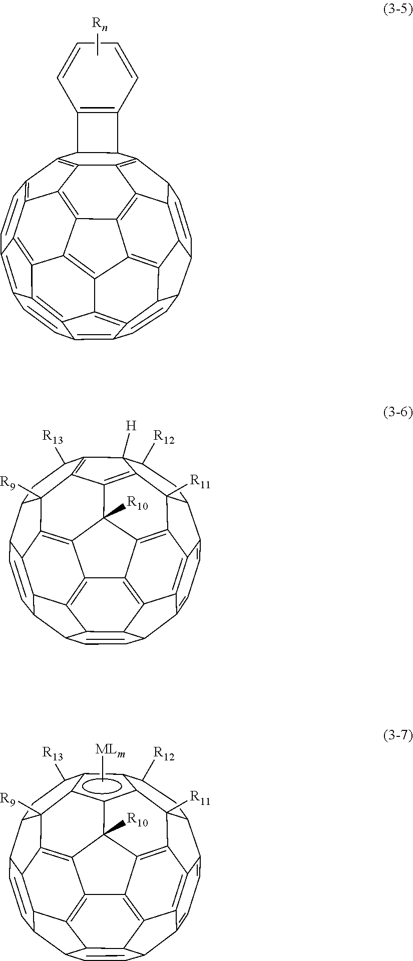

In fullerene derivatives (3-1) to (3-7), R, R₁, R₂, R₃, R₄, R₅, R₆, R₇, R₈, and R₉ to R₁₃ each represents a hydrogen atom or a substituent, the substituent represented by R, R₁, and R₂ are the same as represented by the aforesaid R, “n” represents an integer of 1 to 4. M represents a transition metal atom, and “L” represents a ligand which coordinates to this metal atom. The ligand is not limited in particular as long as it is a molecule or an ion which forms a ligand in the conventional metal complex. Further, “m” represents an integer of 1 to 5.

Although examples of fullerene and a fullerene derivative are shown below, the present invention is not limited to these.

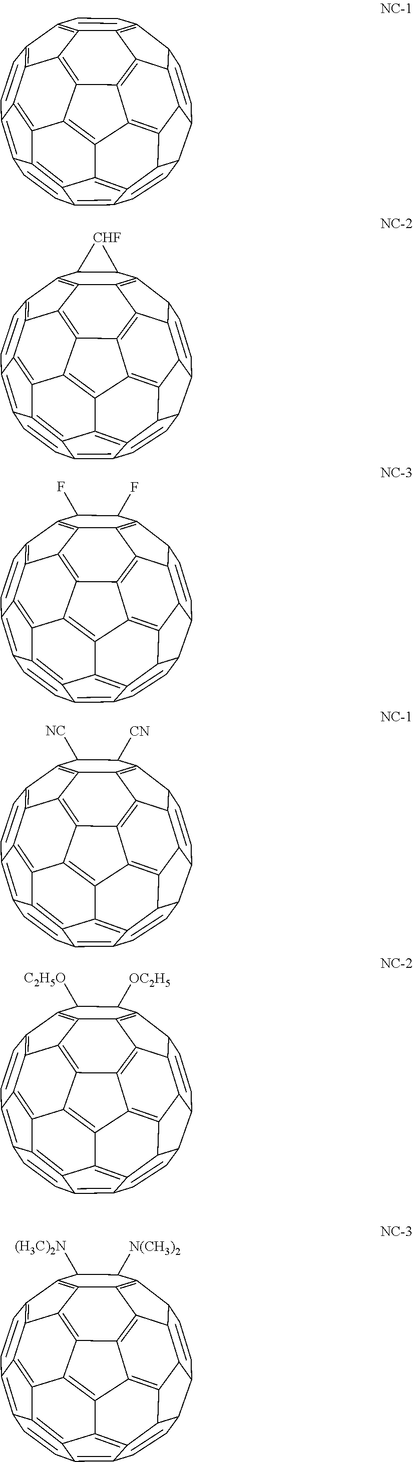

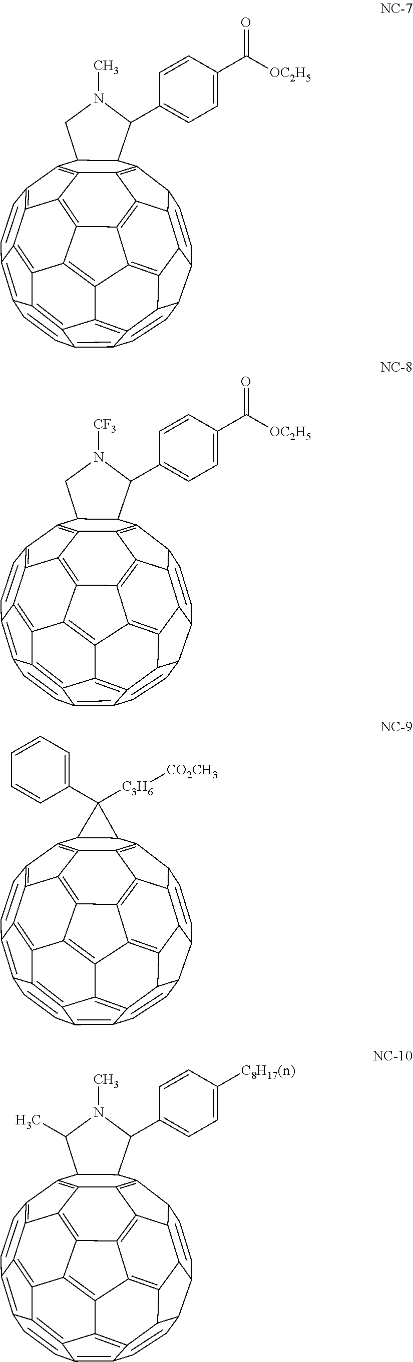

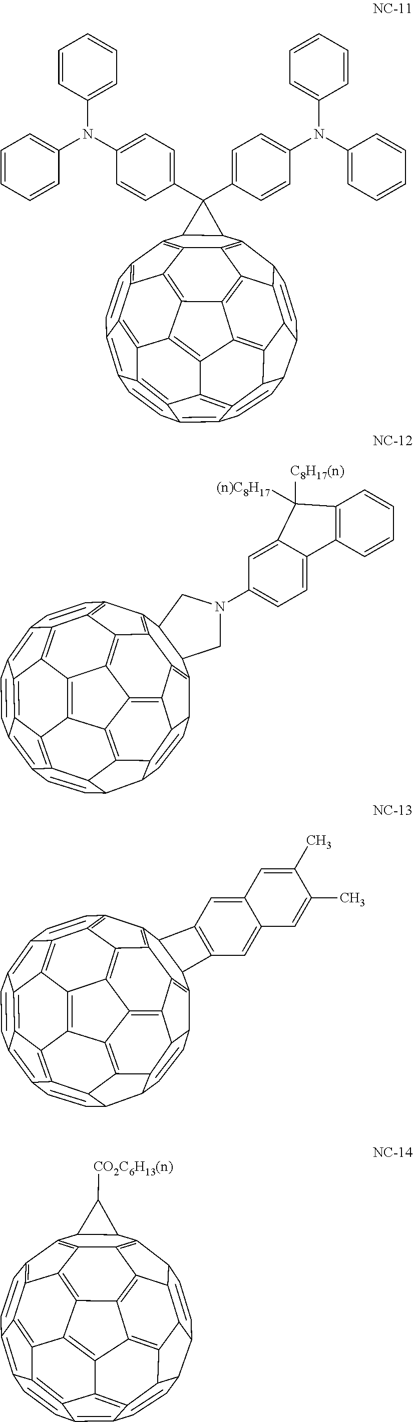

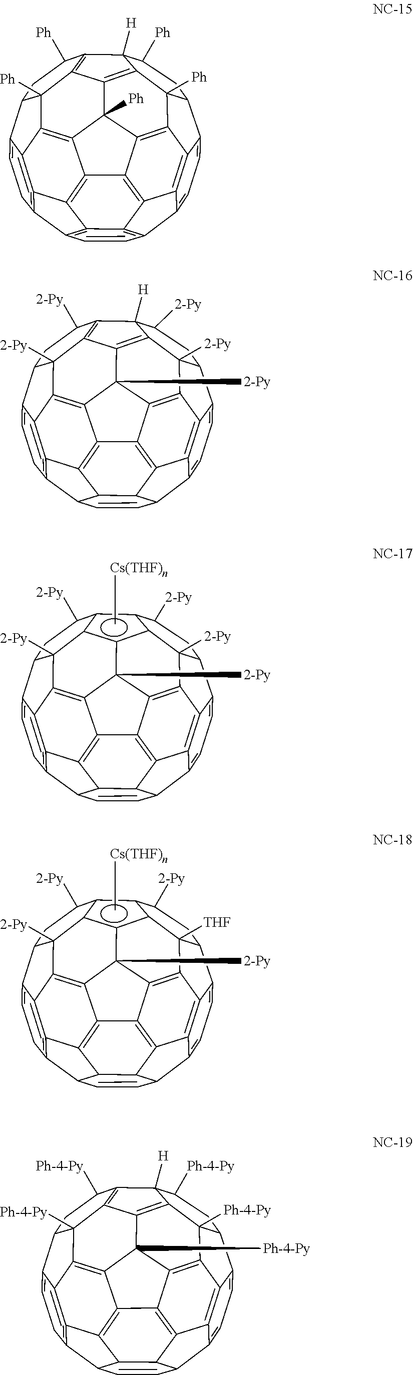

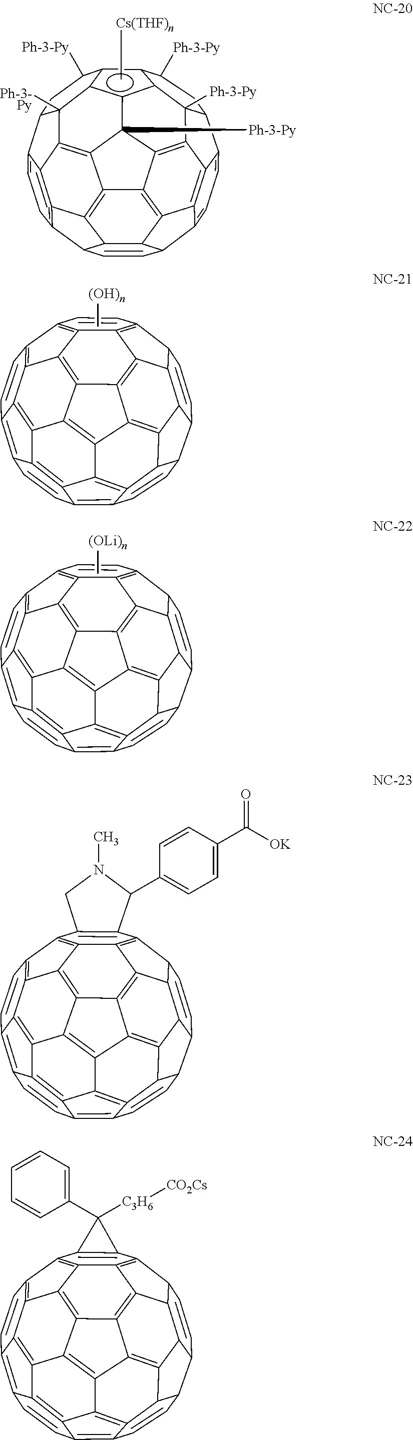

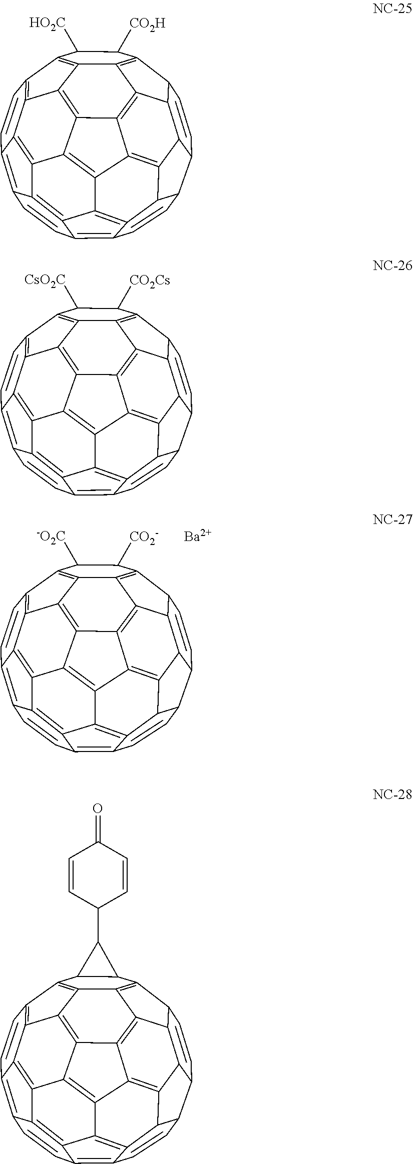

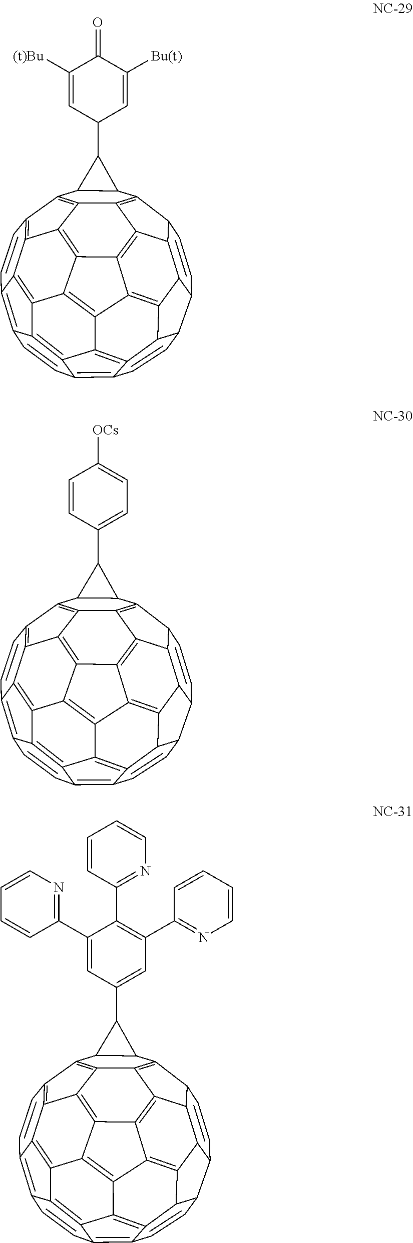

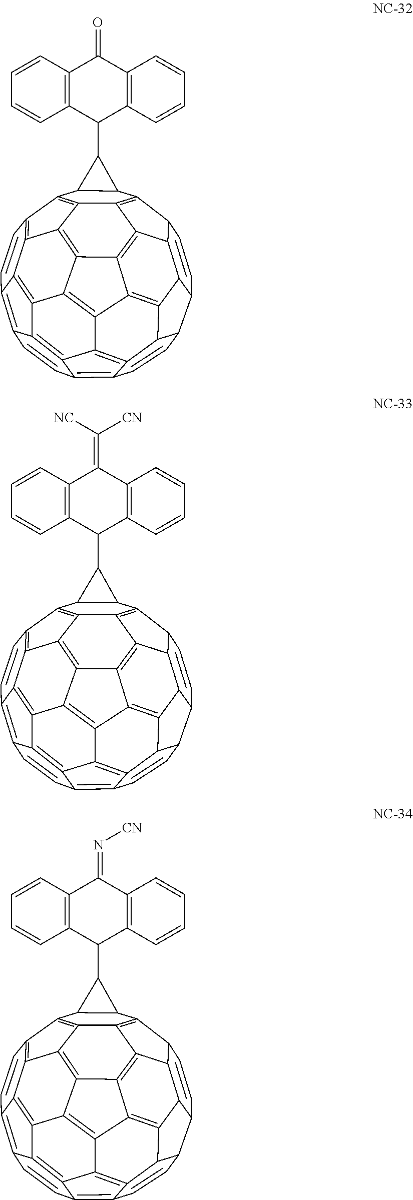

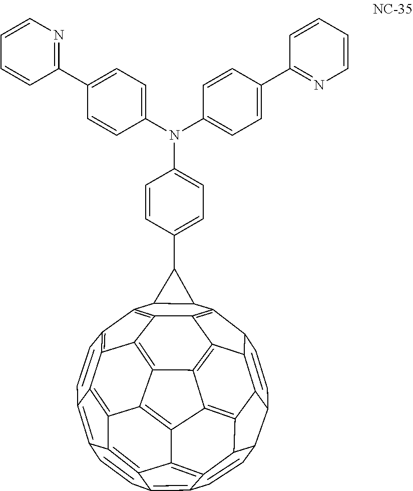

### <Organic Semiconductor Material>

### (Organic Donor)

Examples of an organic donor include: a phthalocyanine derivative, a porphyrin derivative, a tetrathiafulvalene (TTF) derivative, a tetrathiatetracene (TTT) derivative, a metallocene derivative, a thiophene derivative, an imidazole radical derivative, a condensed multi-ring aromatic hydrocarbon, an arylamine derivative, an azine derivative, a transition metal complex salt derivative, a compound represented by Formula (N) described later (wherein, a, b, c, d, and e each represent —NRₙ₁— or —CR_{c1}R_{c2}—; E represents N, or —CR_{c3}—; M represents Mo or W; and “n” and “m” each represent an integer of 0 to 5) and a triarylamine derivative.

(1) Examples of a phthalocyanine derivative are compounds represented by the following Formula (A). Here, X₁, X₂, X₃ and X₄ each respectively represent N or —CR, and R represents a hydrogen atom, an alkyl group, an alkoxy group, an aryl group, or a heteroaryl group. M represents H₂ or a metal atom. The phthalocyanine derivative may have a substituent on the phthalocyanine ring. M is preferably H₂, Co, Fe, Mg, Li₂, Ru, Zn, Cu, Ni, Na₂, Cs₂, or Sb.

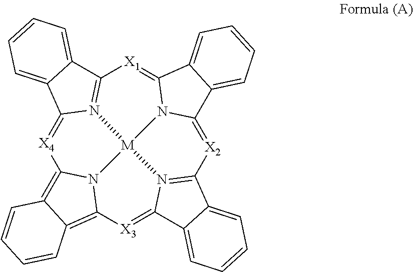

Although specific examples of a phthalocyanine derivative are shown below, the present invention is not limited to these.

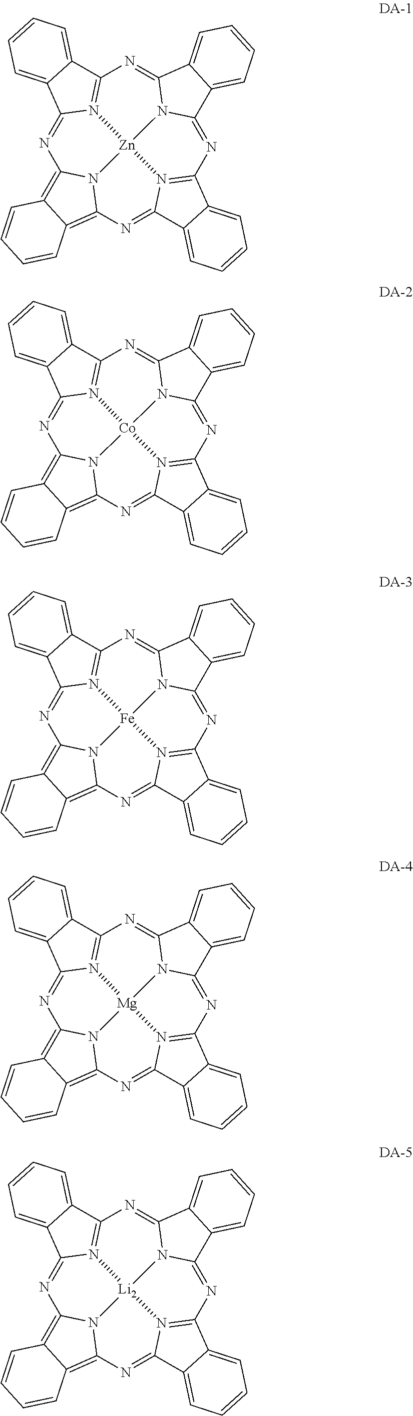

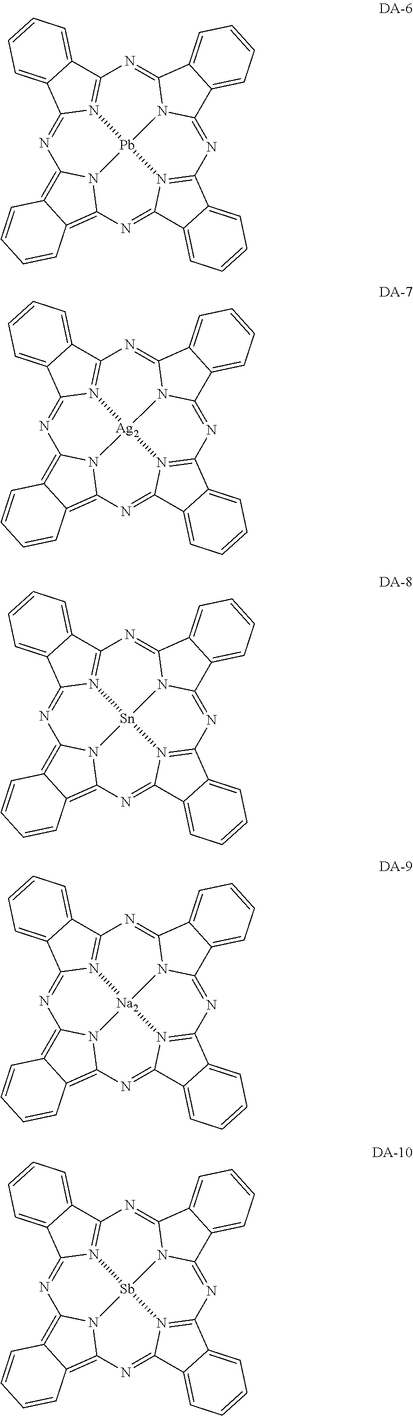

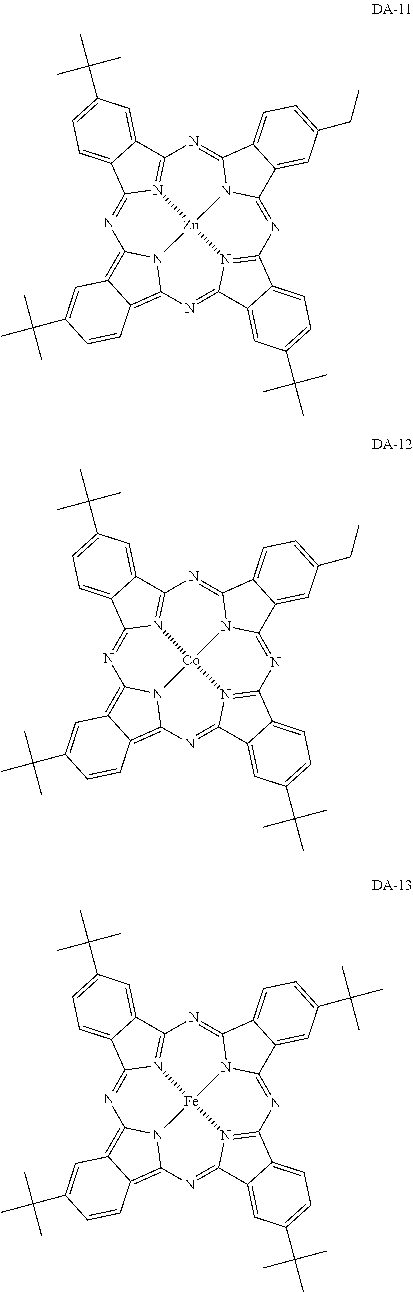

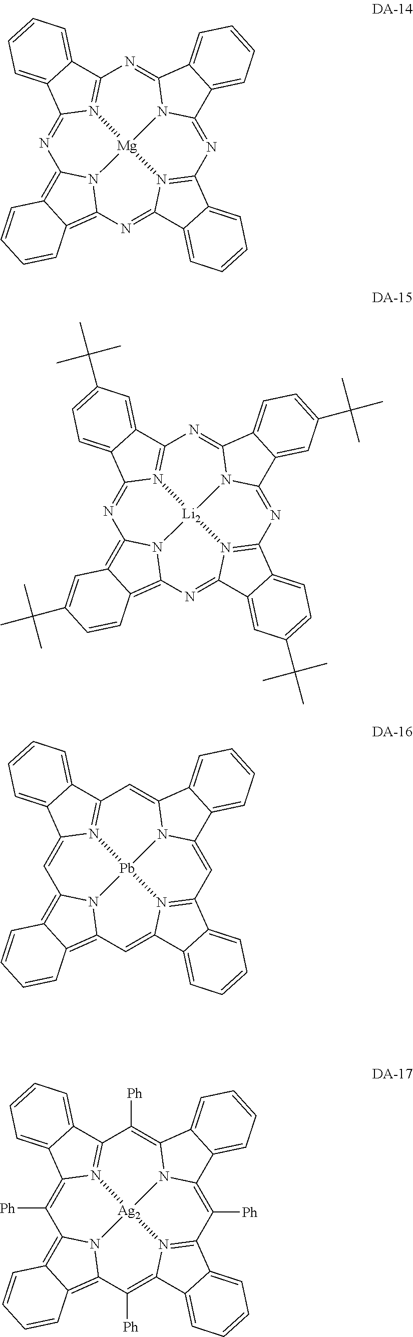

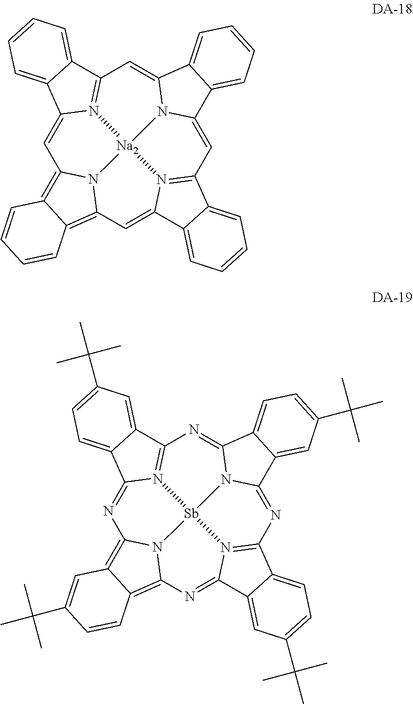

(2) Examples of a porphyrin derivative are compounds represented by the following Formula (B). Here, X₁, X₂, X₃ and X₄ each respectively represent N or —CR, and R represents a hydrogen atom, an alkyl group, an alkoxy group, an aryl group, or a heteroaryl group. M represents H₂ or a metal atom. The porphyrin derivative may have a substituent on the porphyrin ring. M is preferably H₂, Co, Fe, Mg, Li₂, Ru, Zn, Cu, Ni, Na₂, Cs₂, or Sb.

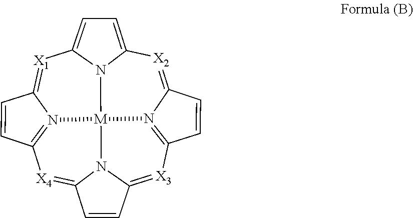

Although specific examples of a porphiline derivative are shown below, the present invention is not limited to these.

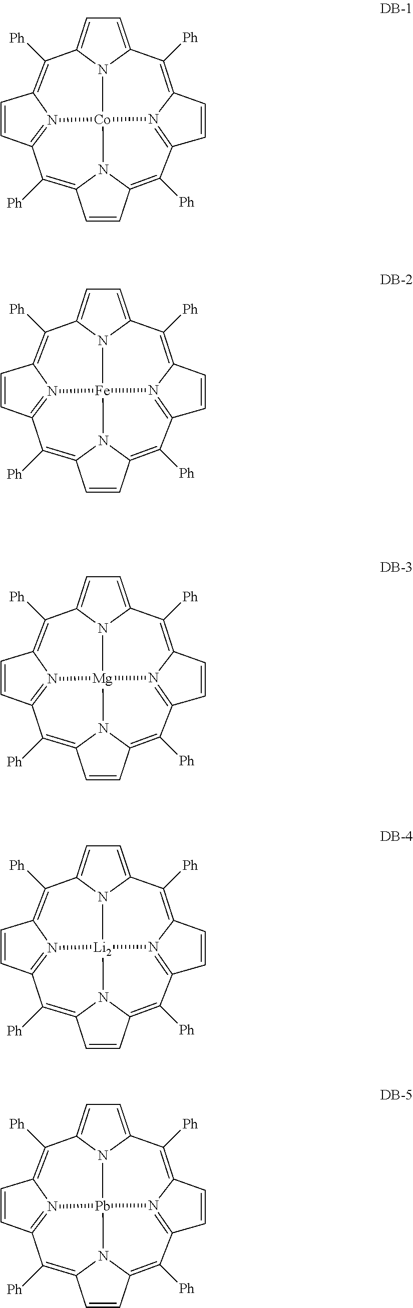

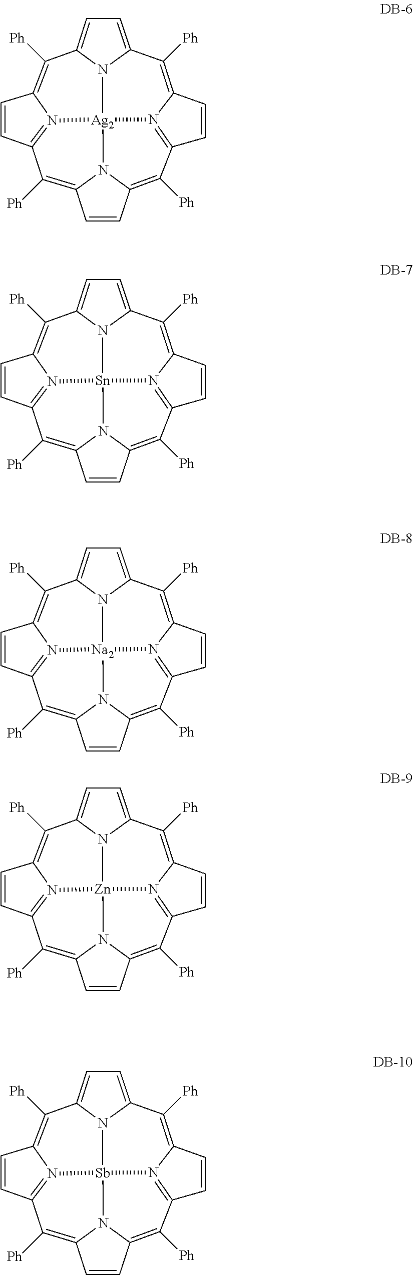

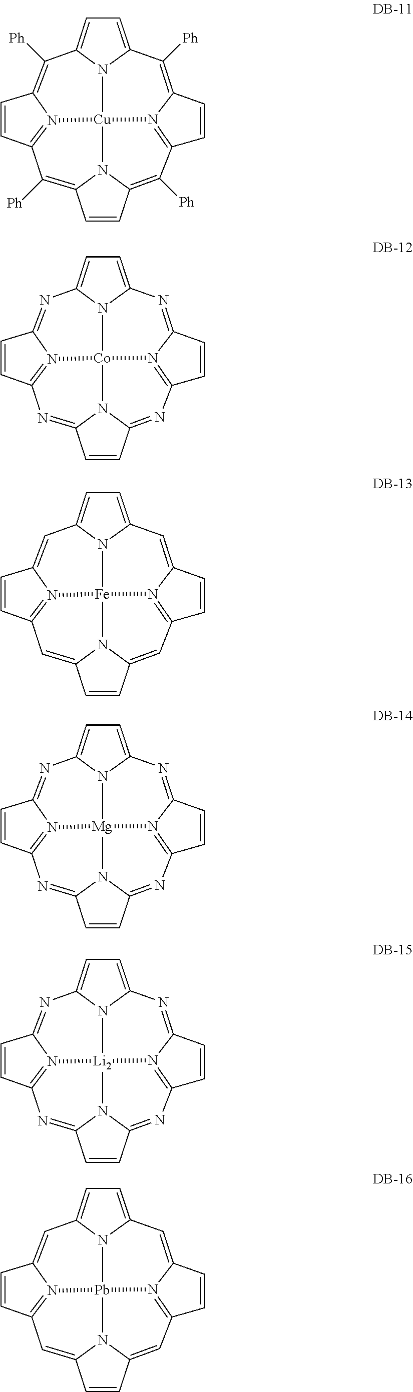

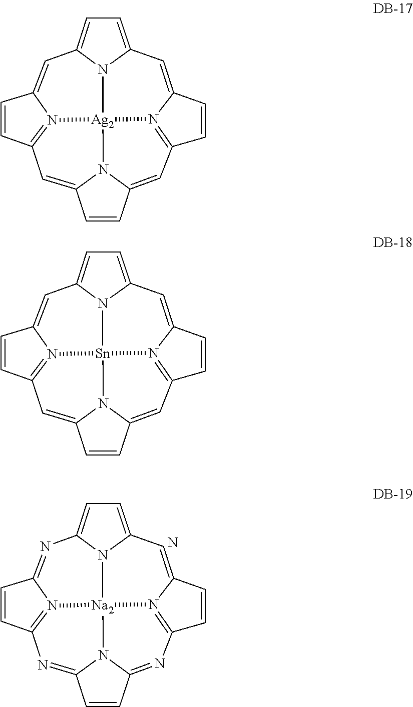

(3) Examples of a tetrathiafulvalene (TTF) derivative are compounds represented by Formula (C). Here, X₁, X₂, X₃ and X₄ each respectively represent S, Se, or Te; R₁, R₂, R₃ and R₄ each respectively represent a hydrogen atom or a substituent, R₁ and R₂, and R₃ and R₄ each pair may be joined to form a ring.

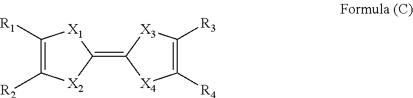

Although specific examples of a TTF derivative represented by Formula (C) are shown below, the present invention is not limited to these.

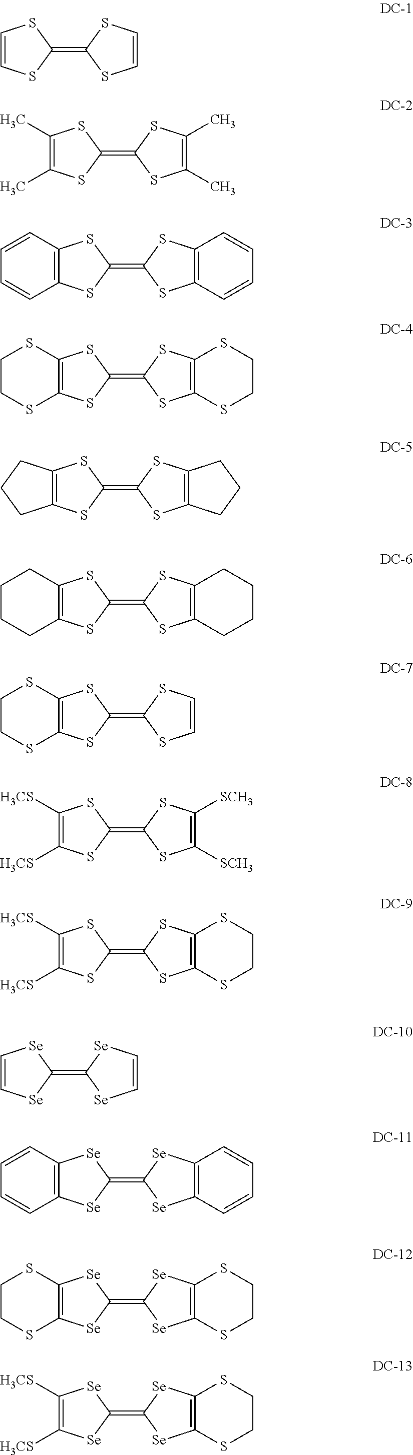

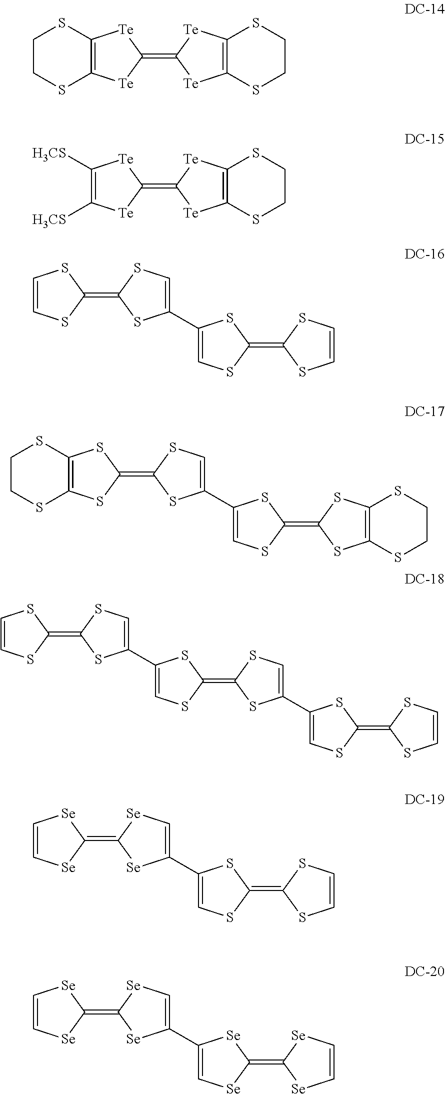

(4) Examples of TTT derivative are compounds represented by Formula (D). Here, X₁, X₂, X₃ and X₄ each respectively represent S, Se, or Te; R₁, R₂, R₃ and R₄ each respectively represent a hydrogen atom or a substituent, R₁ and R₂, and R₃ and R₄ each pair may be joined to form a ring.

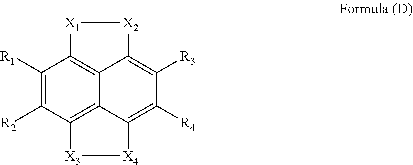

Although specific examples of a TTT derivative represented by Formula (D) are shown below, the present invention is not limited to these.

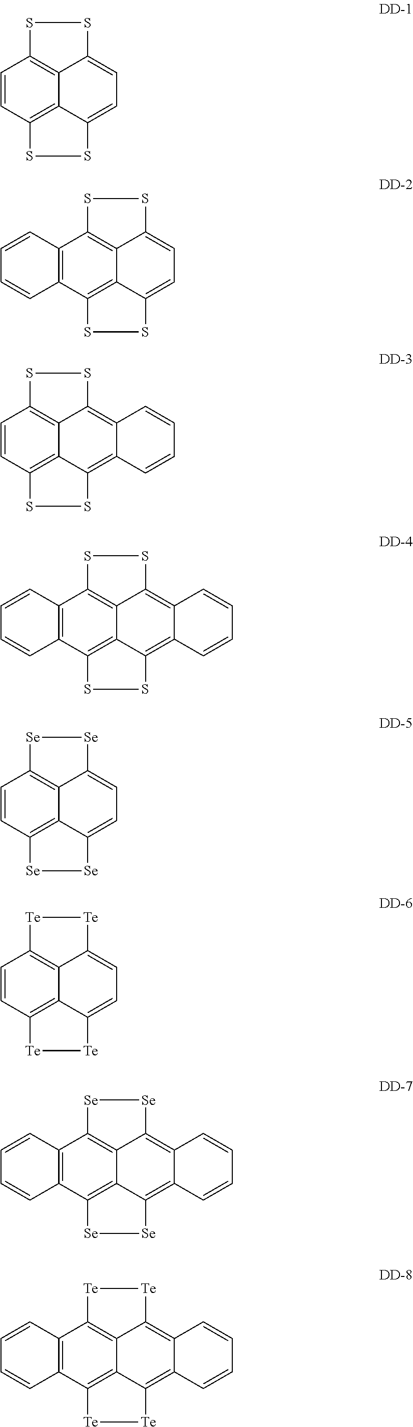

(5) Specific examples of a metallocene derivative are ferrocene, cobaltocene and nickelcene. These may have a substituent.

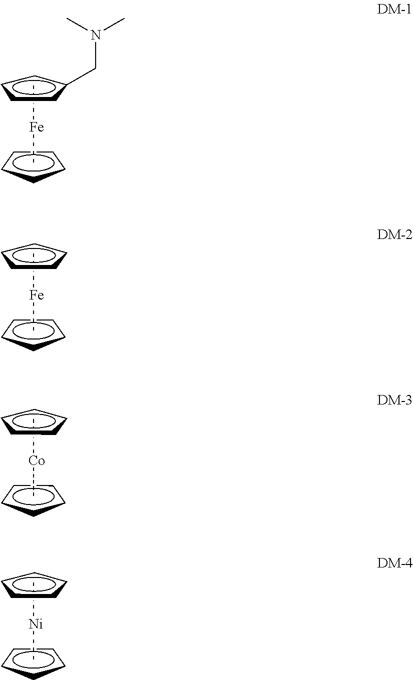

(6) As an imidazole radical derivative, it is included a compound which produces an imidazole radical by applying light or heat. Specific examples thereof are compounds represented by the following Formula (E). Here, R₁, R₂ and R₃ each respectively represent a hydrogen atom or a substituent, R₂ and R₃ may be joined to form a ring.

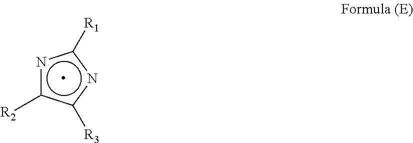

Although specific examples of an imidazole radical derivative represented by Formula (E) are shown below, the present invention is not limited to these.

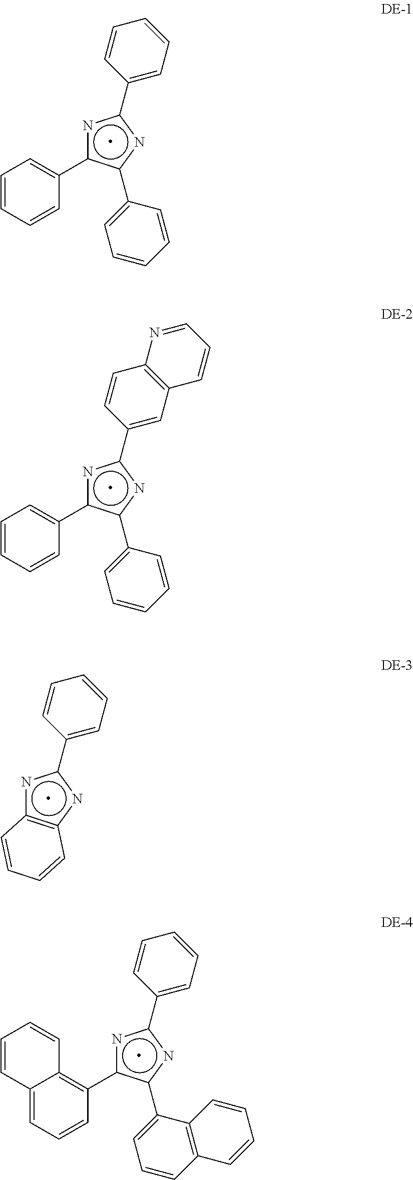

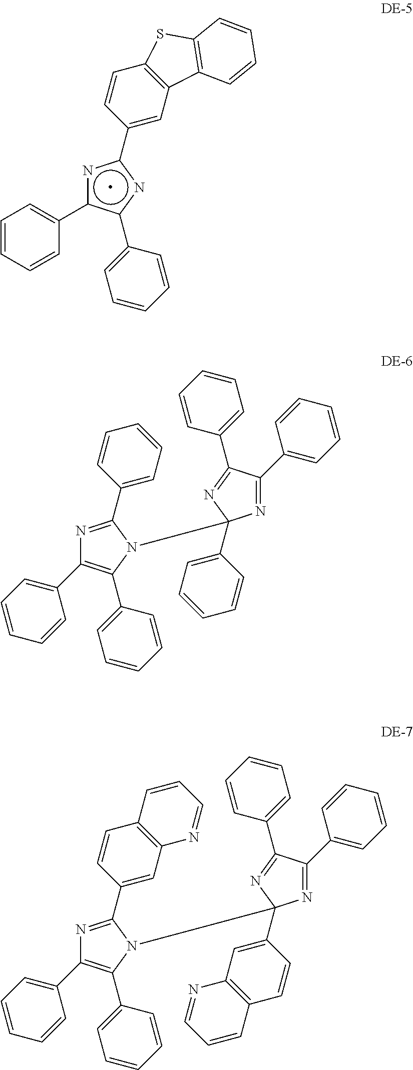

(7) Examples of a condensed multi-ring aromatic hydrocarbon include: naphthalene, anthracene, phenanthrene, pyrene, triphenylene, chrysene, tetracene, pentacene, perylene, ovalene, circumanthracene, anthanthrene, pyranthrene and rubrene.

(8) Examples of an arylamine derivative include: diethylamino benzene, aniline, toluidine, anisidine, chloroaniline, diphenylamine, indole, scatol, p-phenylenediamine, durene diamine, N,N, N, N-tetramethyl-p-phenylenediamine, benzidine, N,N, N,N-tetramethyl benzidine, tetrakis(dimethylamino)pyrene, tetrakis(dimethylamino)ethylene, biimodazole, m-MDTATA and α-NPD.

(9) Examples of an azine derivative include: cyanine dye, carbazole, acridine, a phenazine, an N,N-dihydrodimethyl phenazine, phenoxazine and phenothiazine.

(10) Examples of a transition metal complex salt derivative are compounds represented by the following Formula (F). Here, X₁, X₂, X₃ and X₄ each respectively represent S, Se, Te, or NR, R represents a hydrogen atom, an alkyl group, an alkoxy group, an aryl group, or a heteroaryl group. R₁, R₂, R₃ and R₄ each respectively represent a hydrogen atom or a substituent, R₁ and R₂, and R₃ and R₄ each pair may be joined to form a ring. M is preferably H₂, Co, Fe, Mg, Li₂, Ru, Zn, Cu, Ni, Na₂, Cs₂, or Sb.

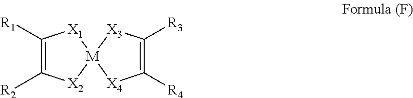

Although specific examples of a transition metal complex salt derivative represented by Formula (F) are shown below, the present invention is not limited to these.

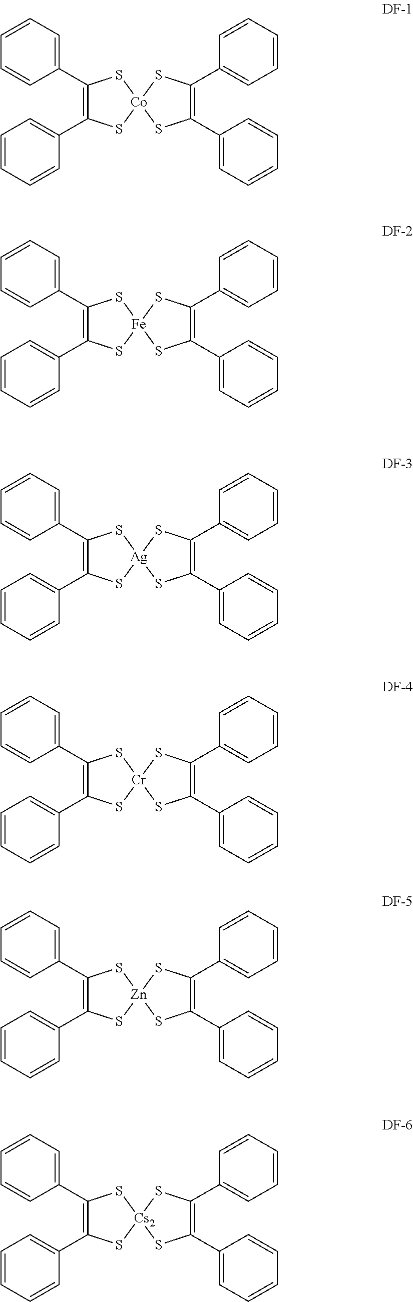

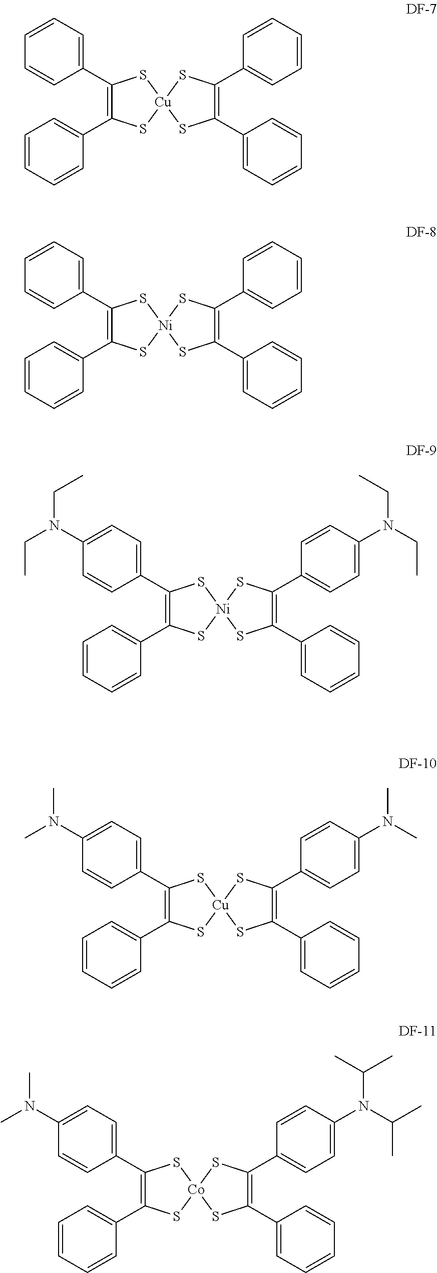

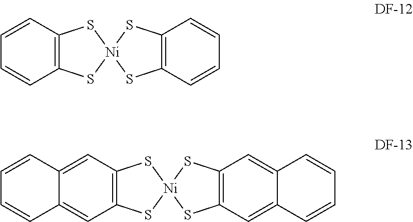

(11) As further examples of a transition metal complex salt derivative, there are compounds represented by the following Formula (N). Here, a, b, c, and e each represent —NRₙ₁—, or —CR_{c1}CR_{c2}—, provided that Rₙ₁, CR_{c1} and CR_{c2} each respectively represent a hydrogen atom or a substituent, E represents N, or —CR_{c3}—, and R_{c3} represents a hydrogen atom or a substituent. M represents Mo or W. “n” and “m” each represent an integer of 0 to 5.

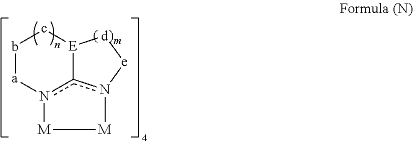

Although specific examples of a compound represented by Formula (N) are shown below, the present invention is not limited to these.

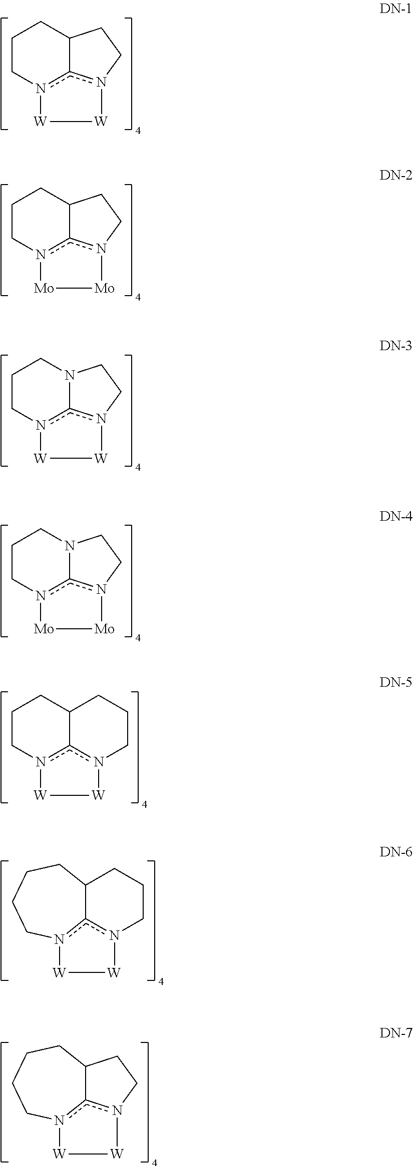

(12) Although specific examples of a triarylamine derivative are shown below, the present invention is not limited to these.

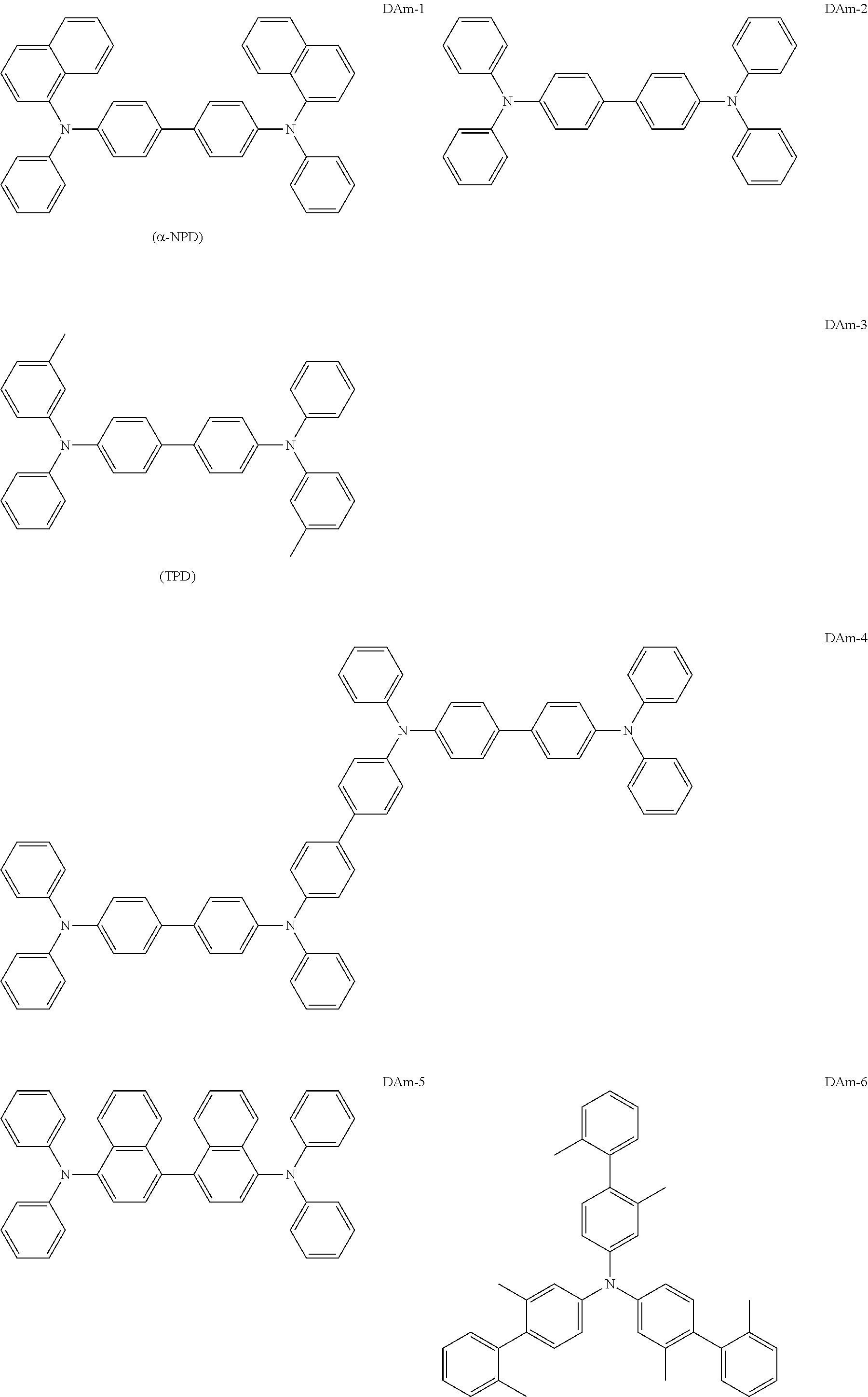

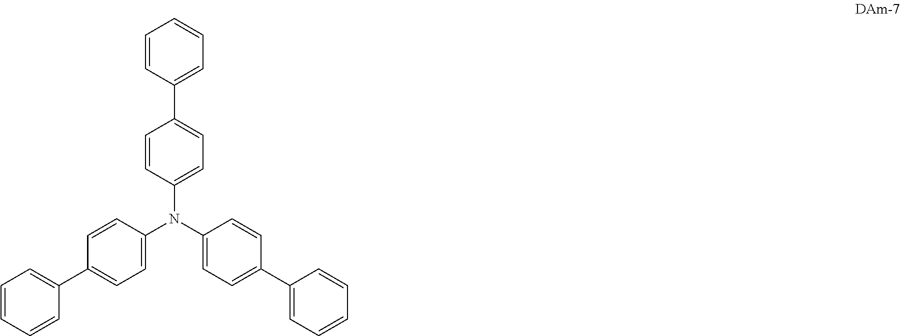

### (Organic Acceptor)

Examples of an organic acceptor include: a quinone derivative, a polycyano derivative, a tetracyanoquinodimethane derivative, a DCNQI derivative, a polynitro derivative, a transition metal complex salt derivative, a phenanthroline derivative, an azacarbazole derivative, a quinolinol metal complex derivative, an aromatic heterocyclic derivative, a fullerene derivative, a phthalocyanine derivative, a porphyrin derivative, a fluorinated heterocyclic derivative.

(1) Examples of a quinone derivative are compounds represented by Formula (O). Here, R₁, R₂, R₃ and R₄ each respectively represent a hydrogen atom or a substituent, R₁ and R₂, and R₃ and R₄ each pair may be joined to form a ring. R₁, R₂, R₃ and R₄ each are preferably a halogen atom or a cyano group.

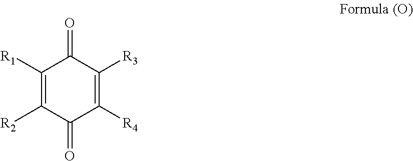

Although specific examples of a quinone derivative are shown below, the present invention is not limited to these.

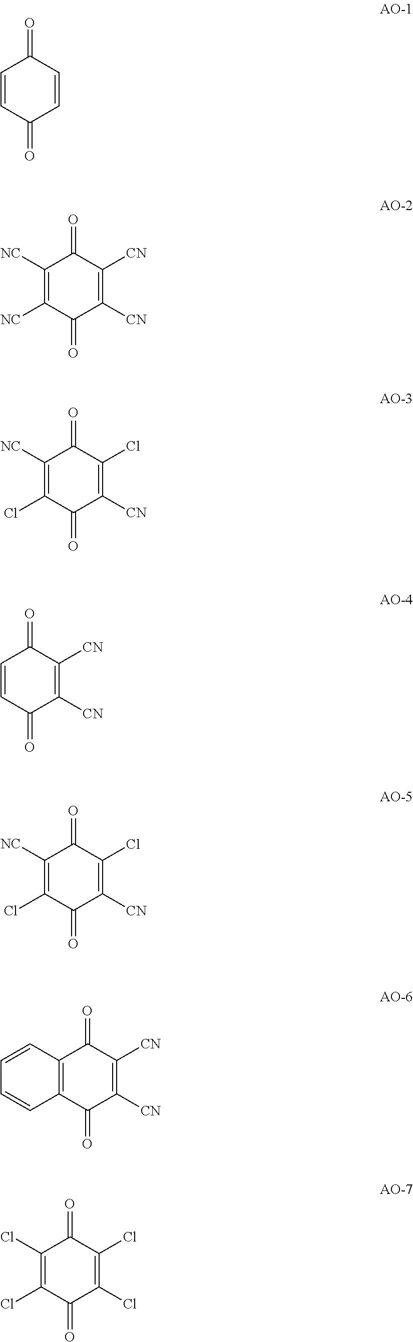

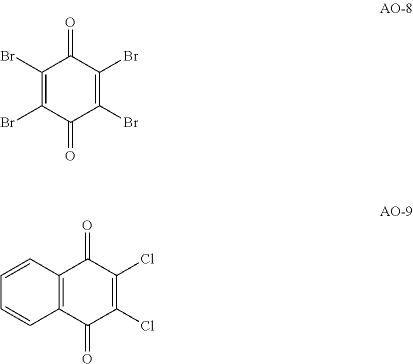

(2) Examples of a polycyano derivative are shown below.

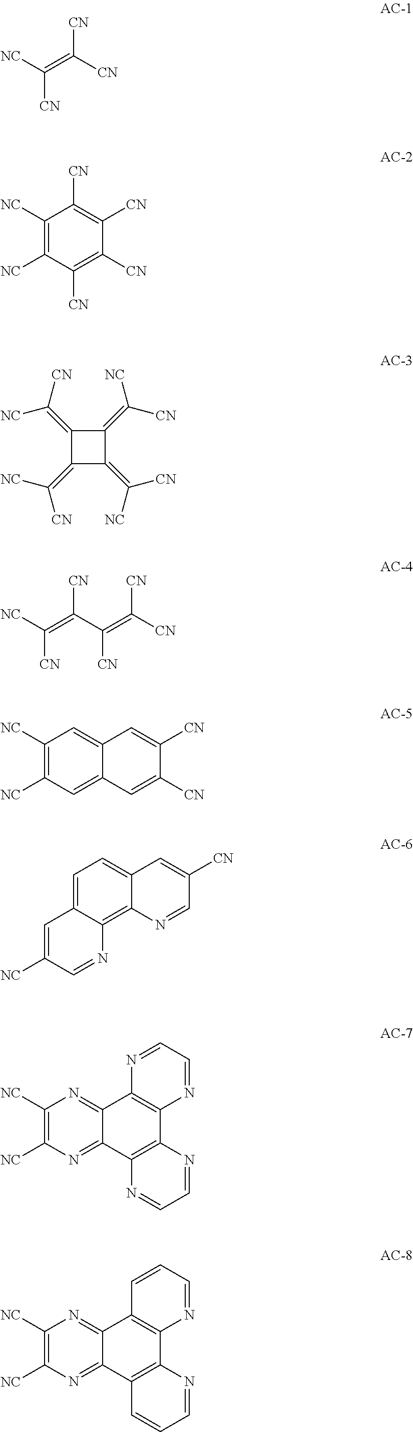

(3) Examples of a tetracyanoquinodimethane derivative are compounds represented by the following Formula (G). Here, R₁, R₂, R₃ and R₄ each respectively represent a hydrogen atom or a substituent, R₁ and R₂, and R₃ and R₄ each pair may be joined to form a ring.

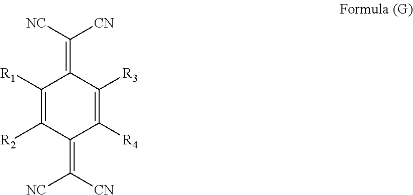

Although specific examples of a tetracyanoquinodimethane derivative are shown below, the present invention is not limited to these.

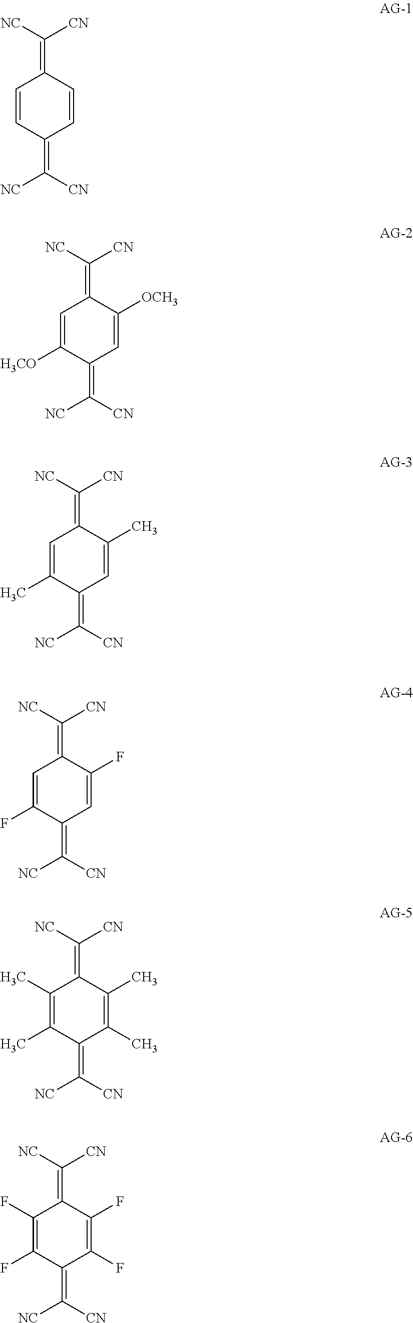

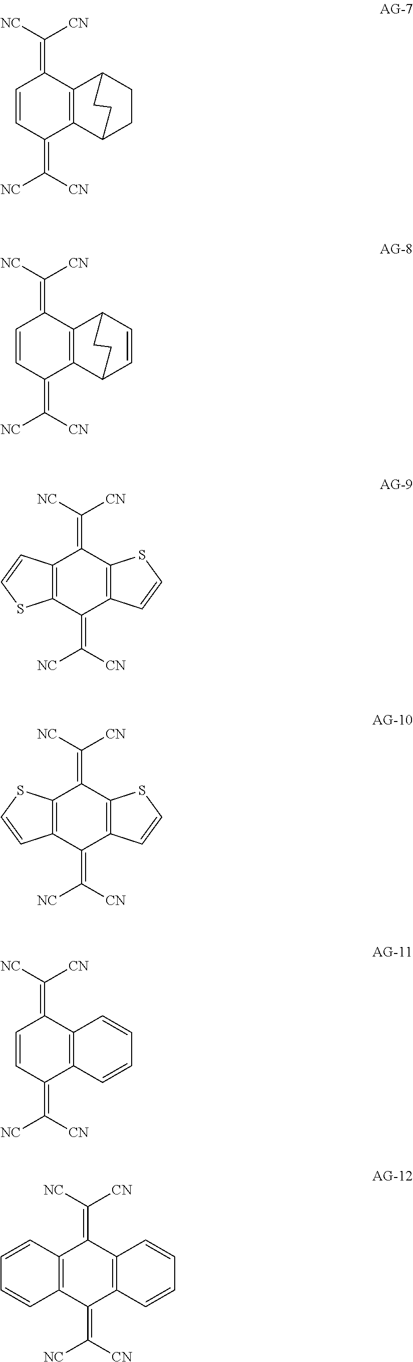

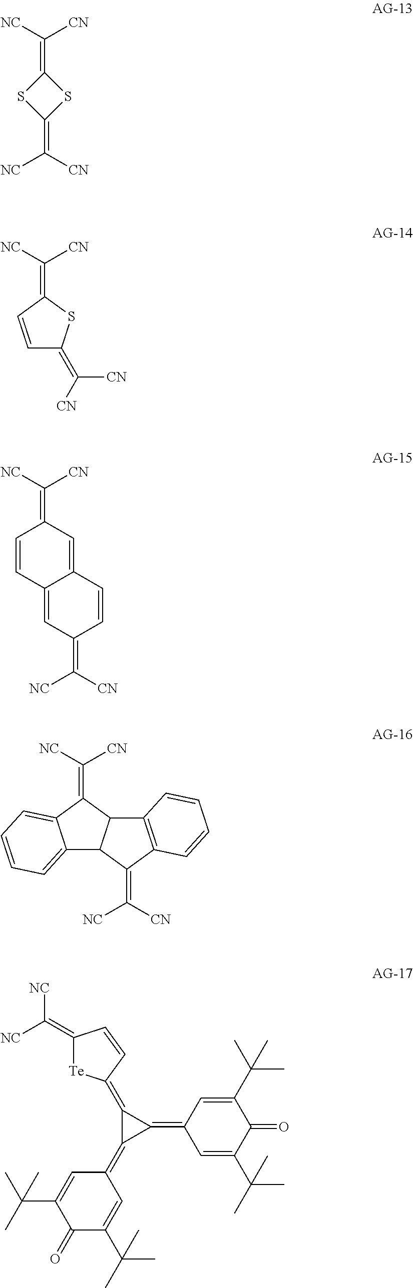

(4) Examples of a DCNQI derivative are compounds represented by Formula (H). Here, R₁, R₂, R₃ and R₄ each respectively represent a hydrogen atom or a substituent, R₁ and R₂, and R₃ and R₄ each pair may be joined to form a ring.

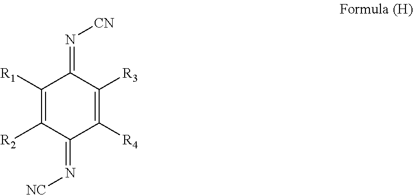

Although specific examples of a DCNQI derivative represented by Formula (H) are shown below, the present invention is not limited to these.

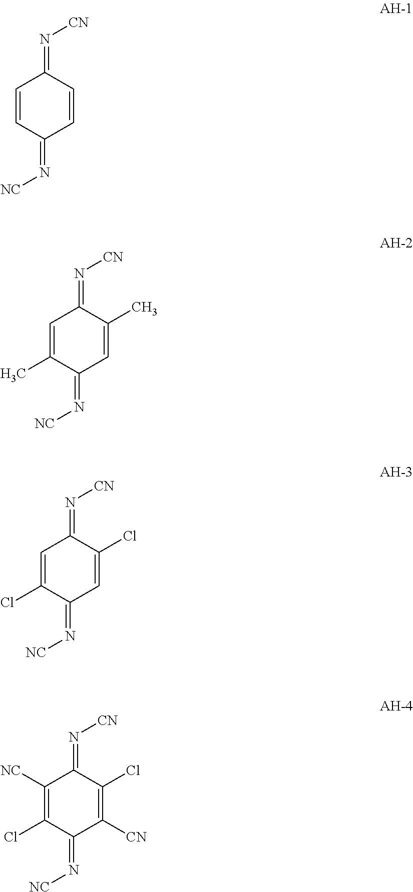

(5) Examples of a polynitro derivative include: trinitrobenzene, picric acid, dinitrophenol, dinitro biphenyl, 2,4,7-trinitro-9-fluorenone, 2,4,5,7-tetranitro-9-fluorenone, 9-dicyanomethylene-2,4,7-trinitrofluorenone and 9-dicyanomethylene-2,4,5,7-tetranitrofluorenone.

(6) Examples of a transition metal complex salt derivative are a transition metal complex salt represented by the following Formulas (I) or (J), or their derivatives. Specific examples of a transition metal complex salt derivative are the same compounds as described above.

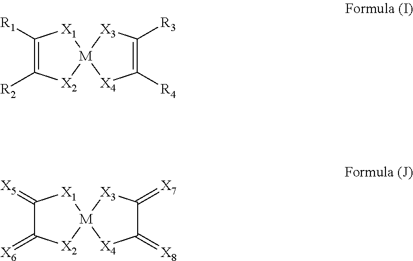

Here, X₁, X₂, X₃ and X₄ each respectively represent S, Se, Te, or NR. R represents a hydrogen atom, an alkyl group, an alkoxy group, an aryl group, or a heteroaryl group. R₁, R₂, R₃ and R₄ each respectively represent a hydrogen atom or a substituent, provided that at least one of these groups represents an electron withdrawing group selected from a fluorine atom, a cyano group and a fluorinated alkyl group such as a trifluoromethyl group. R₁ and R₂, and R₃ and R₄ each pair may be joined to form a ring. M is preferably H₂, Co, Fe, Mg, Li₂, Ru, Zn, Cu, Ni, Na₂, Cs₂, or Sb. Further, X₅ to X₈ each represent one of an oxygen atom, a sulfur atom and an imino group (NH).

Specific examples thereof are the following compounds.

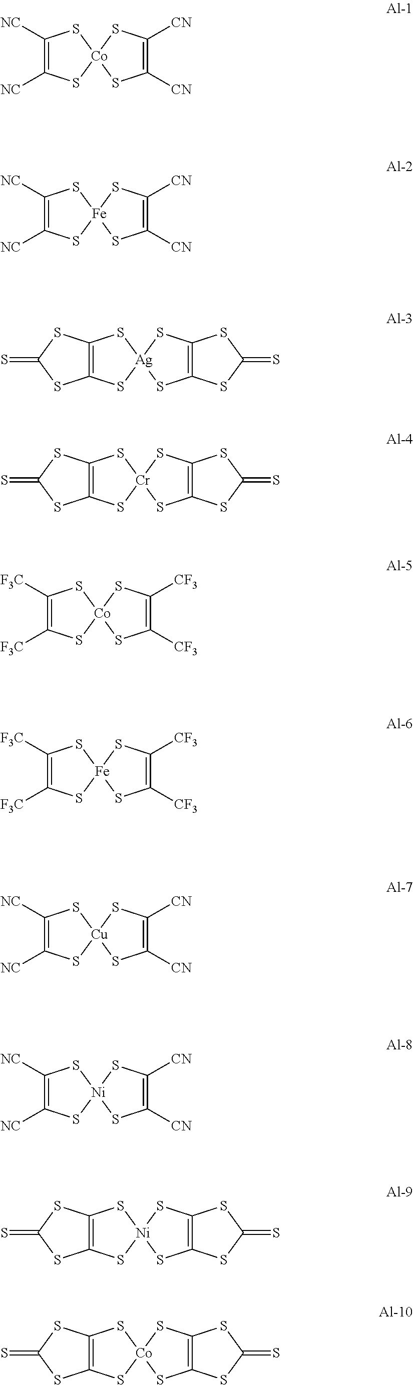

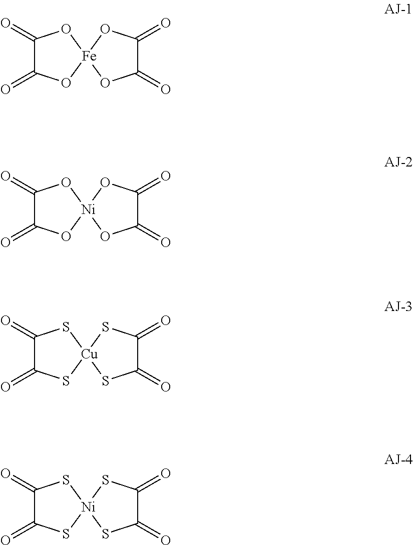

(8) Examples of a phenanthroline derivative are compounds represented by the following Formula (K). Here, R₁, R₂, R₃, R₆, R₅, R₆, R₇ and R₈ each respectively represent a hydrogen atom or a substituent.

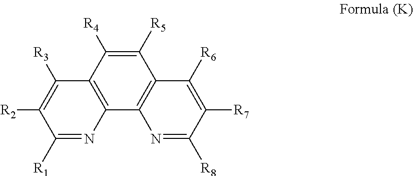

Although specific examples of a phenanthroline derivative represented by Formula (K) are shown below, the present invention is not limited to these.

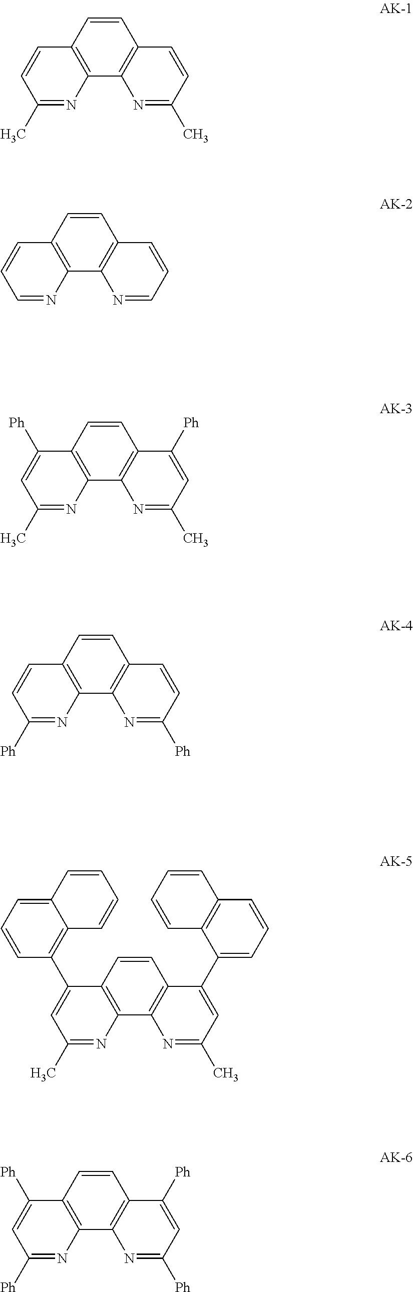

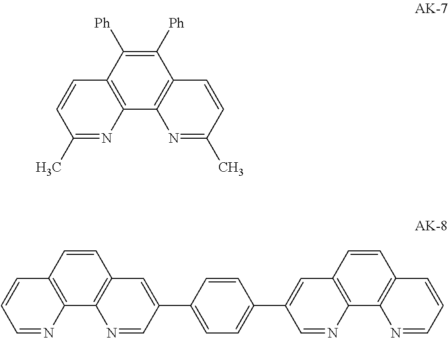

(9) Examples of an azacarbazole derivative are compounds represented by the following Formula (L). Here, X₁, X₂, X₃, X₄, X₅, X₆, X₇ and X₈ each respectively represent N or CR. R represents a hydrogen atom, an alkyl group, an alkoxy group, an aryl group, or a heteroaryl group. R₁ represents a hydrogen atom or a substituent.

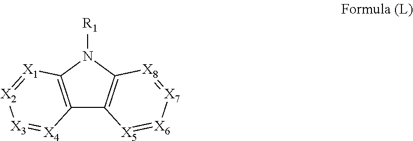

Although specific examples of an azacarbazole derivative represented by Formula (L) are shown below, the present invention is not limited to these.

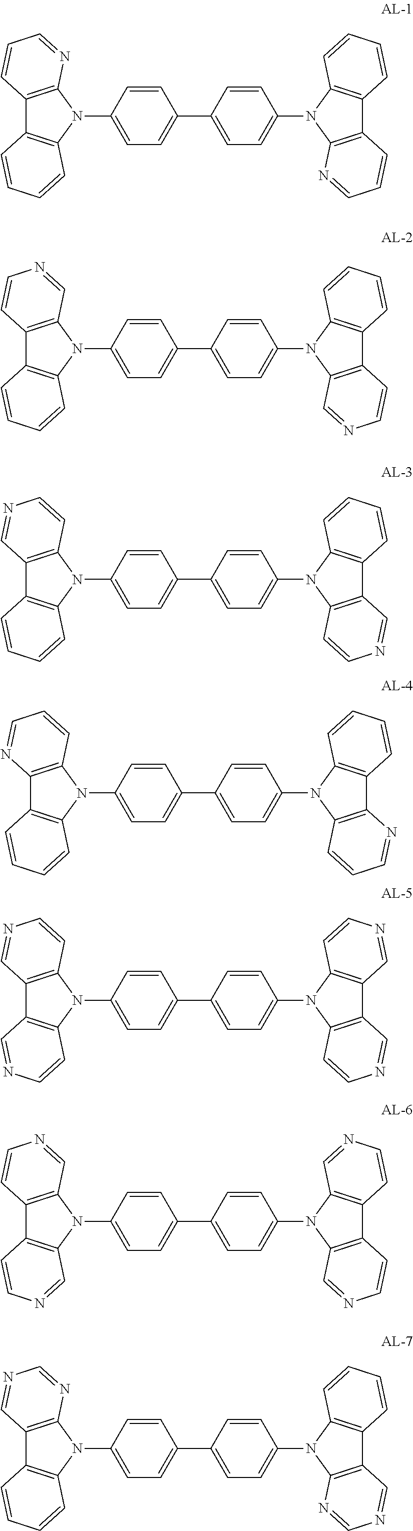

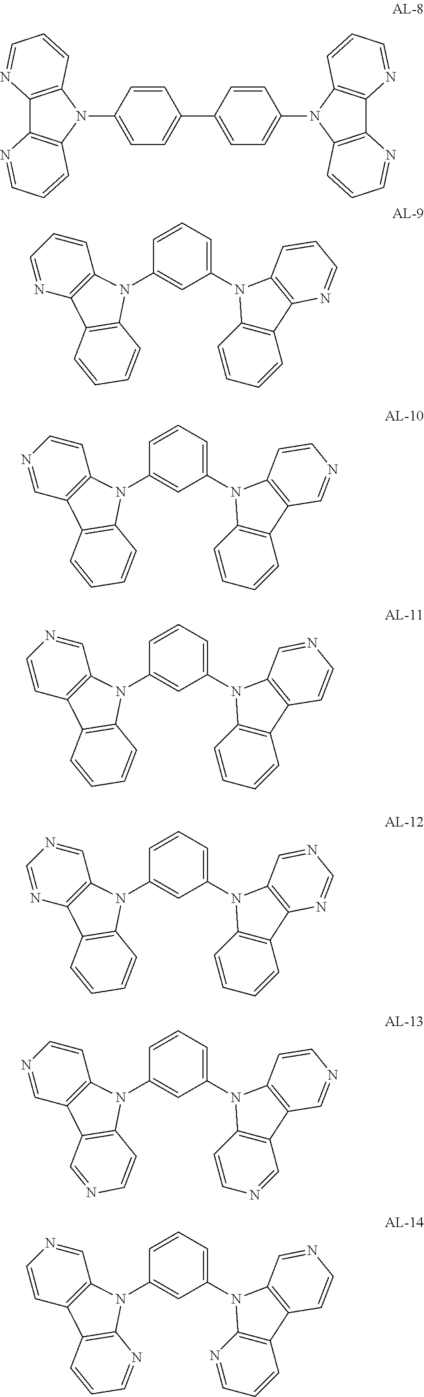

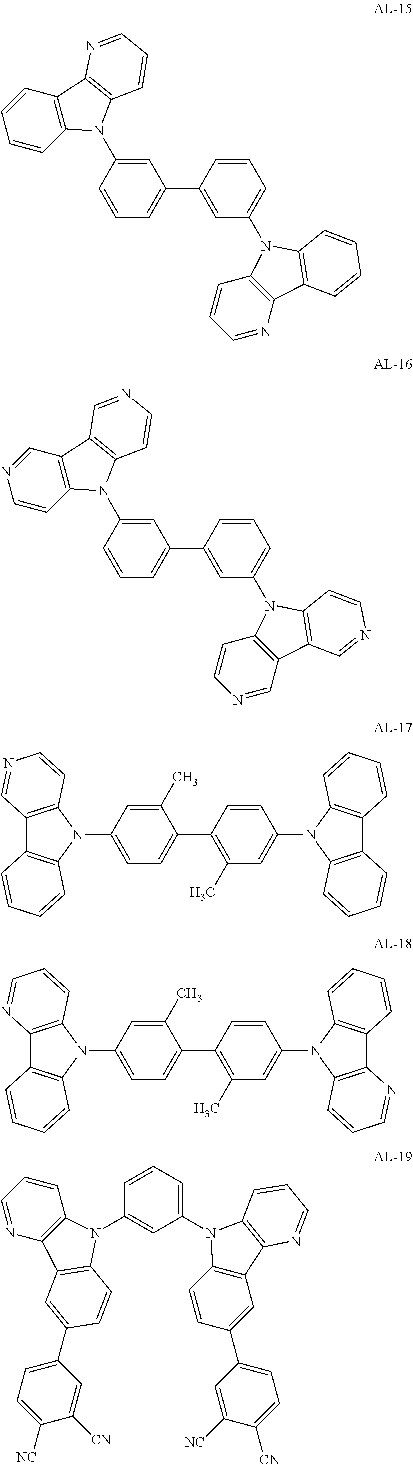

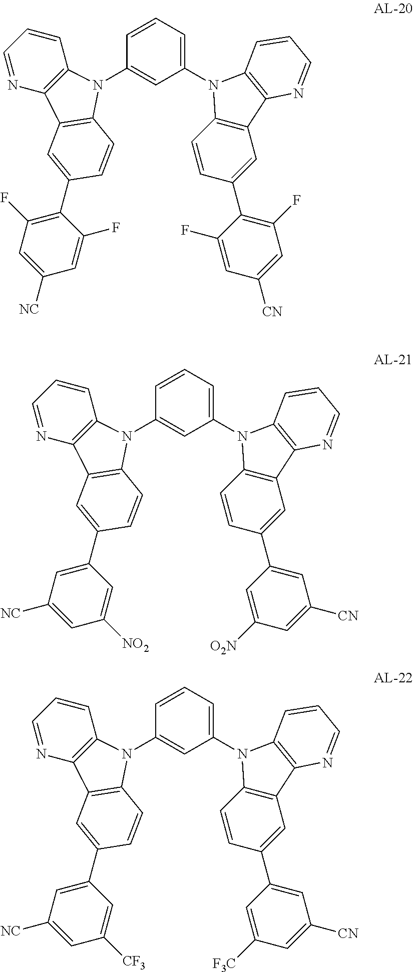

(10) Examples of a quinolinol metal complex derivative are compounds represented by Formula (M). Here, M is preferably Al, Co, Fe, Mg, Ru, Zn, Cu, or Ni.

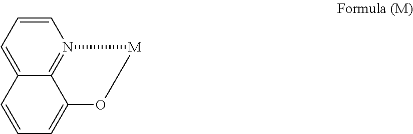

Although specific examples of a quinolinol metal complex derivative represented by Formula (M) are shown below, the present invention is not limited to these.

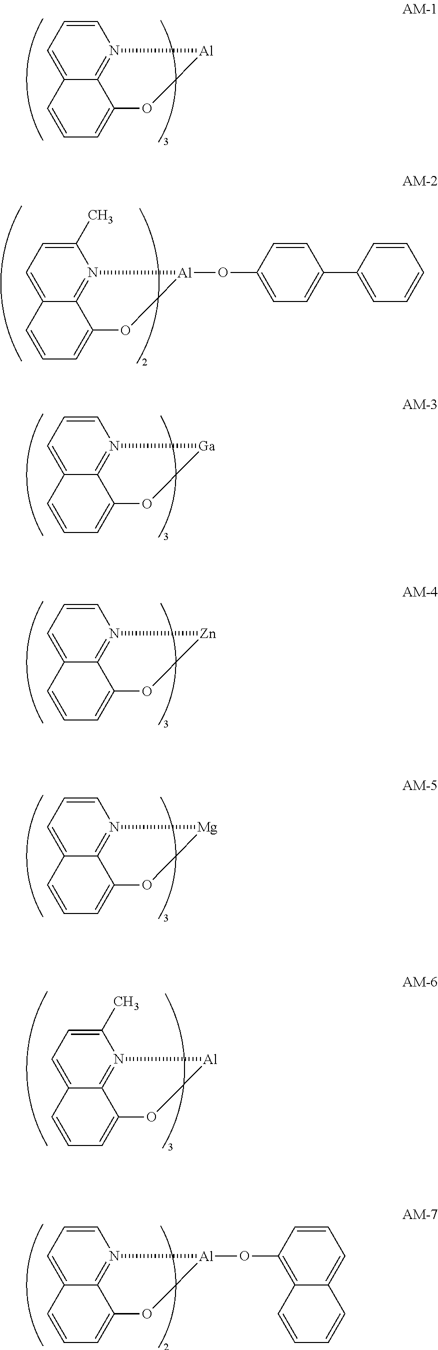

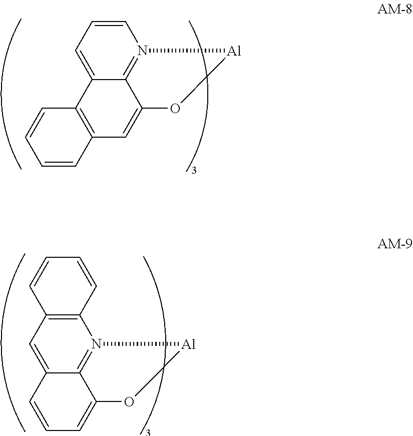

(11) Among aromatic heterocyclic compounds (in the present invention, an aromatic heterocyclic compound indicates a compound derived from an aromatic hydrocarbon compound in which one or more carbon atoms constituting the aromatic hydrocarbon structure are substituted with a hetero atom, such as an oxygen, sulfur, nitrogen, phosphor, and boron atom), especially, pyridine derivatives obtained by substituting a carbon atom with a nitrogen atom are suitably used. However, the present invention is not limited to these.

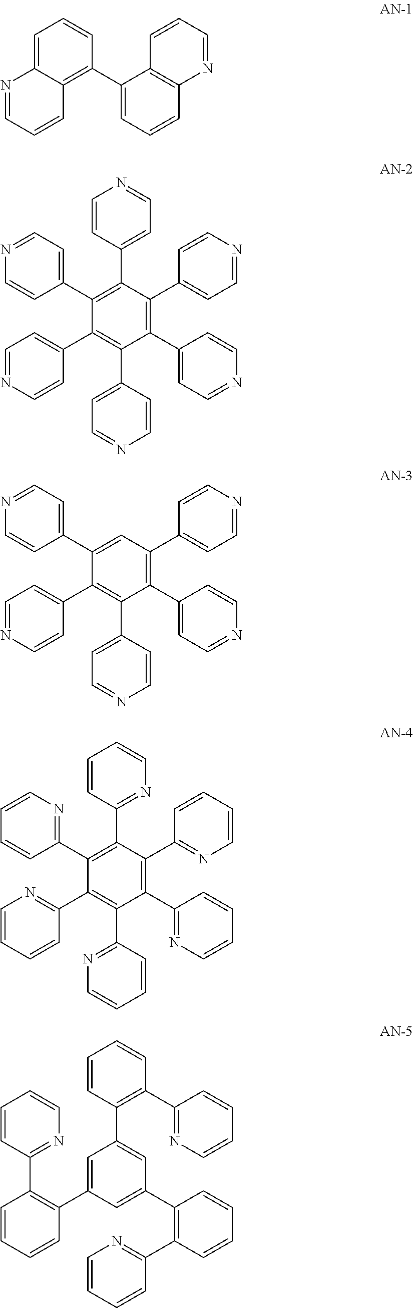

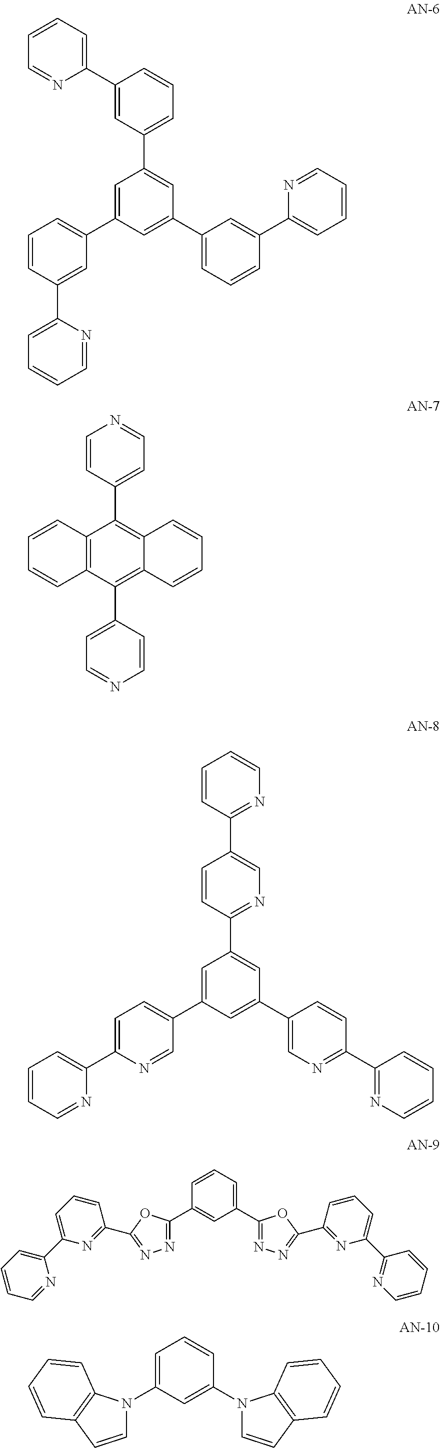

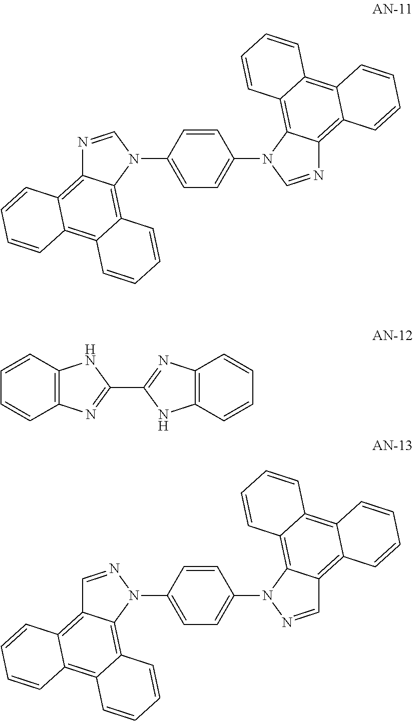

(12) Examples of a nano carbon are the aforesaid nano carbon materials. Preferably, the above-described fullerene derivatives can be used in the present invention.

(13) Examples of a phthalocyanine derivative are compounds represented by the following Formula (P). Here, X₁, X₂, X₃ and X₄ each respectively represent N or —CR. R represents a hydrogen atom, an alkyl group, an alkoxy group, an aryl group, or a heteroaryl group. The phthalocyanine derivative may have a substituent on the phthalocyanine ring. M represents V═O or Ti═O.

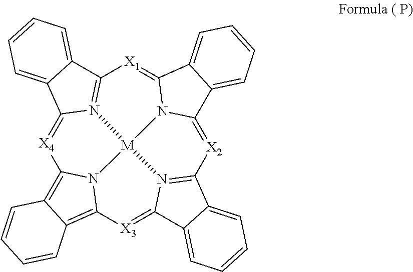

Although specific examples are shown below, the present invention is not limited to these.

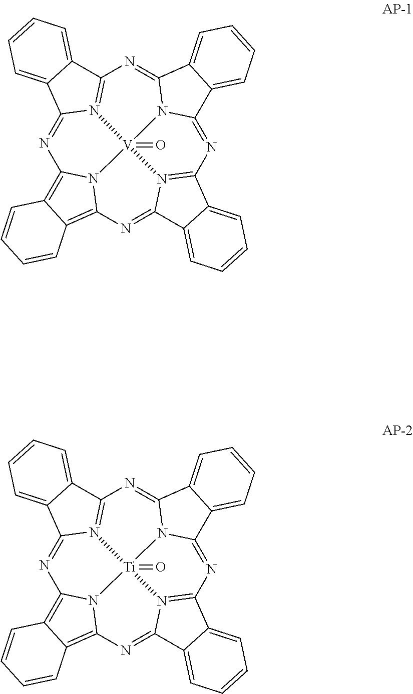

(14) Examples of a porphyrin derivative are compounds represented by the following Formula (Q). Here, X₁, X₂, X₃ and X₄ each respectively represent N or —CR. R represents a hydrogen atom, an alkyl group, an alkoxy group, an aryl group, or a heteroaryl group. The porphyrin derivative may have a substituent on the porphyrin ring. M represents V═O or Ti═O.

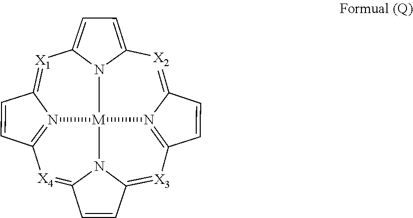

Although specific examples are shown below, the present invention is not limited to these.

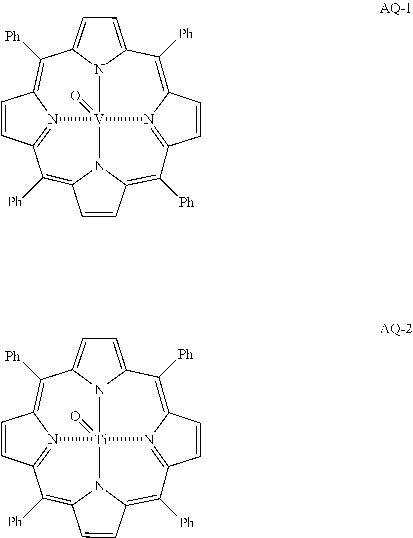

(15) Examples of a fluorinated heterocyclic derivative include a fluorinated aromatic hydrocarbon and a fluorinated hetero aromatic compound. Preferably, there are cited: fluorinated phthalocyanine, fluorinated porphyrin and fluorinated fullerene.

The substituents used for the present invention are as follows: an alkyl group, an alkenyl group, an alkynyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, a heteroaryl group, a heteroaryl group, a heteroaryloxy group, a heteroarylthio group, a heteroarylalkyl group, a hetero arylalkoxy group, a heteroarylalkylthio group, a heteroarylalkenyl group, a heteroarylalkynyl group, an amino group, a substituted amino group, a silyl group, a substituted silyl group, a halogen atom, an acyl group, an acyloxy group, an imine residue, an amido group, an acid imide group, a monovalent heterocycle group, a carboxyl group, a substituted carboxyl group, a cyano group, a nitro group and a halogenyl group. Here, an aryl group is a group formed by removing one hydrogen atom from an aromatic hydrocarbon. An aromatic hydrocarbon contains: a monocyclic aromatic hydrocarbon, a condensed polycyclic hydrocarbon, a bonded compound formed with two or more independent monocycle aromatic hydrocarbons, or a condensed polycyclic hydrocarbon with each other. Examples of an aromatic hydrocarbon include: a phenyl group, a naphthyl group, an anthryl group, a biphenyl group, a fluorenyl group and a binaphthyl group. A hetero aryl group is a group formed by removing one hydrogen atom from a hetero aromatic hydrocarbon. A hetero aromatic hydrocarbon indicates, among the carbon atoms which constitute the aforesaid aromatic hydrocarbon ring, a compound formed by replacing one or more carbon atoms with a hetero atom such as an oxygen, nitrogen, phosphor or a boron atom. A hetero aromatic hydrocarbon contains: a monocyclic hetero aromatic hydrocarbon, a condensed polycyclic hetero hydrocarbon, a bonded compound formed with two or more independent monocyclic hetero aromatic hydrocarbons, or a condensed polycyclic hetero hydrocarbon with each other. Examples of a hetero aromatic hydrocarbon include: a pyridyl group, a thiophenyl group, a bipyridyl group, a phenylpyridinyl group, a carbazolyl group, an azacarbazolyl group, an imidazolyl group, a dibenzofuranyl group, an isoquinolyl group, a dibenzophosphonyl group.

### <Inorganic Material>

As an inorganic compound which forms the inorganic compound layer concerning the charge generating layer of the present invention, it is preferable an inorganic compound having higher conductivity than a semiconductor.

It can choose a metal, an inorganic salt or inorganic oxide having higher conductivity than a semiconductor.

One of the formation methods of an inorganic compound layer is a method to coat a particle dispersion liquid, a precursor particle dispersion liquid, a precursor solution, or a solution with an application process, and if required, to supply energy from the exterior. It is possible to obtain an inorganic compound layer by this method.

As a source of external energy, although heat, lights (ultraviolet, visible, infrared rays, etc.), electromagnetic waves (microwave etc.), plasma, electric discharge can be chosen, it is preferable to choose the condition by which the temperature of the substrate is kept at 180° C. or less, more preferably at 130° C. or less. By adding external energy, it can form a film having a high conductivity. Moreover, the conduction band, the valence band, and the Fermi level of an inorganic compound layer can be changed with external energy.

One of the formation methods of an inorganic compound layer is a method to coat a particle dispersion liquid, a precursor particle dispersion liquid, a precursor solution, or a solution with a non-discharge type coating process. The aforesaid particle dispersion liquid is a dispersion liquid containing particles dispersed with water or an organic solvent. The aforesaid particles are grains having preferably an average size of 10 μm or less, more preferably an average size of 100 nm or less, and still more preferably an average size of 20 nm or less.

It is preferable that the particle dispersion liquid contains particles of uniform size.

As a particle dispersion liquid for forming an inorganic compound layer, it can be cited, for example, a metal particle dispersion liquid, an inorganic oxide particle dispersion liquid, an inorganic salt particle dispersion liquid.

Examples of a metal in the metal particle dispersion liquid include: gold, silver, copper, aluminium, nickel, iron and zinc. Preferable metals are silver and aluminium, however, the present invention is not limited to these. It is possible to use an alloy of the aforesaid metals.

Examples of an inorganic oxide in the inorganic oxide particle dispersion liquid include: titanium oxide, zirconium oxide, niobium oxide, zinc oxide, tin oxide, iron oxide, molybdenum oxide, vanadium oxide, lithium oxide, calcium oxide, magnesium oxide, ITO, IZO and In—Ga—Zn-Oxide, however, the present invention is not limited to these. It is possible to use a mixture of these inorganic oxides.

Examples of an inorganic salt in the inorganic salt particle dispersion liquid include: copper metal salts (for example, CuI), silver metal salt (for example, AgI), iron salt (for example, FeCl₃), compound semiconductor (for example, gallium-arsenic and cadmium selenium) and titanate (for example, SrTiO₃ and BaTiO₃), however, the present invention is not limited to these. It is possible to use a mixture of these inorganic oxides.

The precursor particle dispersion liquid and the precursor solution are respectively a dispersion liquid and a solution of a precursor to obtain a thin film of a metal or an inorganic oxide using a sol-gel reaction, an oxidation or reduction reaction.

By using a sol-gel reaction, it can obtain an inorganic oxide through a hydrolytic polycondensation with a metal halide salt, an alkoxide or an acetic acid salt.

If required, the sol-gel reaction can be accelerated by adding a catalytic amount of water, acid (inorganic and organic), or base (inorganic salt and organic salt) in the solution followed by coating.

Moreover, in many cases, the obtained inorganic oxide film is not complete due to the large amount of the remaining carbon residue. As a result, the obtained inorganic oxide film may have low conductivity. An inorganic oxide having high conductivity can be obtained by adding external energy if required. The kinds of external energy are described above.

Moreover, the conduction band, the valence band, and the Fermi level can be changed by applying external energy.

Examples of a metal used in a sol-gel reaction include: titanium, zirconium, zinc, tin, niobium, molybdenum, and vanadium, however, the present invention is not limited to these.

An oxidation reaction and a reduction reaction each are a method to change a precursor into an inorganic compound having a higher conductivity than a semiconductor by adding an oxidizing agent or a reducing agent.

For example, it is a combination of a metal salt and a reducing agent in order to reduce AgI to obtain Ag metal, or a combination of a metal and an oxidizing agent in order to produce a metal oxide using a metal and an oxidizing agent.

In obtaining an inorganic compound layer, it is also possible to combine the above-mentioned methods mutually.

It can carry out the following combinations, for example: a combination of a sol-gel method and inorganic particles; a combination of inorganic particles and a inorganic salt solution; and further, a combination of an inorganic compound and an organic compound.

The above-described compounds can be used as examples of an organic compound.

Although the layer thickness of the inorganic compound layer is 1 nm to 1 μm, it is preferably 1 nm to 200 nm, and more preferably 1 to 20 nm.

In the following, it will be described in detail an organic compound layer (organic EL layer) which constitutes an emission unit in an organic EL element having a multi-unit structure containing a charge generating layer which generates a hole and an electron by applying an electric field between a plurality of light emitting units.

### <<Light Emitting Layer>>

The light emitting layer of the organic EL element according to the present invention is a layer which emits light by recombination of electrons and holes which are injected from electrodes, a charge generating layer, an electron transporting layer or a hole transporting layer, and the light emitting part may be within the light emitting layer or at a boundary surface between the light emitting layer and the adjacent layer.

The total thickness of the light emitting layers is not particularly limited, but is preferably controlled within a range of 2 nm to 5 μm from a view point of uniformity of the layer, prevention of applying an unnecessary high voltage during a light emission, and improvement of the stability of a color of the emitted light against a driving current, more preferably controlled in the range of 2 nm to 200 nm, and particularly preferably in the range of 10 nm to 20 nm.

The light emitting layer may be produced by forming a film of a light emitting dopant or a host compound via commonly known thin film forming methods such as a vacuum deposition method, a spin coat method, a casting method, a LB method and an inkjet method.

It is preferable to incorporate a light-emitting host compound and at least one of light emitting dopants (such as a phosphorescent light emitting dopant (also referred to as a phosphorescent light emitting dopant) and a fluorescent dopant) into the light emitting layer of the organic EL element of the present invention.

It is preferable to incorporate a light-emitting host compound and at least one of light emitting dopant as a guest compound. It is more preferable to incorporate a light-emitting host compound and three or more kinds of light emitting dopants. In the following, a host compound (or called as “a light-emitting host compound”) and a light emitting dopant (or called as “a light emitting dopant compound”) will be described.

### (Host Compound (or Also Referred to Light-Emitting Host Compound))

A host compound used in the present invention will be described.

The host compound of the present invention refers to a compound contained in an emission layer in an amount of 20 weight % or more and exhibiting a phosphorescence quantum yield of less than 0.1 during phosphorescence emission at room temperature (25° C.). More preferably, the phosphorescence quantum yield of the host compound is less than 0.01. Among the compounds contained in the emission layer, the content of the host compound is preferably 20 weight % or more.

In the present invention, specifically preferable host compounds are: compounds containing a carbazole ring as a partial structure, compounds containing a polymerizable group and a carbazole ring as a partial structure and polymers of these compounds.

A host compound of the present invention may be a known host compound or it may be used by combining with plural known host compounds. It is possible to control the transfer of charges by making use of a plurality of host compounds, which results in high efficiency of an organic EL element. In addition, it is possible to mix a different emission lights by making use of a plurality of light emitting dopants which will be described later. Any required emission color can be obtained thereby.

Conventionally known host compound which may be used in combination are preferably compounds having a hole transporting ability and an electron transporting ability, as well as preventing elongation of an emission wavelength and having a high Tg (a glass transition temperature).

As specific examples of host compounds known in the fields are listed below and the compounds described in the following Documents are cited.

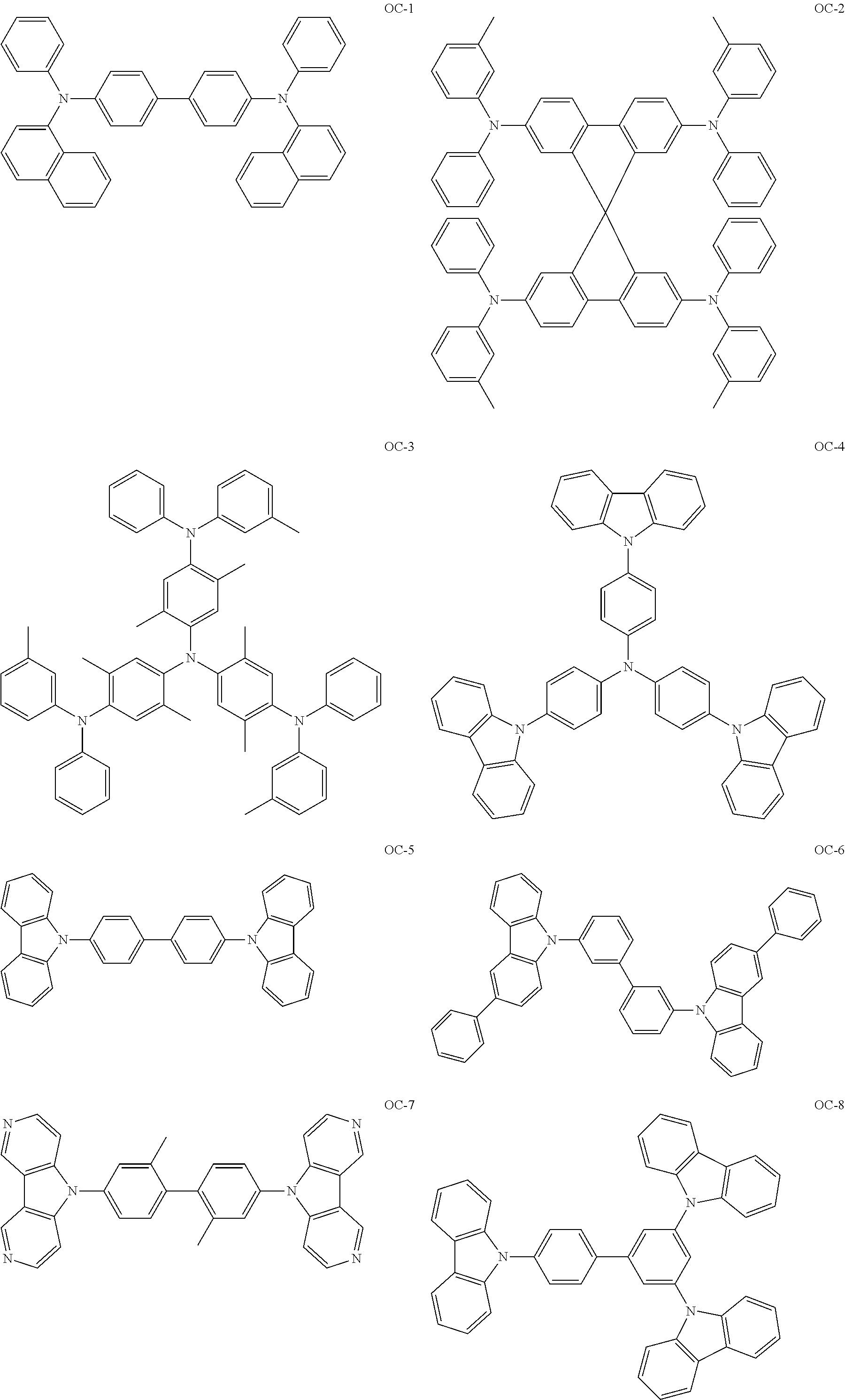

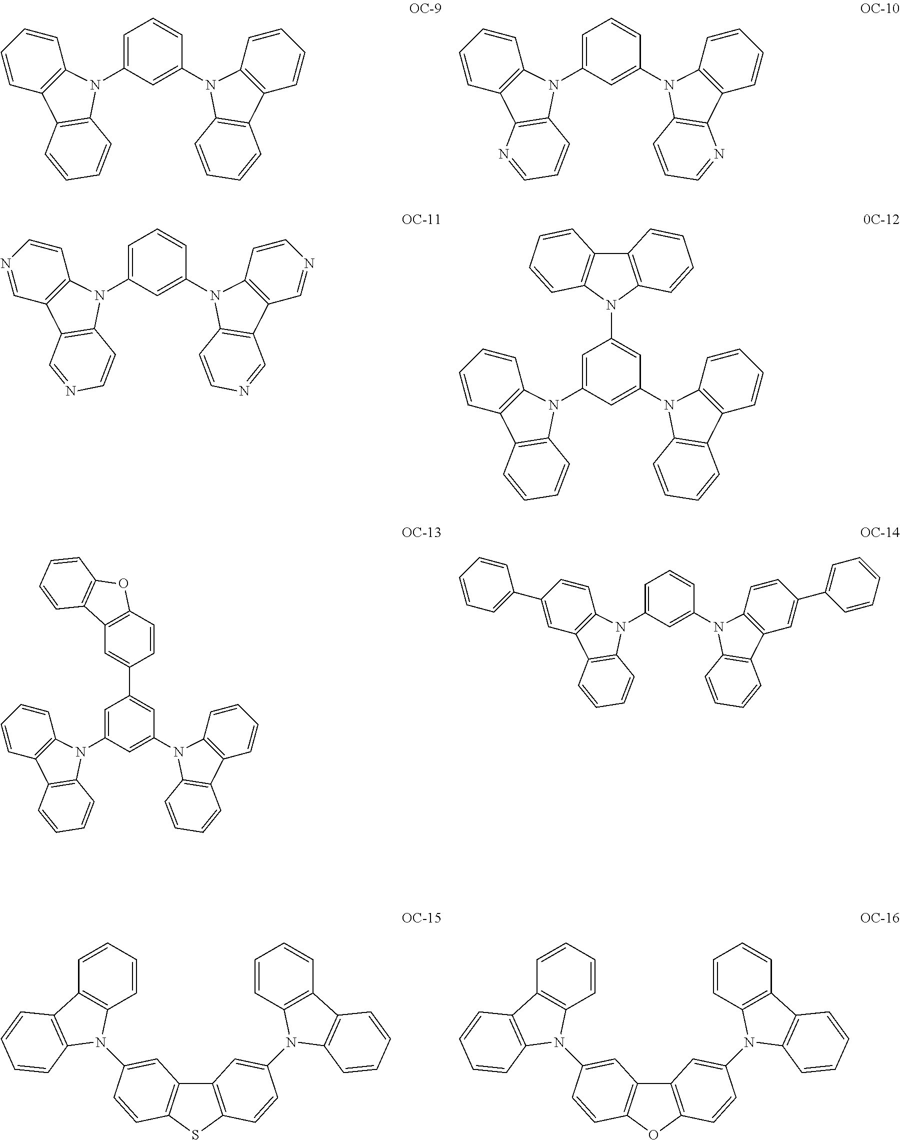

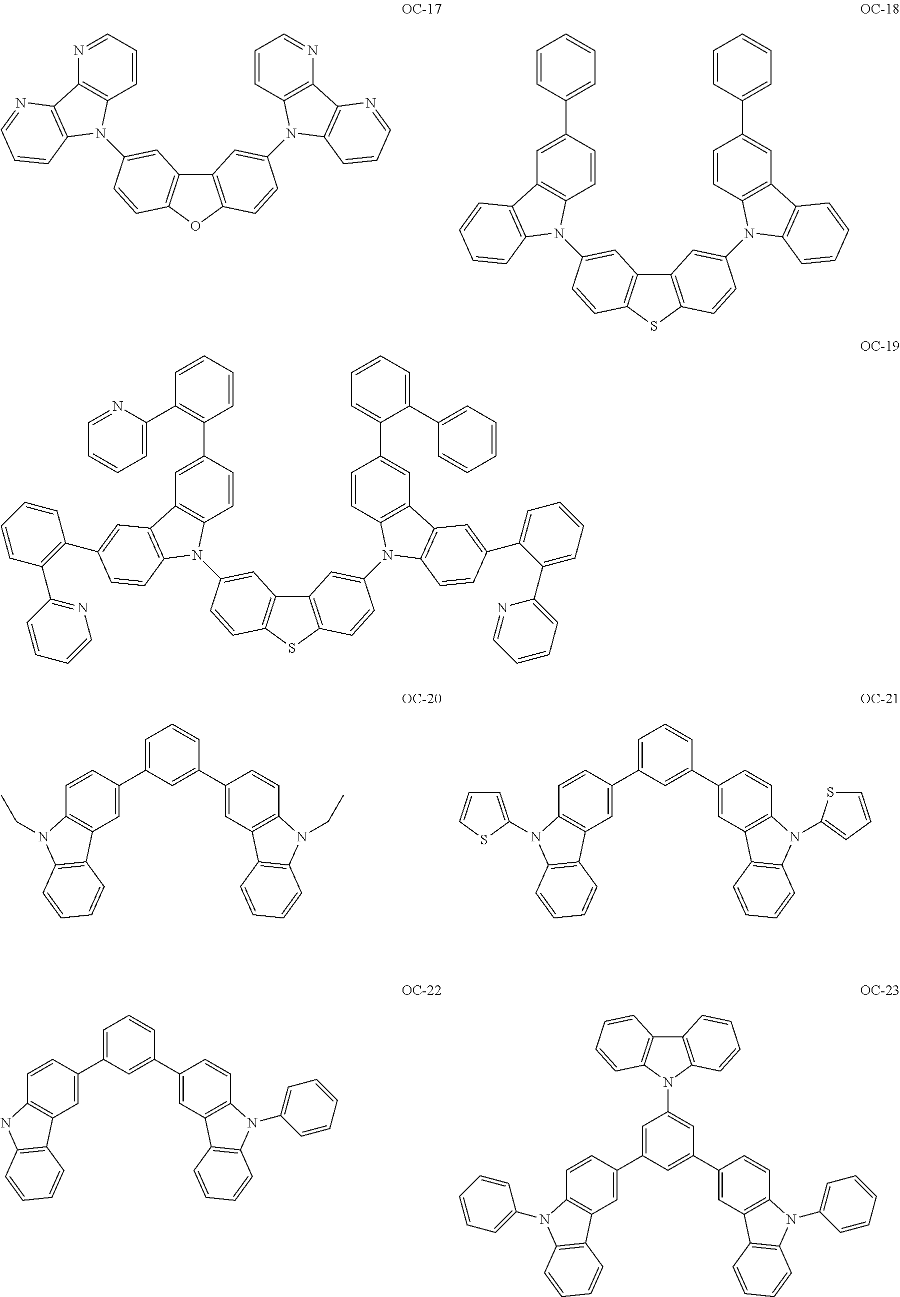

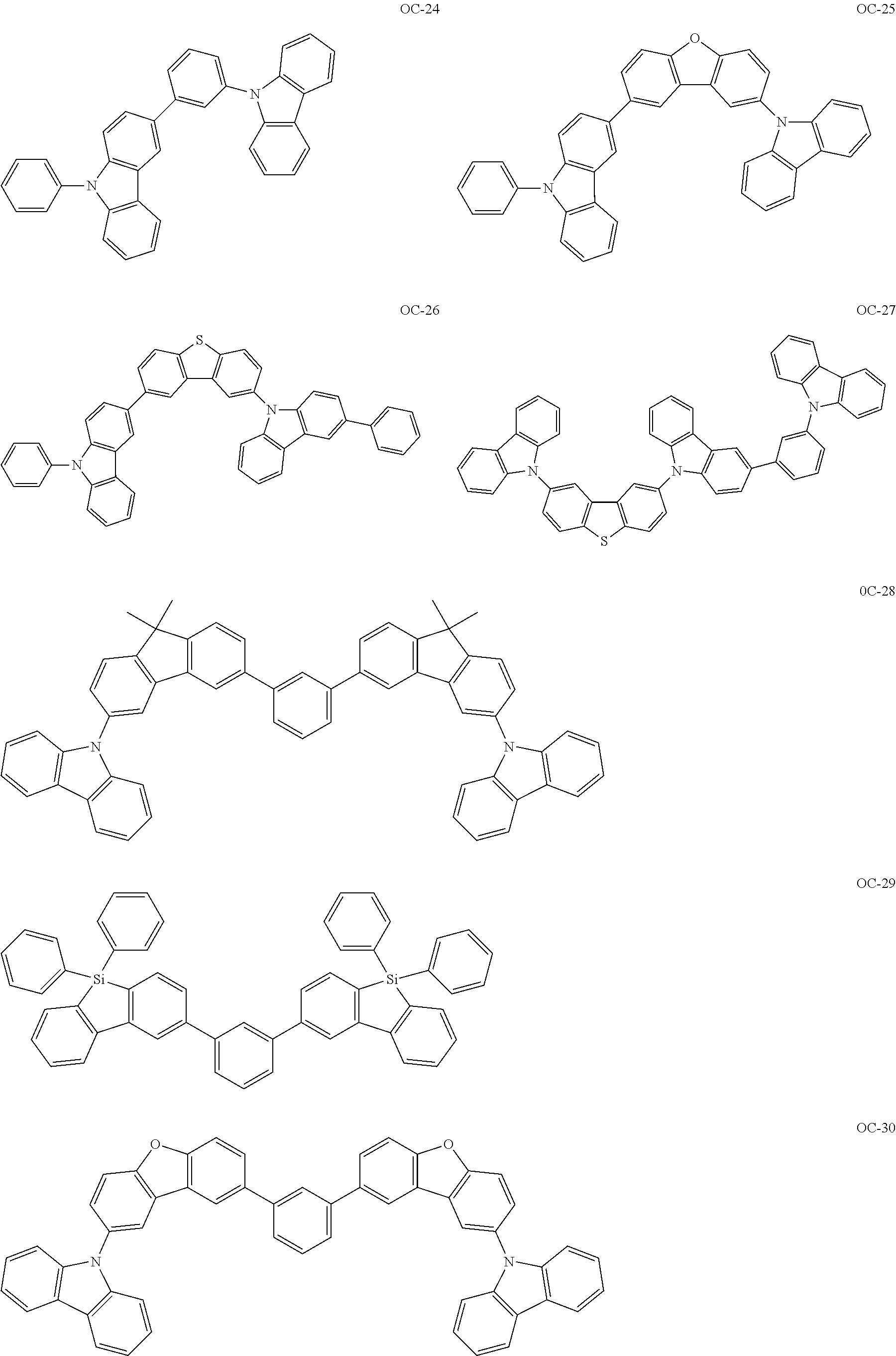

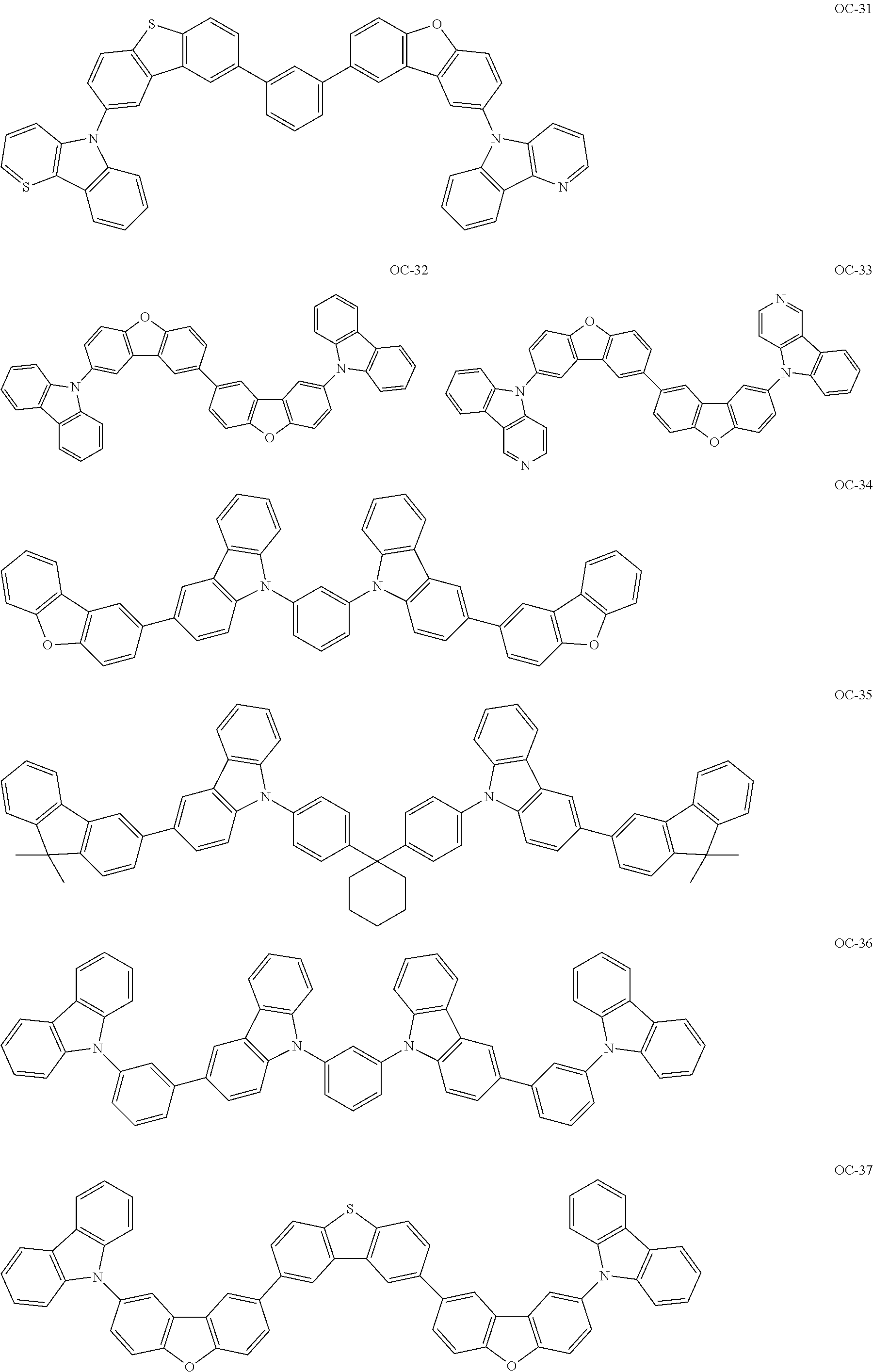

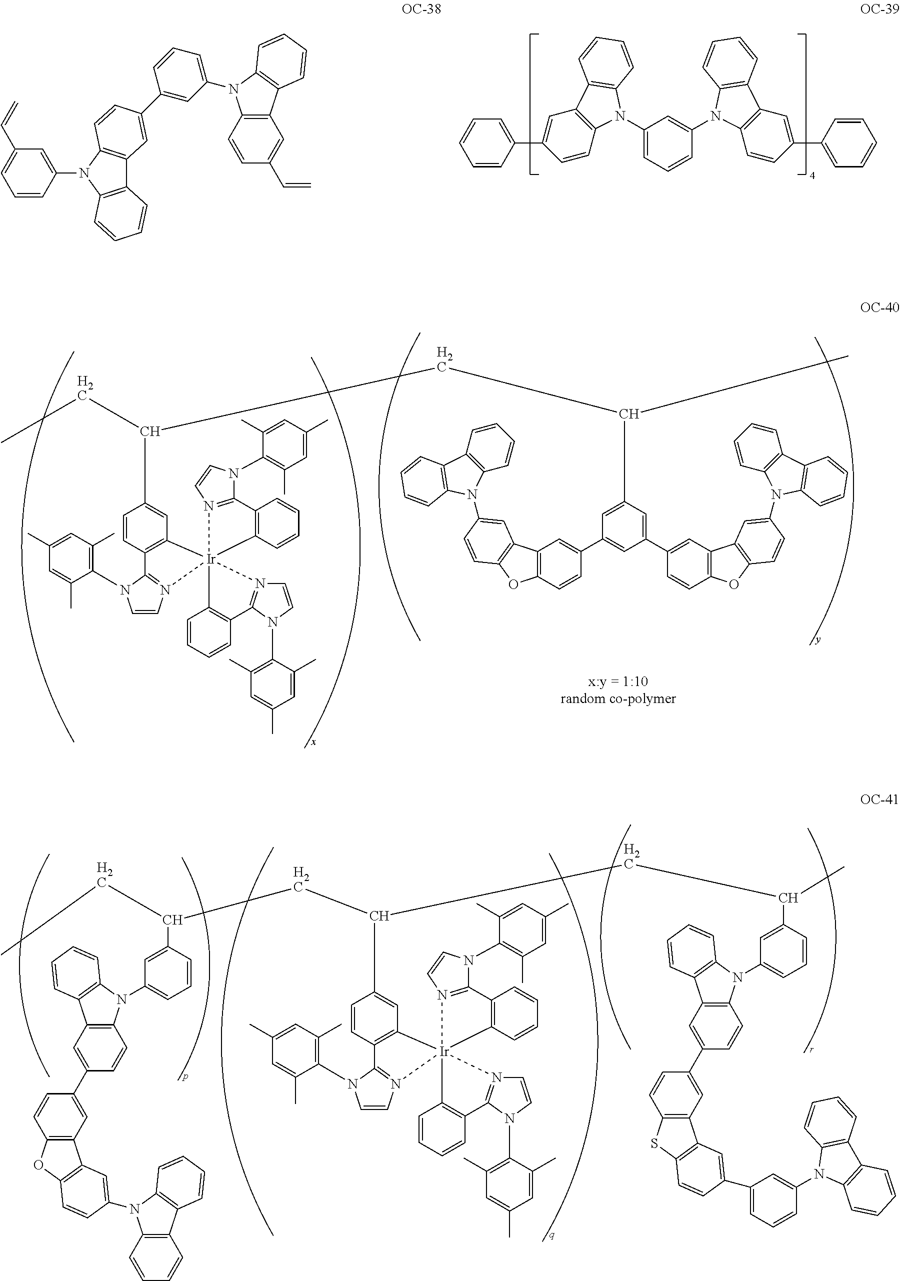

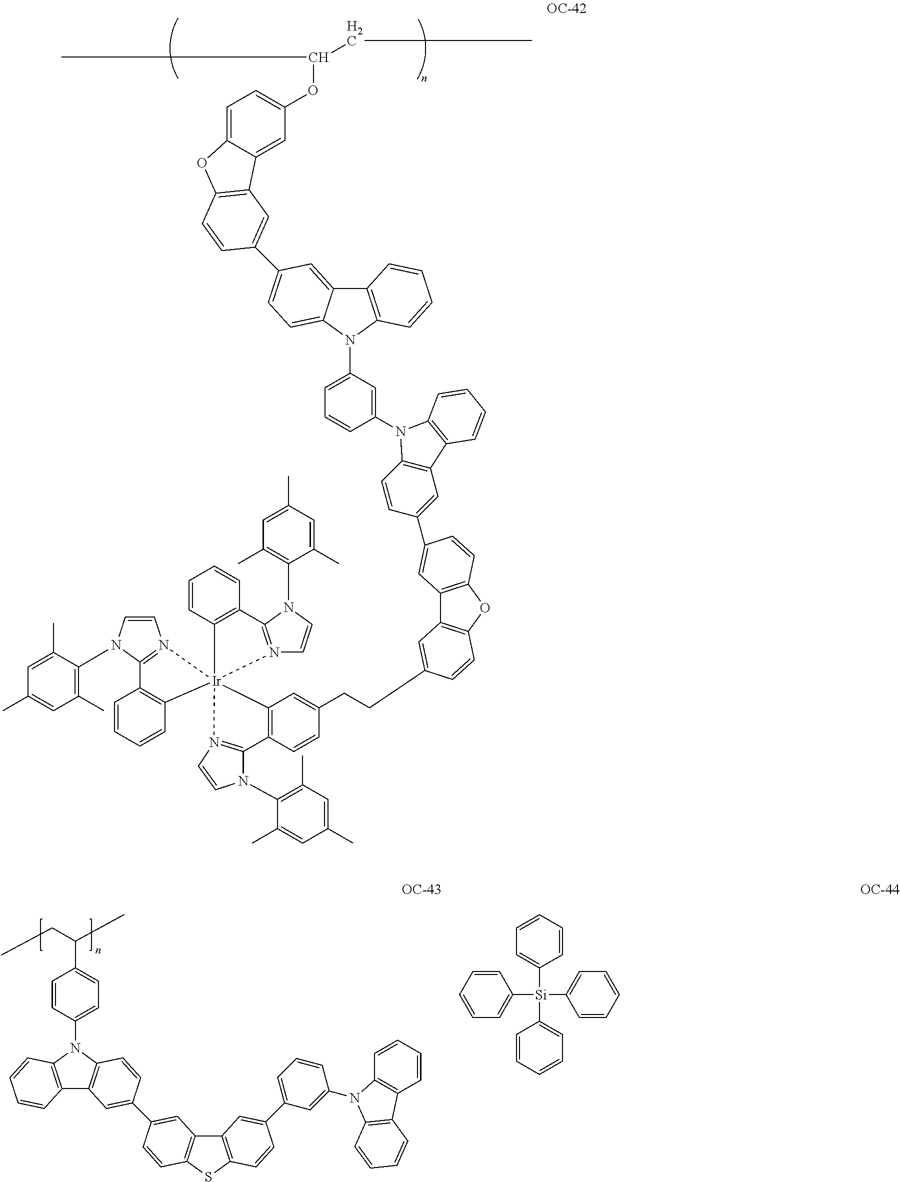

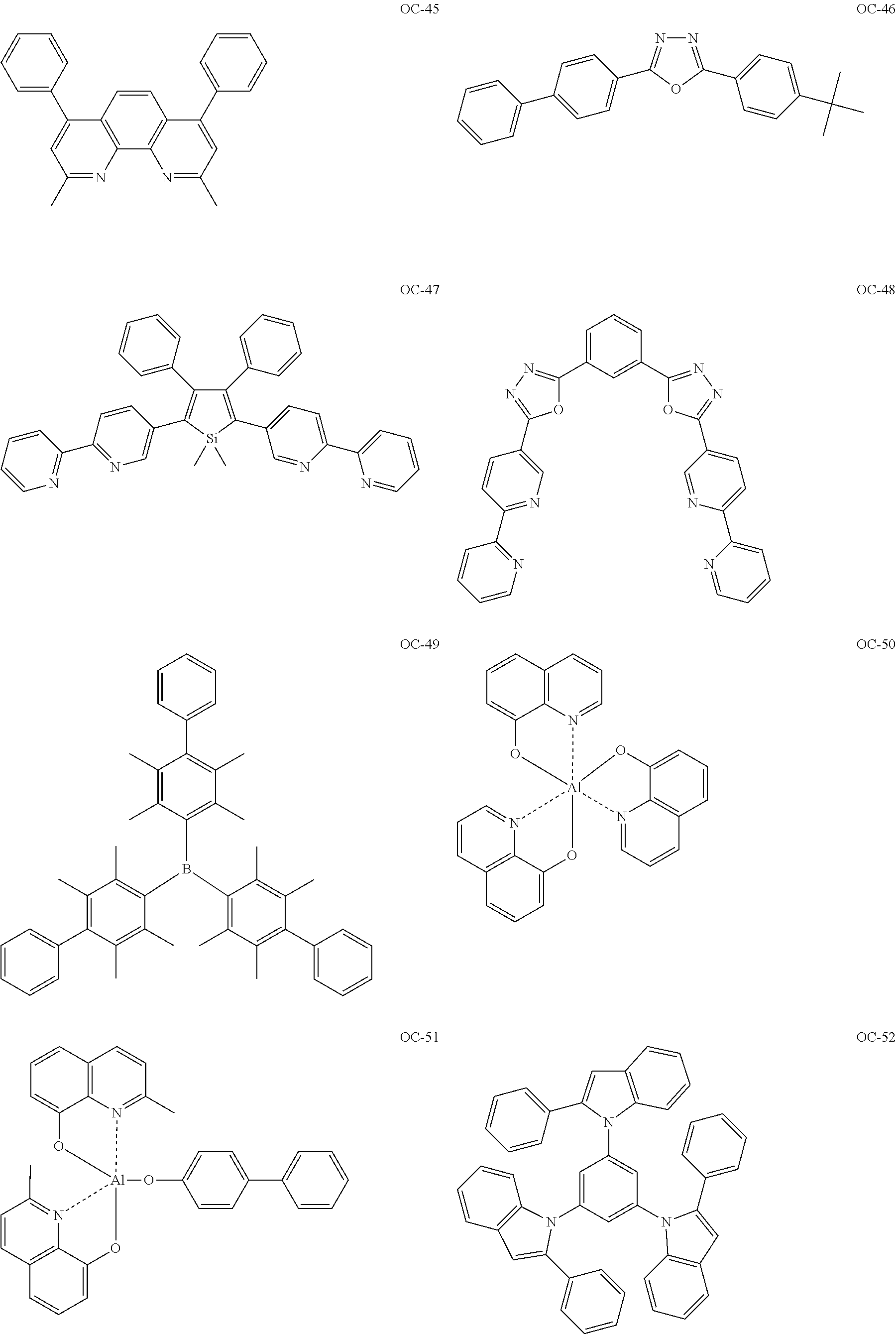

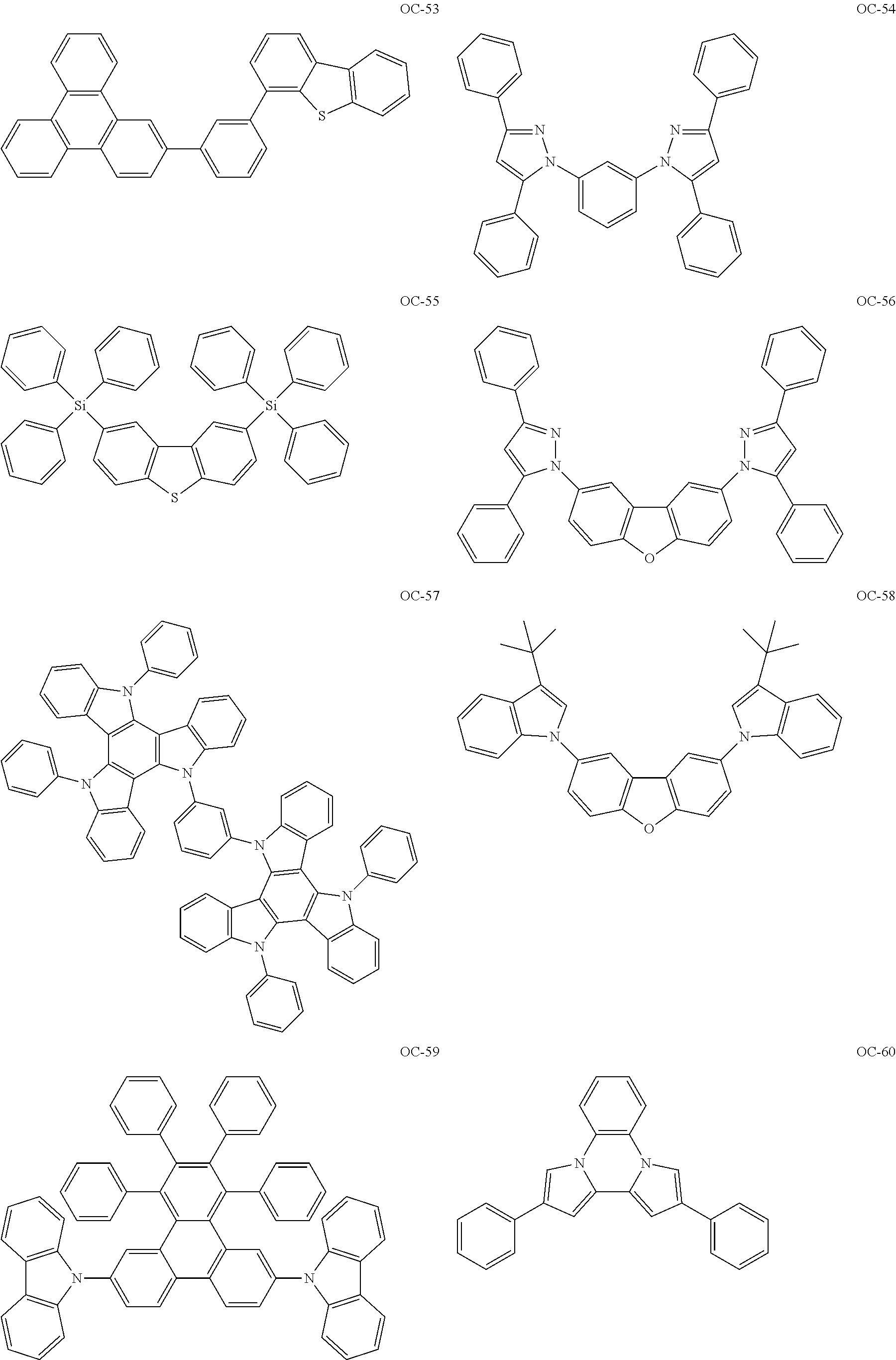

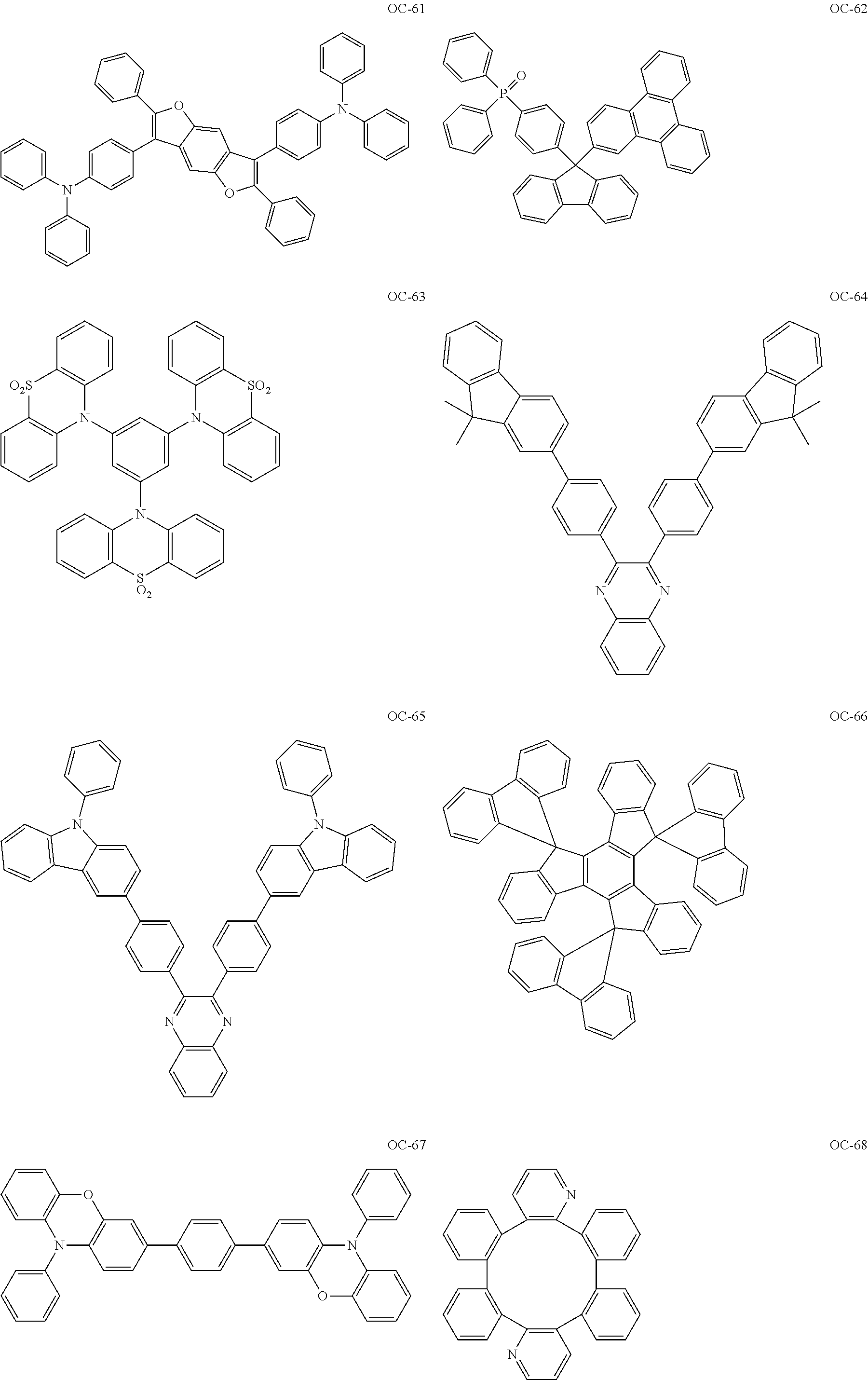

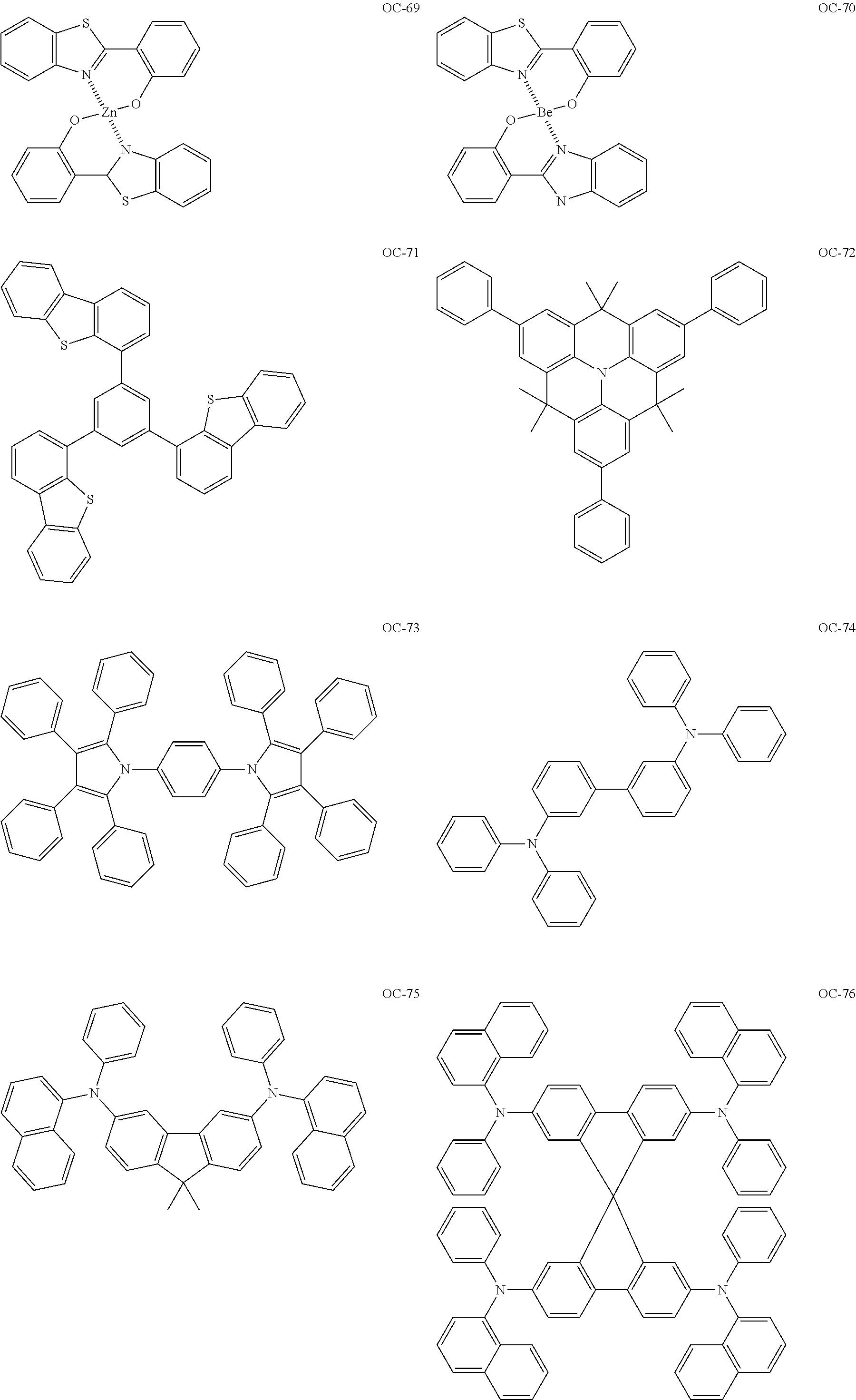

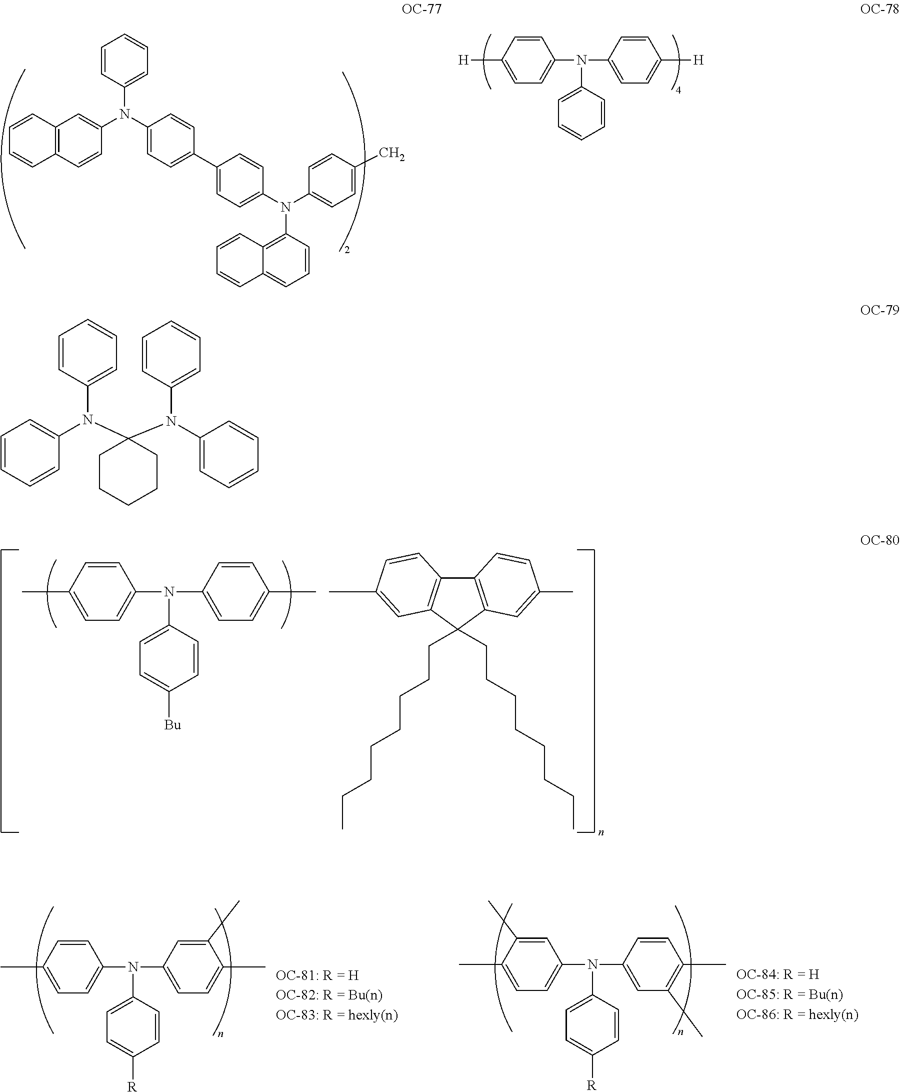

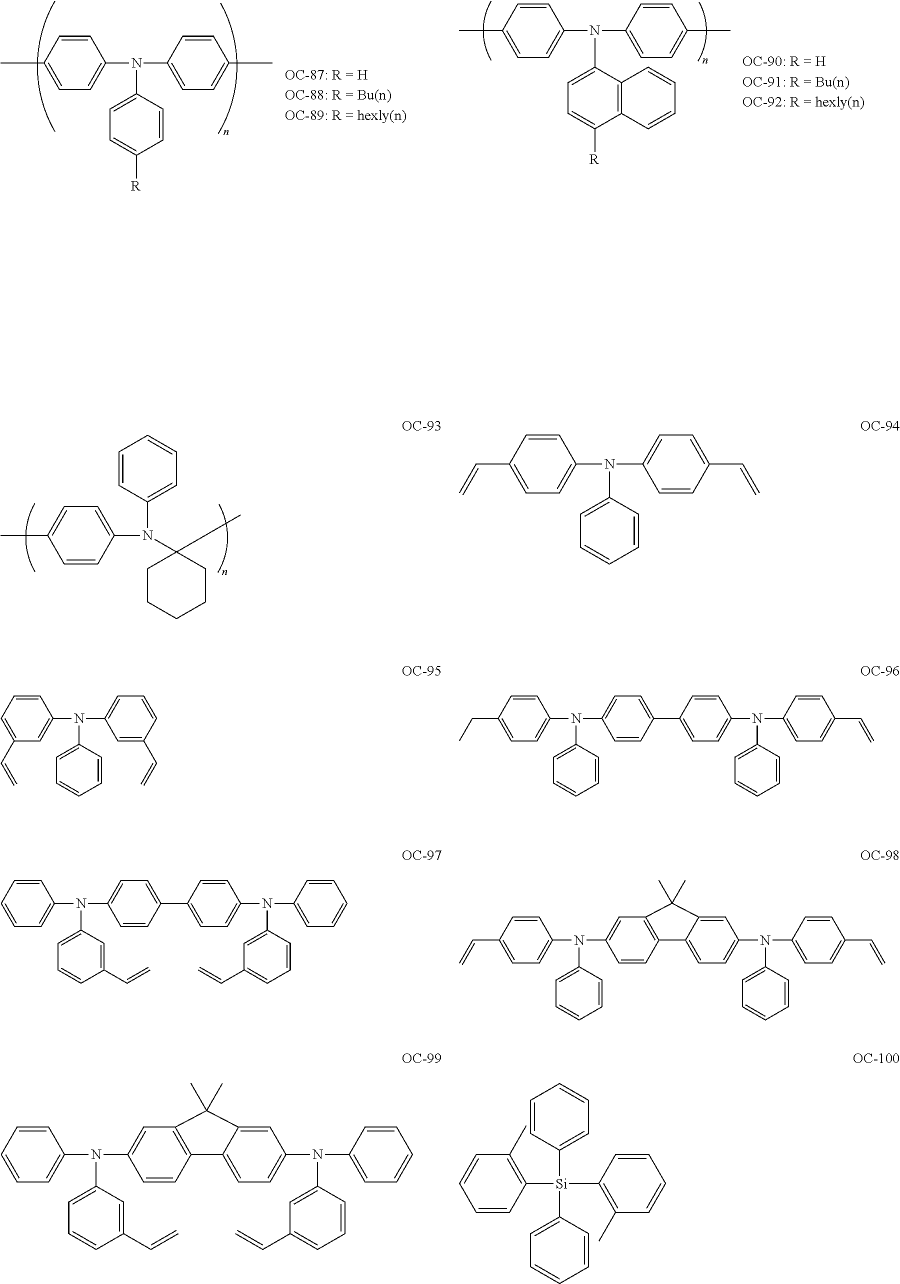

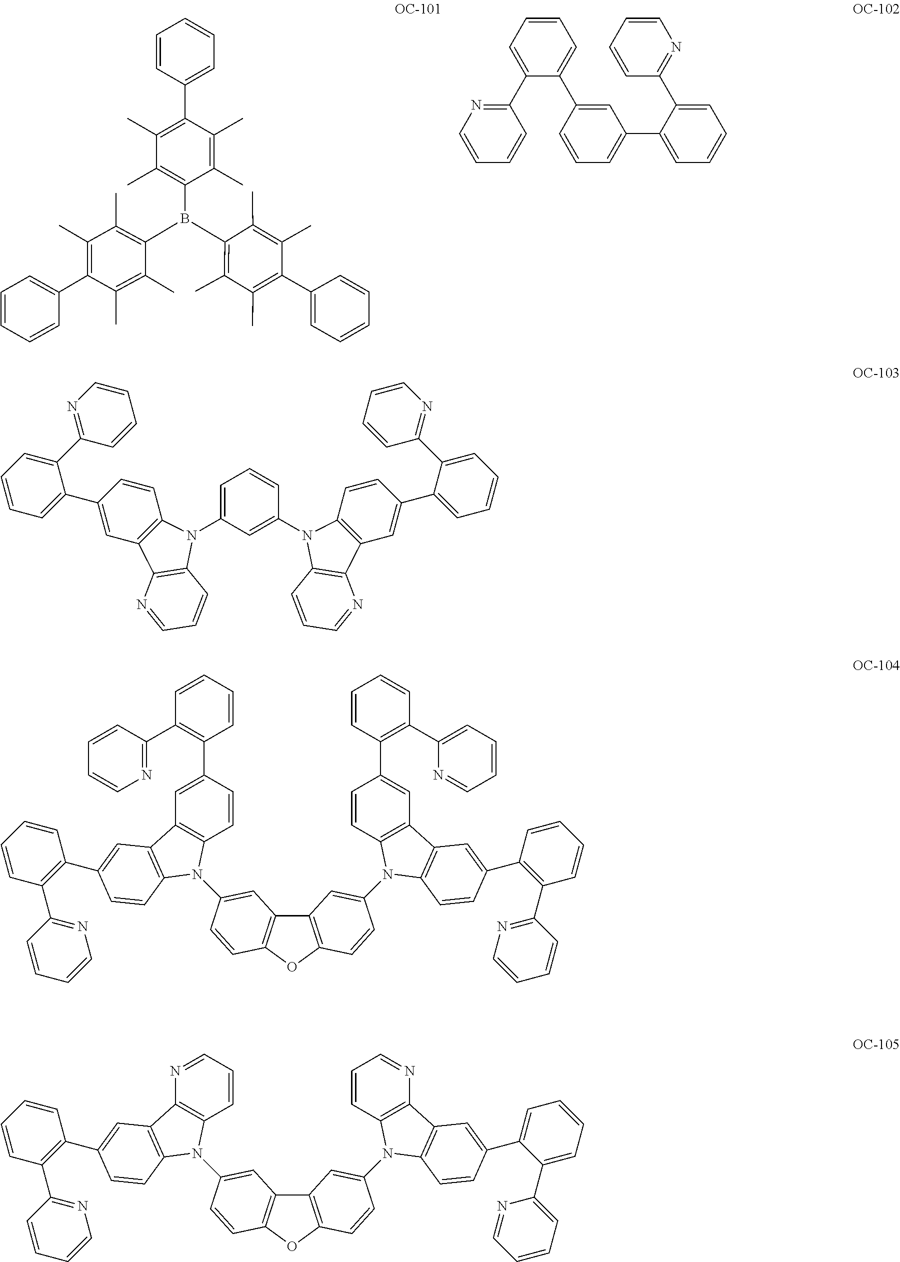

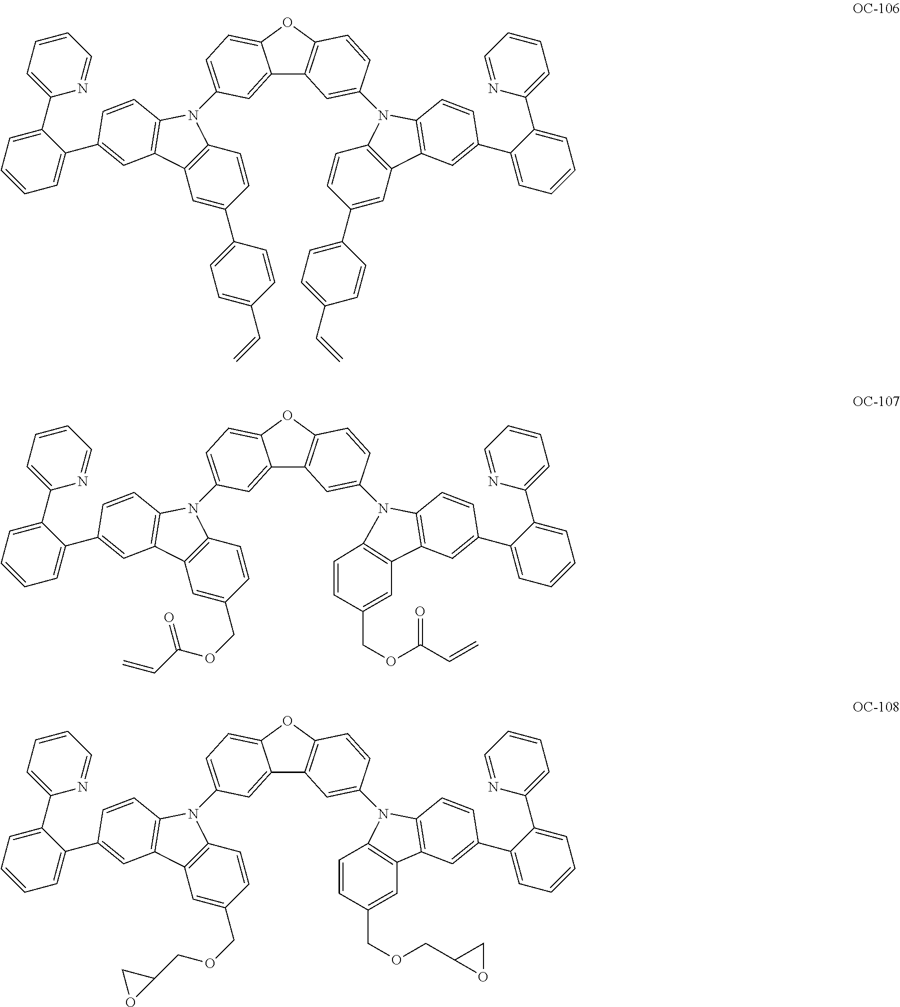

For example, JP-A Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084 and 2002-308837.

### (Light Emitting Dopant)

The light emitting dopant of the present invention will be described.

As a light emitting dopant of the present invention, a phosphorescence-emitting dopant (or called as a phosphorescence-emitting material) or a fluorescence-emitting dopant (or called as a fluorescence-emitter, a fluorescence compound or a fluorescence-emitting compound) can be used. However, in order to obtain an organic EL element having a high emission efficiency, it is preferable to incorporate both a host compound described above and a fluorescence-emitting dopant as a light emitting dopant (or simply called as an emission material) in a light emitting layer or in a light emitting unit.

### (Phosphorescence-Emitting Compound (or Phosphorescence-Emitting Dopant)

A phosphorescence-emitting dopant used in the present invention will be described.

The phosphorescence-emitting compound of the present invention is a compound, wherein emission from an excited triplet state thereof is observed, emitting phosphorescence at room temperature (25° C.) and exhibiting a phosphorescence quantum yield of at least 0.01 at 25° C. The phosphorescence quantum yield is preferably at least 0.1.

The phosphorescence quantum yield can be determined via a method described in page 398 of Bunko II of Dai 4 Han Jikken Kagaku Koza 7 (Spectroscopy II of 4th Edition Lecture of Experimental Chemistry 7) (1992, published by Maruzen Co., Ltd.). The phosphorescence quantum yield in a solution can be determined using appropriate solvents. However, it is only necessary for the phosphorescent compound of the present invention to exhibit the above phosphorescence quantum yield (at least 0.01) using any of the appropriate solvents.

Two kinds of principles regarding emission of a phosphorescence-emitting compound are cited. One is an energy transfer-type, wherein carriers recombine on a host compound on which the carriers are transferred to produce an excited state of the host compound, and then via transfer of this energy to a phosphorescence-emitting compound, emission from the phosphorescence-emitting compound is realized. The other is a carrier trap-type, wherein a phosphorescence-emitting compound serves as a carrier trap and then carriers recombine on the phosphorescence-emitting compound to generate emission from the phosphorescence-emitting compound.

In each case, the excited state energy of the phosphorescence-emitting compound is required to be lower than that of the host compound.

As the phosphorescence-emitting dopant, there may be employed any appropriate compound selected from those known in the art used in an emission layer incorporating an organic EL element.

However, the phosphorescence-emitting compound of the present invention is preferably a complex compound containing, as the central metal, a metal of the 8th-10th groups of the periodic table of the elements, but is more preferably an iridium compound (an Ir complex), an osmium compound, a platinum compound (a platinum complex compound), or a rare earth complex. Of these, an iridium compound (an Ir complex) is most preferable.

Examples of the phosphorescence-emitting compound of the present invention are listed below, but the present invention is not limited to these. The listed compounds can be synthesized via a method described, for example, in Inorg. Chem., Vol. 40, pp. 1704-1711.

The followings are examples of phosphorescent-emitting dopants of the present invention. However, the present invention is not limited by them.

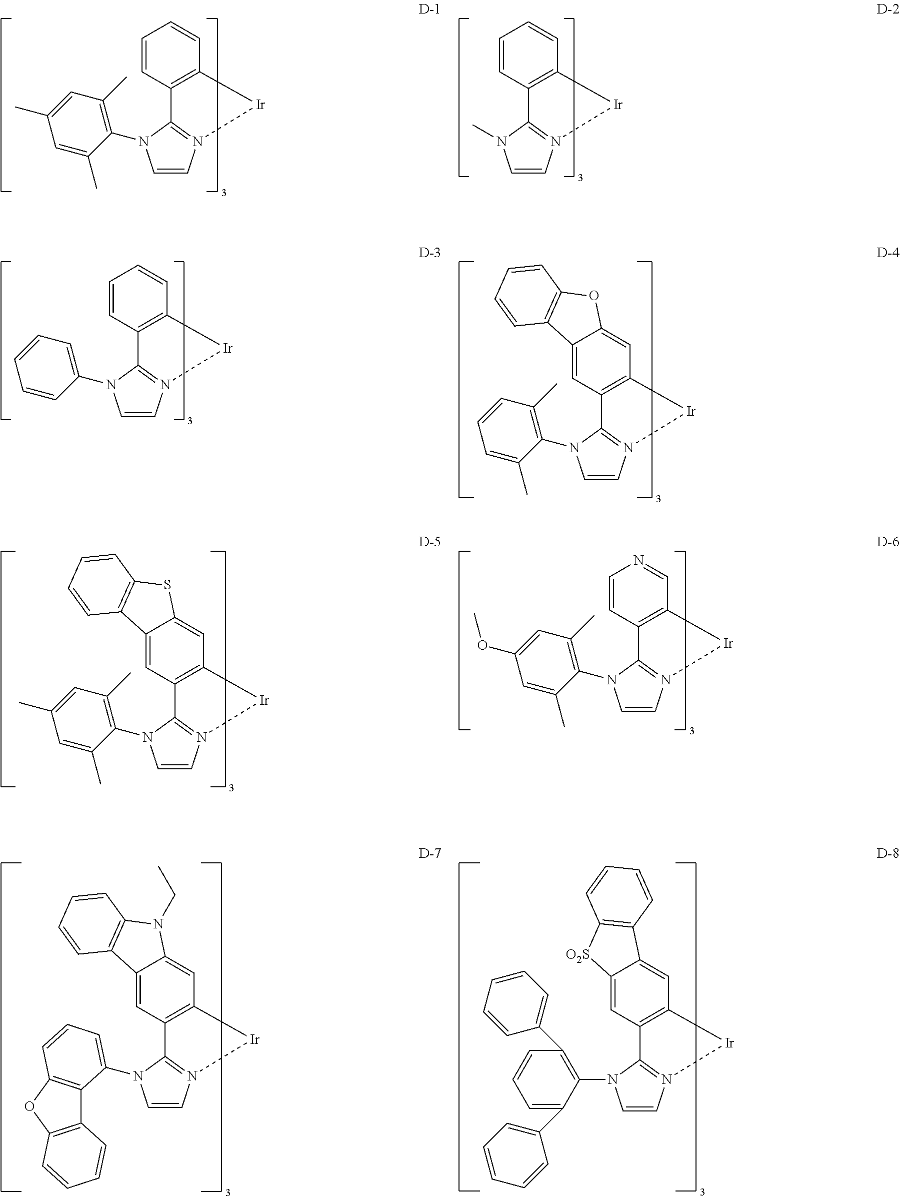

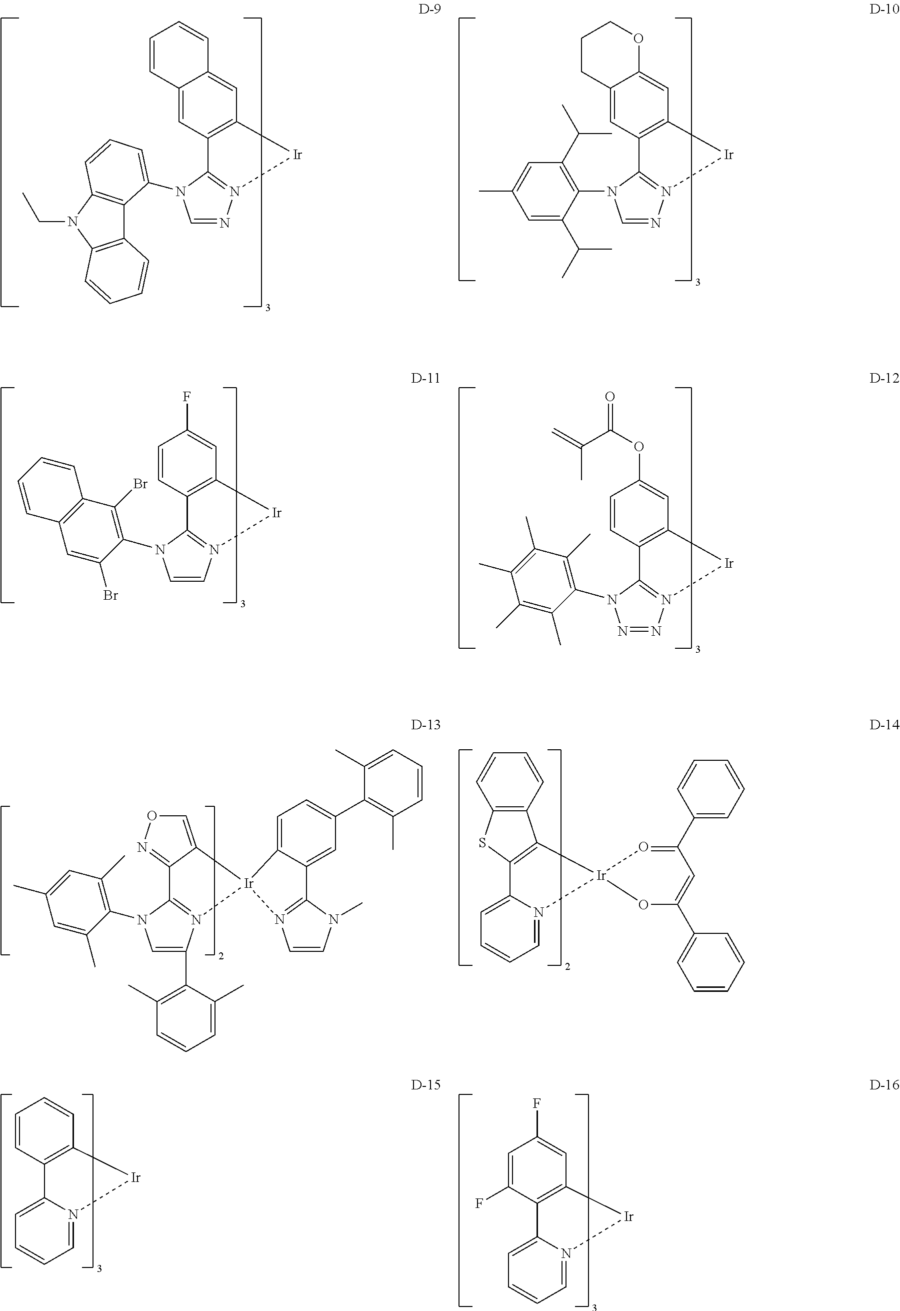

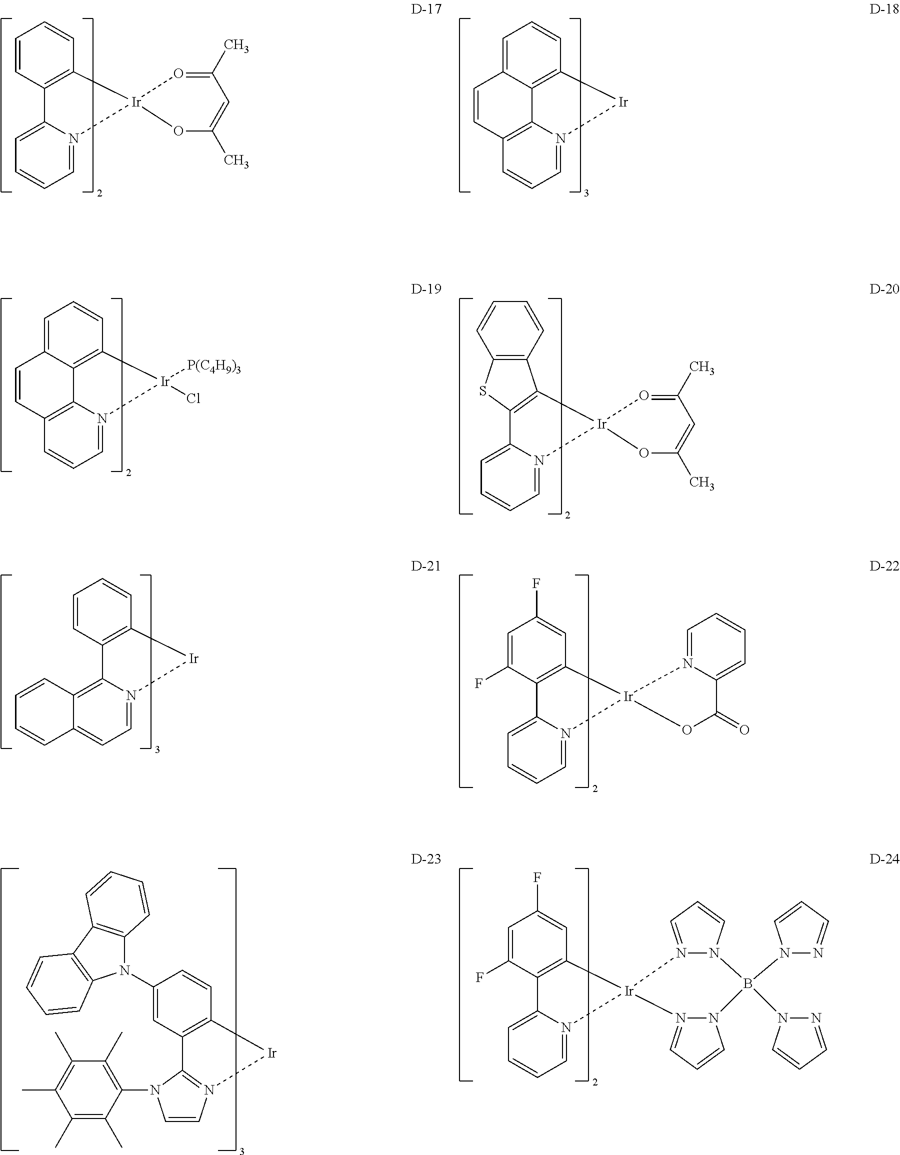

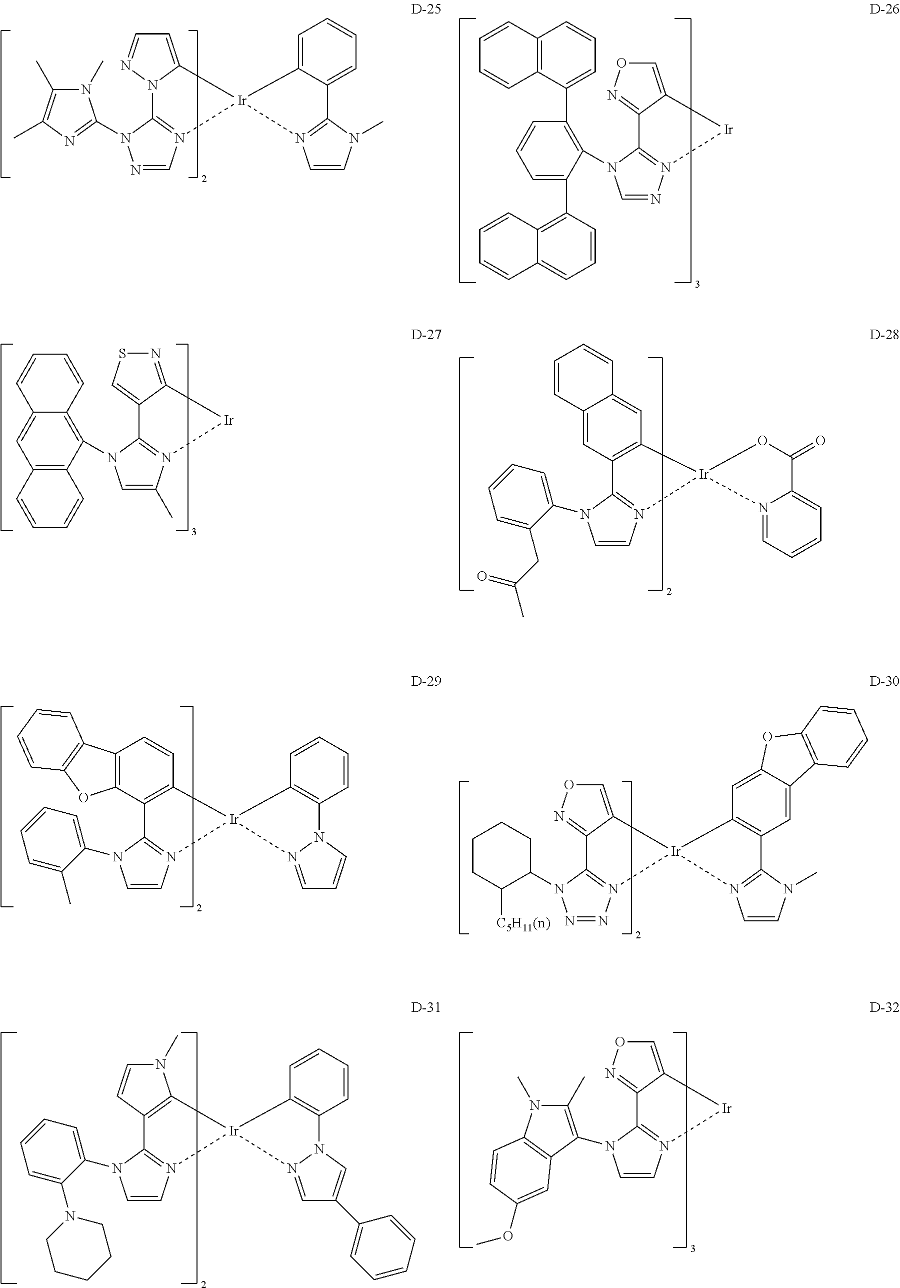

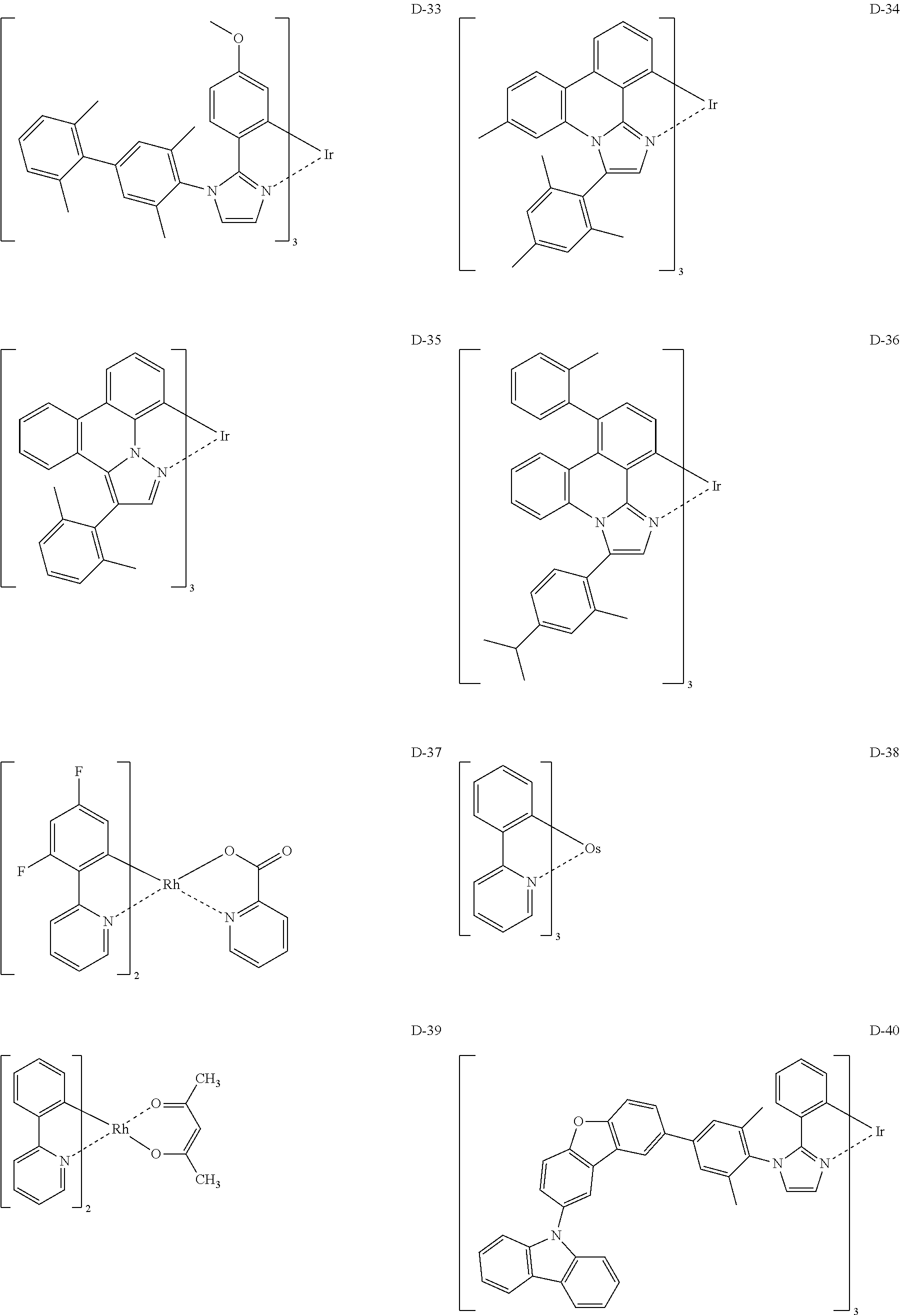

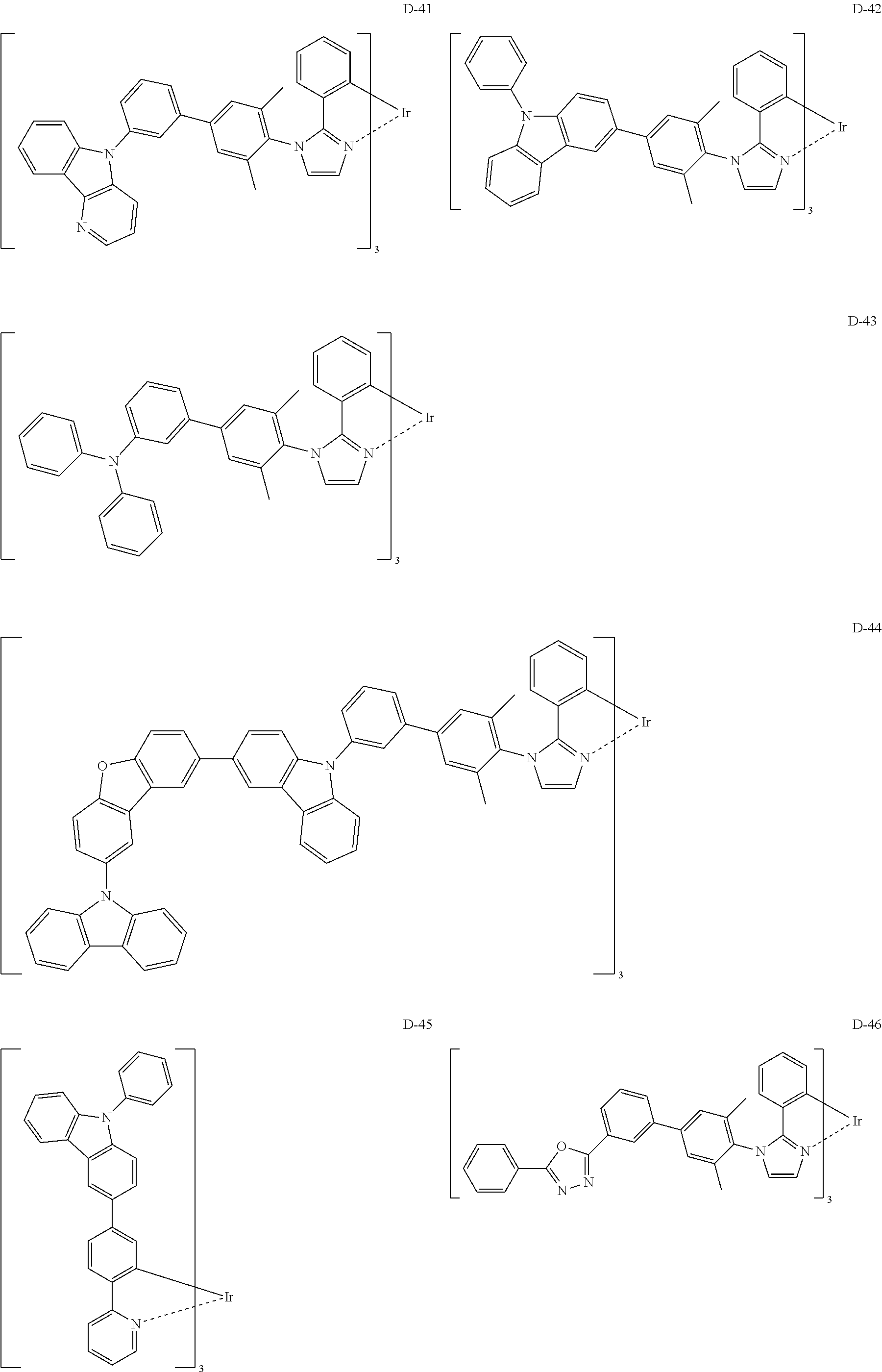

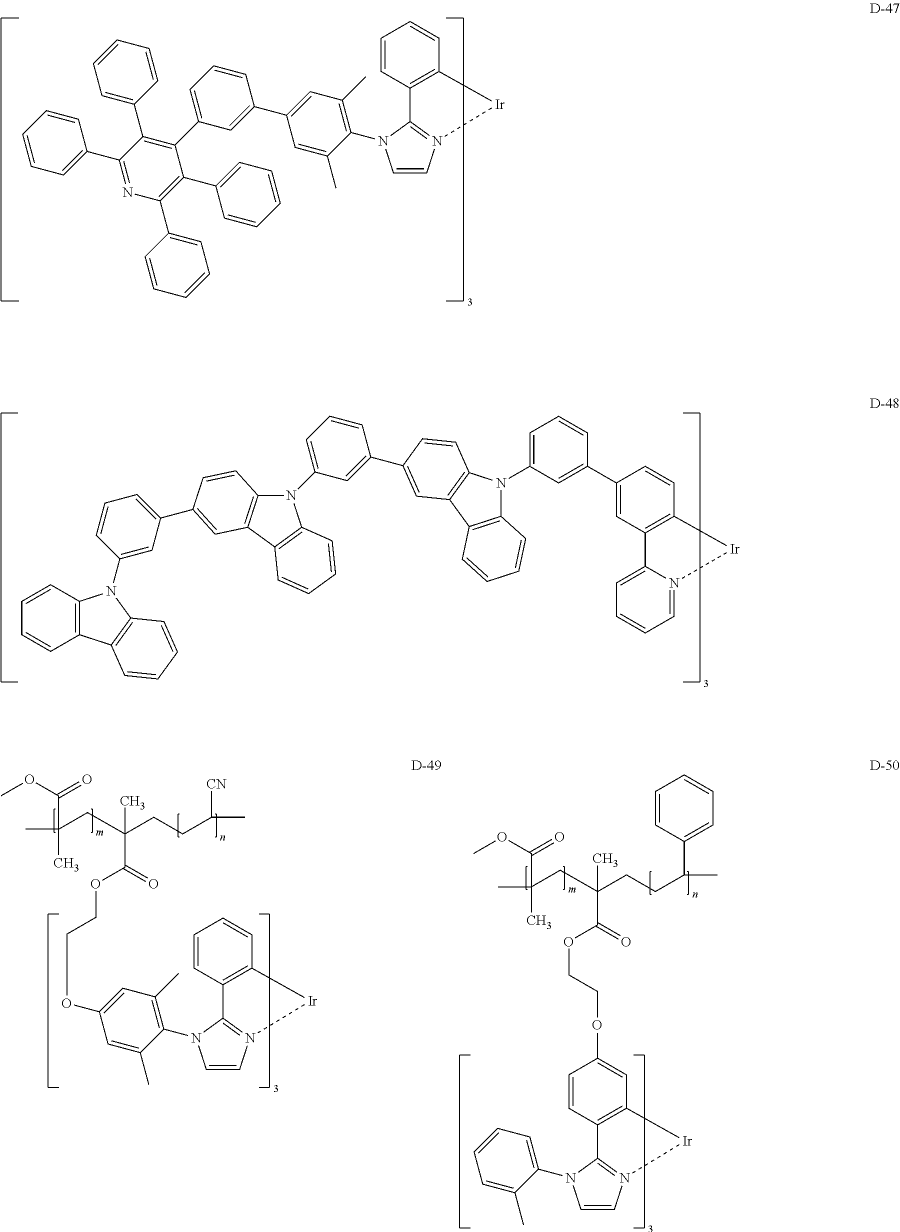

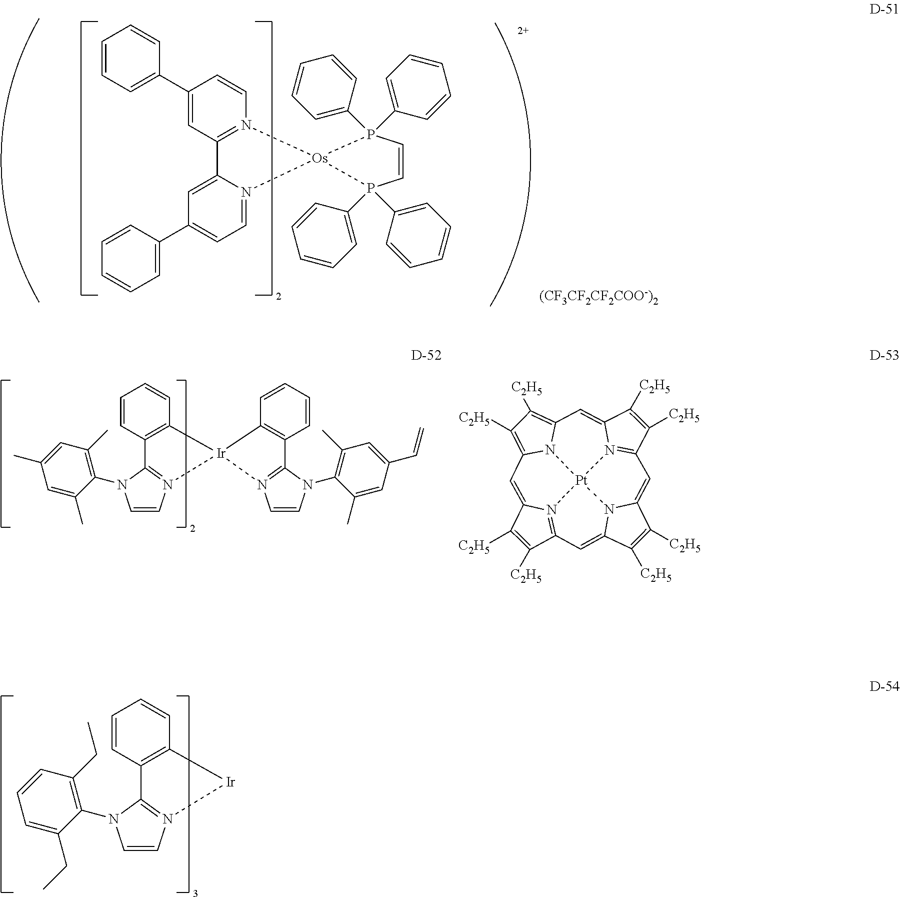

### (Fluorescence-Emitting Dopant (or Called as Fluorescence-Emitting Compound))

Examples of a fluorescence-emitting dopant (fluorescence-emitting compound) include a coumarin dye, a pyran dye, a cyanine dye, a croconium dye, a squalium dye, an oxobenzanthracene dye, a fluorescein dye, a rhodamine dye, a pyrylium dye, a perylene dye, a stilbene dye, and a polythiophene dye, and a rare earth metal complex fluorescence compound.

Next, an injection layer, a blocking layer and an electron transport layer used as constitution layers of an organic EL element of the present invention will be described.

### <<Injection Layer: Electron Injection Layer, Hole Injection Layer>>

An injection layer is appropriately provided and includes an electron injection layer and a hole injection layer, which may be arranged between an anode and an emission layer or a positive transfer layer, and between a cathode and an emission layer or an electron transfer layer, as described above.

An injection layer is a layer which is arranged between an electrode and an organic layer to decrease an operating voltage and to improve an emission luminance, which is detailed in volume 2, chapter 2 (pp. 123-166) of “Organic EL Elements and Industrialization Front thereof (Nov. 30, 1998, published by N. T. S Corp.)”, and includes a hole injection layer (an anode buffer layer) and an electron injection layer (a cathode buffer layer).

An anode buffer layer (a hole injection layer) is also detailed in such as JP-A 9-45479, 9-260062 and 8-288069, and specific examples include such as a phthalocyanine buffer layer comprising such as copper phthalocyanine, an oxide buffer layer comprising such as vanadium oxide, an amorphous carbon buffer layer, and a polymer buffer layer employing conductive polymer such as polythiophene.

A cathode buffer layer (an electron injection layer) is also detailed in such as JP-A 6-325871, 9-17574 and 10-74586, and specific examples include a metal buffer layer comprising such as strontium and aluminum, an alkali metal compound buffer layer comprising such as lithium fluoride, an alkali earth metal compound buffer layer comprising such as magnesium fluoride, and an oxide buffer layer comprising such as aluminum oxide. The above-described buffer layer (injection layer) is preferably a very thin layer, and the layer thickness is preferably in a range of 0.1 nm-5 □m although it depends on a raw material.

### <<Blocking Layer: Hole Blocking Layer, Electron Blocking Layer>>

A blocking layer is provided if needed in addition to the basic constitution layer structures in the organic thin layers of the present invention. Examples of such a blocking layer are hole blocking layers (hole block layers) described in JP-A Nos. 11-204258 and 11-204359 and p. 273 of “Organic EL Elements and Industrialization Front Thereof (Nov. 30 (1998), published by N. T. S Corp.)”.

A hole blocking layer, in a broad meaning, is provided with a function of electron transport layer, being comprised of a material having a function of transporting an electron but a very small ability of transporting a hole, and can improve the recombination probability of an electron and a hole by blocking a hole while transporting an electron.

Further, a constitution of an electron transport layer described later can be appropriately utilized as a hole blocking layer of an organic EL element according to this invention.

The hole blocking layer in the organic EL element of the present invention is preferably provided adjacent to the emission layer.

The hole blocking layer preferably incorporates an azacarbazole derivative for a host compound as described above.

In the present invention, when the organic EL element has a plurality of emission layers each emitting a different emission color, it is preferable that an emission layer emitting a light of a shortest wavelength is provided at the nearest position to the anode among all of the emission layers. In such case, it is preferable that a hole blocking layer is further provided between the aforementioned emission layer of the shortest wavelength and the emission layer secondary nearest to the anode.

Further, it is preferable that not less than 50 weight % of a compound contained in the hole blocking layer exhibits a ionization potential at least 0.3 eV larger than that of a host compound in aforementioned emission layer of the shortest wavelength.

An ionization potential is defined as a required energy to emit an electron stayed on a HOMO (highest occupied molecular orbital) of a compound to a vacuum level. The ionization potential can be obtained using the following methods, for example.

(1) Gaussian 98 (Gaussian 98, Revision A. 11. 4, M. J. Frisch, et al, Gaussian, Inc., Pittsburgh Pa., 2002), which is software for a molecular orbital calculation, and produced by Gaussian Inc. The ionization potential value of the compound of the present invention can be calculated via structure optimization employing B3LYP/6-31G* as a key word and converted in eV unit after rounded off to one decimal place. The reason for the calculated value being considered to be valid is that the calculated value obtained by the above method is in good agreement with the experimental one.

(2) An ionization potential can be directly obtained by measuring with a photoelectron spectroscopy. Such measurement can be appropriately done using, for example, a low energy photoelectron spectroscopy “Model Ac-1” made by Riken Keiki Co., Ltd or a ultra-violet photoelectron spectroscopy.

Meanwhile, an electron blocking layer has a function of a hole transport layer in a broad sense. An electron blocking layer is composed a material having a property to transport a hole and, at the same time, having a very weak property to transport an electron. It is possible to improve the recombination rate of an electron and a hole by transporting a hole and blocking an electron from transporting.

A structure of a hole transport layer can be used for an electron blocking layer. The layer thickness of the hole blocking layer and the electron transport layer according to the present invention is preferably from 3 nm to 100 nm, and is more preferably from 5 nm to 30 nm.

### <<Hole Transport Layer>>

A hole transport layer contains a material having a function of transporting a hole, and in a broad meaning, a hole injection layer and an electron blocking layer are also included in a hole transport layer. A single layer of or plural layers of a hole transport layer may be provided.

A hole transport material is those having any one of a property to inject or transport a hole or a barrier property to an electron, and may be either an organic substance or an inorganic substance. For example, listed are a triazole derivative, an oxadiazole derivative, an imidazole derivative, a polyallylalkane derivative, a pyrazolone derivative, a phenylenediamine derivative, a allylamine derivative, an amino substituted chalcone derivative, an oxazole derivatives, a styrylanthracene derivative, a fluorenone derivative, a hydrazone derivative, a stilbene derivative, a silazane derivative, an aniline type copolymer, or conductive polymer oligomer and specifically preferably such as thiophene oligomer.

As a hole transport material, those described above can be utilized, however, it is preferable to utilized a porphyrin compound, an aromatic tertiary amine compound and a styrylamine compound, and specifically preferably an aromatic tertiary amine compound.

Typical examples of an aromatic tertiary amine compound and a styrylamine compound include N,N, N′,N′-tetraphenyl-4,4′-diaminophenyl; N,N′-diphenyl-N,N′-bis(3-methylphenyl)-(1,1′ biphenyl)-4,4′-diamine (IUP); 2,2-bis(4-di-p-tolylaminophenyl)propane; 1,1-bis(4-di-p-tolylaminophenyl)cyclohexane; N,N, N′,N′-tetra-p-tolyl 4,4′-diaminobiphenyl; 1,1-bis(4-di-p-tolylaminophenyl)-4-phenylcyclohexane; bis(4-dimethylamino-2-methyl)phenylmethane; bis(4-di-p-tolylaminophenyl)phenylmethane; N,N′-diphenyl-N,N′-di(4-methoxyphenyl)-4,4′-diaminobiphenyl; N,N,N′,N′-tetraphenyl-4,4′-diaminophenylether; 4,4′-bis(diphenylamino)quarterphenyl; N,N,N-tri(p-tolyl)amine; 4-(di-p-tolylamino)-4′-[4-(di-p-triamino)styryl]stilbene; 4-N,N-diphenylamino-(2-diphenylvinyl)benzene; 3-methoxy-4′-N,N-diphenylaminostilbene; and N-phenylcarbazole, in addition to those having two condensed aromatic rings in a molecule described in U.S. Pat. No. 5,061,569, such as 4,4′-bis[N-(1-naphthyl)-N-phenylamino]biphenyl (NDP), and 4,4′,4″-tris[N-(3-methylphenyl)-N-phenylamino]triphenylamine (MDTDATA), in which three of triphenylamine units are bonded in a star burst form, described in JP-A 4-308688.

Polymer materials, in which these materials are introduced in a polymer chain or constitute the main chain of polymer, can be also utilized. Further, an inorganic compound such as a p type-Si and a p type-SiC can be utilized as a hole injection material and a hole transport material.

It can be used a so-called p type hole transport material described in JP-A 11-251067 and J. Huang et al., Applied Physics Letters 80 (2002), p. 139. It is preferable to use these compounds in the present invention because they enable to give an emission element with a high emitting efficiency.

This hole transport layer can be prepared by forming a thin layer made of the above-described hole transport material according to a method well known in the art such as a vacuum evaporation method, a spin coating method, a cast method, an inkjet method and a LB method. In the present invention, it is preferable to prepare the layer with a coating method (a coating process). The layer thickness of a hole transport layer is not specifically limited, however, is generally 5 nm 5 μm, and preferably 5 nm-200 nm. This hole transport layer may have a single layer structure composed of one or not less than two types of the above described materials.

Further, an impurity-doped hole transport layer exhibiting high p-characteristics may be used. Examples thereof include those described in JP-A Nos. 4-297076, 2000-196140, and 2001-102175, as well as J. Appl. Phys., 95, 5773 (2004).

In the present invention, such a hole transport layer exhibiting high p-characteristics is preferably used to produce a low-power-consuming element.

### <<Electron Transport Layer>>

An electron transfer layer is comprised of a material having a function to transfer an electron, and an electron injection layer and a hole blocking layer are included in an electron transfer layer in a broad meaning. A single layer or plural layers of an electron transfer layer may be provided.

In the past, when a mono or plural electron transport layers are arranged in the position nearer to the cathode with respect to an emission layer, an electron transfer material (also used as a hole blocking material) in an electron transport layer is required to have a function to transport an electron injected from a cathode to an emission layer. The compounds conventionally well known in the art can be utilised by arbitrarily selection as a material thereof.

Examples of a material utilized in this electron transfer layer (hereinafter, referred to as an electron transfer material) include such as a nitro-substituted fluorene derivative, a diphenylquinone derivative, a thiopyradineoxide derivative, a heterocyclic tetracarbonic acid anhydride such as naphthaleneperylene, carbodiimide, a fluorenylidenemethane derivative, anthraquinonedimethane and anthrone derivatives, and an oxadiazole derivative.

Further, a thiazole derivative in which an oxygen atom in the oxadiazole ring of the above-described oxadiazole derivative is substituted by a sulfur atom, and a quinoxaline derivative having a quinoxaline ring which is known as an electron attracting group can be utilized as an electron transfer material. Polymer materials, in which these materials are introduced in a polymer chain or these materials form the main chain of polymer, can be also utilized.

Further, a metal complex of a 8-quinolinol derivative such as tris(8-quinolinol)aluminum (Alq), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (Znq); and metal complexes in which a central metal of the aforesaid metal complexes is substituted by In, Mg, Cu, Ca, Sn, Ga or Pb, can be also utilized as an electron transfer material.

Further, metal-free or metal phthalocyanine, or those whose terminal is substituted by an alkyl group and a sulfonic acid group, can be preferably utilized as an electron transfer material. Further, distyrylpyrazine derivative, which has been exemplified as a material of an emission layer, can be also utilized as an electron transfer material, and, similarly to the case of a hole injection layer and a hole transfer layer, an inorganic semiconductor such as an n-type-Si and an n-type-SiC can be also utilized as an electron transfer material.

The electron transport layer can be prepared by forming a thin layer made of the above-described electron transport material according to a method well known in the art such as a vacuum evaporation method, a spin coating method, a cast method, a printing method such as an inkjet method, and a LB method.

The layer thickness of an electron transport layer is not specifically limited; however, is generally 5 nm to 5 μm, and preferably 5 nm to 200 nm. This electron transport layer may have a single layer structure comprised of one or not less than two types of the above described materials.

An electron transport layer containing a doped impurity and having a high n-property can be used. Examples are shown in JP-A 04-297076, 10-270172, 2000-196140, 2001-102175, and J. Appl. Phys., 95, 5773 (2004).

In the present invention, it is preferable to use an electron transport layer having a high n-property for achieving an element to be driven with low electric power consumption.

### <<Anode>>

As an anode according to an organic EL element of this invention, those comprising metal, alloy, a conductive compound, which is provided with a large work function (not less than 4 eV), and a mixture thereof as an electrode substance are preferably utilized.

Specific examples of such an electrode substance include a conductive transparent material such as metal like Au, CuI, indium tin oxide (ITO), SnO₂ and ZnO.

Further, a material such as IDIXO (In₂O₃—ZnO), which can prepare an amorphous and transparent electrode, may be also utilized. As for an anode, these electrode substances may be made into a thin layer by a method such as evaporation or spattering and a pattern of a desired form may be formed by means of photolithography, or in the case of requirement of pattern precision is not so severe (not less than 100 μm), a pattern may be formed through a mask of a desired form at the time of evaporation or spattering of the above-described substance.

In case that a material (such as organic electric conductive compounds) capable of being coated is used, a printing method or a wet type film-forming method such as a coating method can be applied.

When emission is taken out of this anode, the transmittance is preferably set to not less than 10% and the sheet resistance as an anode is preferably not more than a few hundreds Ω/□. Further, although the layer thickness depends on a material, it is generally selected in a range of 10 nm to 1,000 nm and preferably selected in a range of 10 nm to 200 nm.

### <<Cathode>>

On the other hand, as a cathode according to this invention, metal, alloy, a conductive compound and a mixture thereof, which have a small work function (not more than 4 eV), are utilized as an electrode substance. Specific examples of such an electrode substance includes such as sodium, sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture and rare earth metal.

Among them, with respect to an electron injection property and durability against such as oxidation, preferable are a mixture of electron injecting metal with the second metal which is stable metal having a work function larger than electron injecting metal, such as a magnesium/silver mixture, a magnesium/aluminum mixture, a magnesium/indium mixture, an aluminum/aluminum oxide (Al₂O₃) mixture and a lithium/aluminum mixture, and aluminum. As for a cathode, these electrode substances may be made into a thin layer by a method such as evaporation or spattering. It may be used a metal foil layer produced by forming a coated layer of a dispersion liquid containing metal nano particles such as silver nano ink, then calcined.

The sheet resistance as a cathode is preferably not more than a few hundreds Ω/□ and the layer thickness is generally selected in a range of 10 nm to 5 μm and preferably of 50 nm to 200 nm. Herein, to transmit emission, either one of an anode or a cathode of an organic EL element is preferably transparent or translucent to improve the mission luminance.

Further, a transparent or a translucent cathode can be made by applying a transparent conductive material on a cathode after providing the above-described metal on the cathode in a thickness of 1 nm to 20 nm which. The transparent conductive materials are described in the section for anode. By applying these materials, it can be made an element having both an anode and a cathode provided with a property of transparent.

### <<Support Substrate>>

Examples of a support substrate (or called as base, substrate, base material or support) are glass and plastics. The kinds of which are not specifically limited. They may be transparent or opaque. When an emission of light is taken from the side of support substrate, the support substrate is preferably transparent.

Examples of preferably used for a support substrate are glass, quartz, and transparent resin films. Specifically preferable support substrates are resin films which enable to give flexibility to an organic EL element.

The following can be cited as examples of a resin film.

Polyesters (e.g., polyethylene terephthalate (PET), polyethylenenaphthalate (PEN)), polyethylene, polypropylene, cellophane, cellulose esters or those derivatives (e.g., cellulose di acetate, cellulose triacetate, cellulose acetate butyrate, cellulose acetate propionate (CAP), cellulose acetate phthalate (TAC), cellulose nitrate) polyvinylidene chloride, polyvinyl alcohol, polyethylene vinyl alcohol, syndiotactic polystyrene, polycarbonate, norbornene resin, polymethyl pentene, polyether ketone, polyimide, polyether sulfone (PES), polyphenylene sulfide, polysulfones, polyetherimide, polyether ketoneimide, polyamide, fluororesin, nylon, polymethylmethacrylate, acrylic resins, or polyarylates, cycloolefin resins (e.g., ARTON (trade name made by JSR), or APEL (trade name made by Mitsui Chemicals, Inc).

On the surface of the resin film, a film of inorganic or organic compounds or a hybrid film of both of them may be formed. The above film is preferably a barrier film exhibiting a water vapor permeability of at most 0.01 g/(m²·24 h) (at 25±0.5° C. and 90±2% RH), which is determined based on the method of JIS K 7129-1992. Further, the above film is preferably a high barrier film exhibiting an oxygen permeability of at most 10⁻³ cm³/(m²·24 h·MPa) determined based on the method of JIS K 7126-1987 and the water vapor permeability exhibiting at most 10 g/(m²·24 h).

Any materials may be employed to form the bather film as long as they exhibit the function to retard penetration of substances such as moisture or oxygen, which will lead to degradation of the element, and the materials such as silicon oxide, silicon dioxide, or silicon nitride may be employed. Further, in order to reduce brittleness, it is preferable to form a laminated layer structure composed of a layer comprising the above inorganic material, and a layer comprising an organic material.

The lamination order of the inorganic and organic layers is not particularly limited, but it is preferable that both layers are alternated several times.

Formation methods of the barrier film are not particularly limited, and it is possible to employ, for example, a vacuum deposition method, a sputtering method, a reactive sputtering method, a molecular beam epitaxial method, a cluster ion beam method, an ion plating method, a plasma polymerization method, an atmospheric pressure plasma polymerization method, a plasma CVD method, a laser CVD method, a thermal CVD method, and a coating method. Of these, particularly preferred is the atmospheric pressure plasma polymerization method, as described in JP-A No. 2004-68143.

Examples of opaque substrates include metal plates or films such as aluminum or stainless steel, opaque resin substrates, and substrates composed of ceramic materials.

The quantum efficiency of light extraction to the outside of the light emission of the organic EL element of the present invention at room temperature is preferably at least 1%, and more preferably at least 5%.

Herein, quantum efficiency of light extraction to the outside (%)=(the number of photons emitted to the exterior of the organic EL element)/(the number of electrons supplied to the organic EL element)×100.

A hue improving filter such as a color filter, or a color conversion filter, which converts emitted light color from an organic EL element to multi-color by employing a fluorescent compound, may be used in combination. In the case where the color conversion filter is used, the λmax of the light emitted from the organic EL element is preferably not more than 480 nm.

### <<Sealing>>

Sealing means employed in the present invention include, for example, a method which allows a sealing member to adhere to an electrode and a substrate employing adhesives.

Any sealing member may be employed as long as they are arranged to cover the display region of the organic EL element, and may be either in the form of an intaglio plate or a flat plate. Further, properties of transparency or electric insulation are not particularly required.

Specific examples include a glass plate, a polymer plate/film, and a metal plate/film. Glass plates may include specifically soda-lime glass, barium and strontium containing glass, lead glass, aluminosilicic acid glass, borosilicic acid glass, barium borosilicic acid glass, and quartz. Polymer plates may include polycarbonate, acryl, polyethylene terephthalate, polyether sulfide, and polysulfone. Metal plates may be composed of at least one metal selected from the group consisting of stainless steel, iron, copper, aluminum, magnesium, nickel, zinc, chromium, titanium, molybdenum, silicon, germanium and tantalum, or an alloy composed of at least two metals selected from the above group.

In the present invention, polymer or metal films may be preferably employed since they can make the element thinner. Furthermore, it is preferable that the polymer film exhibits an oxygen permeability of at most 1×10⁻³ cm³/(m²·24 h·MPa), which is determined by the method based on JIS K 7126-1987, and a water vapor permeability of at most 1×10⁻³ g/(m²·24 h) (at 25±0.5° C. and 90±2% RH), which is determined by the method based on JIS K 7129-1992.

In order to process a sealing member to form a concave shape, sand blasting or chemical etching may be employed.

Specific examples of an adhesive include photocurable and thermocurable type adhesives having a reactive vinyl group of acrylic acid oligomers and methacrylic acid oligomers, and moisture curable type adhesives such as 2-cyanoacrylic acid ester.

Thermal and chemical curing type (two blended liquids) adhesives such as an epoxy adhesive are also included. Hot-melt type polyamide, polyester, and polyolefin are also included. Further, cationically curable type ultraviolet ray curable type epoxy resin adhesives are included.

Since organic EL elements are occasionally degraded due to a thermal treatment, adhesives which are adhesion-curable at from room temperature to 80° C. are preferred. Further, desiccants may be dispersed into the above adhesives. Application of the adhesives onto the sealing portion may be achieved by employing a commercial dispenser or may be printed in the same manner as screen printing.

Further, inorganic and organic material layers are appropriately formed as a sealing film in such a way that from exterior of an electrode facing the substrate, of the two electrodes sandwiching the organic layer, the aforesaid electrode and organic layer are covered and the sealing film contacts the substrate. In this case, any appropriate materials may be applied to the aforesaid film which exhibit a function to retard penetration of substances such as moisture and oxygen, which substances will lead to degradation of the element, and materials such as silicon oxide, silicon dioxide, or silicon nitride may be employed. Further, in order to reduce brittleness, it is preferable to form a laminated layer structure composed of an inorganic layer and a layer composed of organic materials.

Preparation methods of the above films are not particularly limited, and it is possible to employ, for example, a vacuum deposition method, a sputtering method, a reactive sputtering method, a molecular beam epitaxial method, a cluster ion beam method, an ion plating method, a plasma polymerization method, an atmospheric pressure plasma polymerization method, a plasma CVD method, a laser CVD method, a thermal CVD method, and a coating method.

Into the space between the sealing member and the display area of the organic EL element, in the case where the space is to be a gas or liquid phase, inert gases such as nitrogen and argon or inert liquids such as fluorinated hydrocarbon and silicone oil are preferably injected. The space may also be a vacuum space. Further, hygroscopic compounds may be enclosed within the interior.

Examples of the hygroscopic compounds include metal oxides (for example, sodium oxide, potassium oxide, calcium oxide, barium oxide, magnesium oxide, or aluminum oxide), sulfates (for example, sodium sulfate, calcium sulfate, magnesium sulfate, or cobalt sulfate), metal halides (for example, calcium chloride, magnesium chloride, cesium fluoride, tantalum fluoride, cerium bromide, magnesium bromide, barium iodide, or magnesium iodide), and perchlorates (for example, barium perchlorate or magnesium perchlorate). In sulfates, metal halides and perchlorates, anhydrous salts are suitably employed.

### <<Protective Film and Protective Plate>>

To enhance mechanical strength of the element, a protective film or a protective plate may be provided on the exterior of the above sealing film which was provided on the side facing a substrate, while sandwiching the organic layer.

Specifically, in the case where the sealing is conducted via the above sealing film, the resulting strength is not always sufficient. Consequently, it is preferable to provide the above protective film or protective plate. As usable materials for the above, glass plates, polymer plate/film, and metal plate/film which are the same as those employed for the above sealing may be employed. In view of allowing the element to be lighter and thinner, it is preferable to employ a film.

### <<Light Extraction>>

It is commonly stated that the organic EL element emits light in a layer exhibiting a higher refractive index (being about 1.7 to about 2.1) than that of air, whereby only about 15 to 20% of light emitted in the light emitting layer can be taken out.

The reasons for the above are as follows: the light incoming to the interface (the interface between the transparent substrate and air) at angle □ which is greater than the critical angle is totally reflected, whereby no light is taken out to the exterior of the element; and the light is totally reflected between the transparent electrode or the light emitting layer and the transparent substrate so that the light is waveguided through the transparent electrode or the light emitting layer, and as a result the light escapes to the side direction of the element.

Means to increase the light extraction efficiency include, for example, a method in which irregularity is formed on the surface of the transparent substrate so that total reflection at the interface between the transparent substrate and air is minimized (U.S. Pat. No. 4,774,435); a method in which efficiency is enhanced by allowing the substrate to exhibit light focusing properties (JP-A No. 63-314795); a method in which a reflective surface is formed on the side of the element (JP-A No. 1-220394); a method in which a flat layer exhibiting an intermediate refractive index is introduced between the substrate and the light emitting body, whereby an reflection inhibiting film is formed (JP-A No. 62-172691); a method in which a flat layer exhibiting a refractive index lower than that of the substrate is introduced between the above substrate and the light emitting body (JP-A No. 2001-202827); and a method in which a diffraction grating is arranged between any layers of the substrate, the transparent electrode layer and the light emitting layer (including between the substrate and the exterior) (JP-A No. 11-283751).

In the present invention, the above methods may be employed in combination with the organic EL element of the present invention. However, there may be suitably employed the method to introduce a flat layer exhibiting a lower refractive index than that of the substrate between the above substrate and the light emitting body, or the method to arrange a diffraction grating between any layers of the substrate, the transparent electrode layer and the light emitting layer (including between the substrate and the exterior).

By combining these methods, the present invention enables preparation of the element which exhibits higher luminance and more excellent durability.

In the case where a medium exhibiting a low refractive index is formed at a thickness greater than the wavelength of light between the transparent electrode and the transparent substrate, the lower the refractive index of the medium, the higher the efficiency of extraction of the light, emitted from the transparent electrode, to the outside.

Examples of the medium of the low refractive index layer include aerogel, porous silica, magnesium fluoride, and fluorine based polymers. Since the refractive index of the transparent substrate is commonly about 1.5 to 1.7, the refractive index of the above low refractive index layer is preferably at most 1.5, and more preferably at most 1.35.

Further, the thickness of the low refractive index medium is preferably at least twice the wavelength in the medium. The reason is that when the thickness of the low refractive index medium is about light wavelength so that electromagnetic wave leaked out via evernescent enters into the substrate, effects of the low refractive index layer are reduced.

A method to introduce a diffraction grating at the interface which results in total reflection or into any of the media is characterized in that increased effects of the light extraction efficiency is high.

In the above method, of light generated from the light emitting layer, the light, which is not capable of escaping to the exterior due to total reflection at the boundary between two layers, is diffracted via an introduction of the diffraction grating between any layers or within the medium (in the transparent substrate or the transparent electrode) by utilizing properties of the diffraction grating in which it is possible to change the direction of light to a specified direction differing from diffraction via so-called Bragg diffraction, such as primary diffraction or secondary diffraction, to result in the light being extracted to the outside.

It is preferable that the introduced diffraction grating exhibits a two-dimensional periodical refractive index. Since the light emitting layer randomly emits light in all directions, in a general one-dimensional diffraction grating, which exhibits a cyclic refractive index distribution only in a certain direction, only the light directed to a specified direction is diffracted whereby the light extraction efficiency is not so increased.

However, by employing the refractive index of a two-dimensional distribution, the light directing to all directions is diffracted to increase the light extraction efficiency.

The location of the diffraction grating may be, as described above, between any layers or in a medium (in a transparent substrate or a transparent electrode), but a position near the organic light emitting layer where light is emitted is preferred.

In such a case, the period of the diffraction grating is preferably about half to about 3 times the wavelength of the light in the medium.

With regard to the arrangement of the diffraction grating, a two-dimensionally repeating arrangement such as a square lattice shape, a triangle lattice shape, or a honeycomb shape is preferred.

### <<Light Focusing Sheet>>

In the organic EL element of the present invention, it is possible to enhance luminance in a specified direction by focusing light to the specified direction such as the front direction with regard to the light emitting surface of the element, which can be achieved by processing the element to, for example, provide a microlens array structure or by combining the element with a so-called light focusing sheet on the light extracting side of the substrate.

An example of the above microlens army is that quadrangular pyramids are two-dimensionally arranged on the light extracting side of the substrate in such a manner that one side is 30 μm and the vertex angle is 90 degrees. The side is preferably 10 μm to 100 μm. In the case where the side is shorter than the above length, undesirable diffraction effects occur to result in unwanted coloration, while in the case where the side is excessively long, the thickness undesirably increases.

As the light focusing sheet, it is possible to employ, for example, those which are currently used in LED backlights of liquid crystal display devices. As an example of such a sheet, the luminance enhancing film (BED, produced by Sumitomo 3M Co., Ltd., may be employed. As the shape of a prism sheet, examples may include a sheet in which a stripe of triangles is formed on the substrate, which stripe exhibits a vertex angle of 90 degrees and a pitch of 50 μm, or may be a sheet exhibiting shapes such as a rounded vertex, randomly varying pitches, and the like.

Further, to control the radiation angle of light from the light emitting element, a light diffusion plate/film may be combined with the focusing sheet. For example, the light diffusion film (LIGHT-UP), produced by Kimoto Co., Ltd. may be employed.

### <Insolubilization>

In an organic EL element of the present invention which has a multi-unit structure produced by a wet process using a non-discharge type coating process, there may occur a problem which does not occur in a production using a dry process represented by a vacuum deposition. In particular, there may be induced a problem of a damage of an underlaying layer by a coating solvent when an upper layer is formed by laminating. Many inventions have been accomplished until now about a layer lamination method by a wet process. For example, it is disclosed a lamination technology in which the upper layer materials are dissolved in a solvent having a solubility parameter outside the dissolving range of the main material of the underlaying layer, by this, it can laminate the upper layer without producing disturbance of the surface of the under layer thin film (for example, refer to JP-A No. 2002-299061). In the present invention, such a well-known technology can be used when forming a multi-unit structure, but it is desirable to use a positive insolubilization technology as shown below.

The insolubilization used in the present invention is the method as follows: after forming a film with a coating process, the insolubilization process shown below is performed to change the film in an inert state which is insoluble to a test solvent later mentioned and enables to restrain elution or diffusion of a solute component.

The insolubilization process of the present invention will be described.

(1) Restrain of Solvation

Dissolution is a phenomenon in which a solute is solvated and diffused in a solvent, and here, insolubilization is attempted to achieve by restrain of solvation or restrain of diffusion. Although examples of an insolubilization treatment method is shown below, the present invention is not limited to these.

(a) Use of a High Molecular Weight Material or a High Molecular Weight Polymerized Material:

The diffusion of a solute into a solvent is restrained by decreasing a ratio of solvation to control the solvation, and at the same time, by decreasing the diffusion of a solute. In the present invention, “a high molecular weight material” is a condensed aromatic ring derivative or a condensed hetero aromatic ring derivative having a molecular weight of 800 to 1,500, more preferably it is a condensed aromatic ring derivative or a condensed hetero aromatic ring derivative having a molecular weight of 800 to 1,200.

Further, “a high molecular weight polymerized material” indicates: vinyl polymer, polyester, polyamide, polyether, polysulfide, polyimide, and polyarylene, each having a number average molecular weight of 10,000 to 1,000,000.

(b) Film Surface Reforming:

The diffusion of a solvent into a solute is restrained by a surface modification process using electron beams, ultraviolet lights, corona discharge, or plasma; or by control of a surface free energy using surface localization of the substituent described in: Macromolecules 1996, 29, 1229-1234, or DIC Technical Review No. 7/2001.

(2) Use of Chemical Change to an Insoluble Material:

After coating a solution to form a film, the coated film is changed into a state in which re-dissolution is not possible by applying an inner or external stimulus of heat, light or electromagnetic wave to produce chemical or physical change. Although examples of an insolubilization treatment method are shown below, the present invention is not limited to these.

(a) Cross-Linking Reaction:

This is a method performing multi-dimensional cross-linkage by applying a stimulus of heat, light, or electromagnetic waves after coating and forming a film using a plurality of cross-linking groups (polymerizable groups) remaining in a low molecular weight material, a high molecular weight material or a high molecular weight polymerized material. It may be used together a heat and photopolymerization initiator, or a cross-linking agent.

Hereafter, as a cross-linking group which can be used in the present invention, a partial structure represented by Formula (100) is cited. Each cross-linking group may be used independently, or may be used combining plurality.

L-P Formula (100)

“L” represents a single bond or a divalent linking group; and “P” represents a polymerizable group shown below.

Usable divalent linking groups are: an alkylene group, an alkenylene group, an arylene group, a hetero arylene group, —O—, —S—, —NR—, —CO—, —COO—, —NRCO—, —SO₂—, or a divalent linking group by combining these groups.

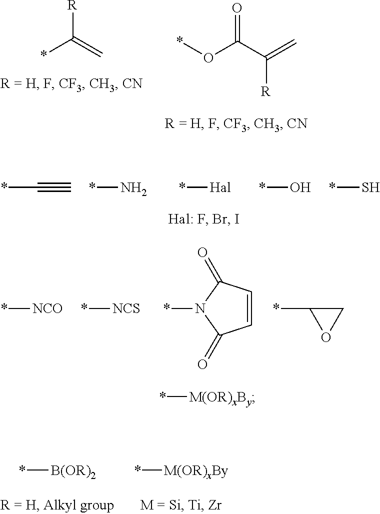

Wherein R represents an alkyl group, “x” is an integer of 2 or more, and “y” pieces of substituent B are bonded to satisfy the valence of a metal M. When a plurality of Bs exist, they may be the same or different. Examples of B include: an alkyl group, an alkenyl group, an alkynyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, a heteroaryl group, a heteroaryl group, a heteroaryloxy group,

a heteroarylthio group, a heteroarylalkyl group, a hetero arylalkoxy group, a heteroarylalkylthio group, a heteroarylalkenyl group, a heteroarylalkynyl group, an amino group, a substituted amino group, a silyl group, a substituted silyl group, a halogen atom, an acyl group, an acyloxy group, an imine residue, an amido group, an acid imide group, a monovalent heterocycle group, a carboxyl group, a substituted carboxyl group, a cyano group, a nitro group and a halogenyl group. Here, an aryl group is a group formed by removing one hydrogen atom from an aromatic hydrocarbon. An aromatic hydrocarbon contains: a monocyclic aromatic hydrocarbon, a condensed polycyclic hydrocarbon, a bonded compound formed with two or more independent monocyclic aromatic hydrocarbons, or a condensed polycyclic hydrocarbon with each other. Examples of an aromatic hydrocarbon include: a phenyl group, a naphthyl group, an anthryl group, a biphenyl group, a fluorenyl group and a binaphthyl group. A hetero aryl group is a group formed by removing one hydrogen atom from a hetero aromatic hydrocarbon. A hetero aromatic hydrocarbon indicates, among the carbon atoms which constitute the aforesaid aromatic hydrocarbon ring, a compound formed by replacing one or more carbon atoms with a hetero atom such as an oxygen, nitrogen, phosphor or a boron atom. A hetero aromatic hydrocarbon contains: a monocyclic hetero aromatic hydrocarbon, a condensed polycyclic hetero hydrocarbon, a bonded compound formed with two or more independent monocyclic hetero aromatic hydrocarbons, or a condensed polycyclic hetero hydrocarbon with each other. Examples of a hetero aromatic hydrocarbon include: a pyridyl group, a thiophenyl group, a bipyridyl group, a phenylpyridinyl group, a carbazolyl group, an azacarbazolyl group, an imidazolyl group, a dibenzofuranyl group, an isoquinolyl group, a dibenzophosphonyl group.

A cross-linking represented by Formula (100) can be used by replacing an arbitrary hydrogen atom of the material constituting the aforesaid light emitting unit or charge generating layer. In the case of a non-polymer compound without a repeating unit, the substitution number is 1 to 10, and preferably it is 1 to 4. In the case of a polymer compound having a repeating unit, the number of cross-linking groups per a number average molecular weight 10,000 is 1 to 100, and preferably it is 1 to 10. The number per a number average molecular weight of 10,000 means as follows, for example, it can be said that the number of cross-linking groups in a polymer having a number average molecular weight of 50,000 is 5 to 500, and preferably it is 5 to 50.

Specific examples of a low molecular weight material, a high molecular weight material and a high molecular weight polymerized material are shown below, however, the present invention is not limited to these.

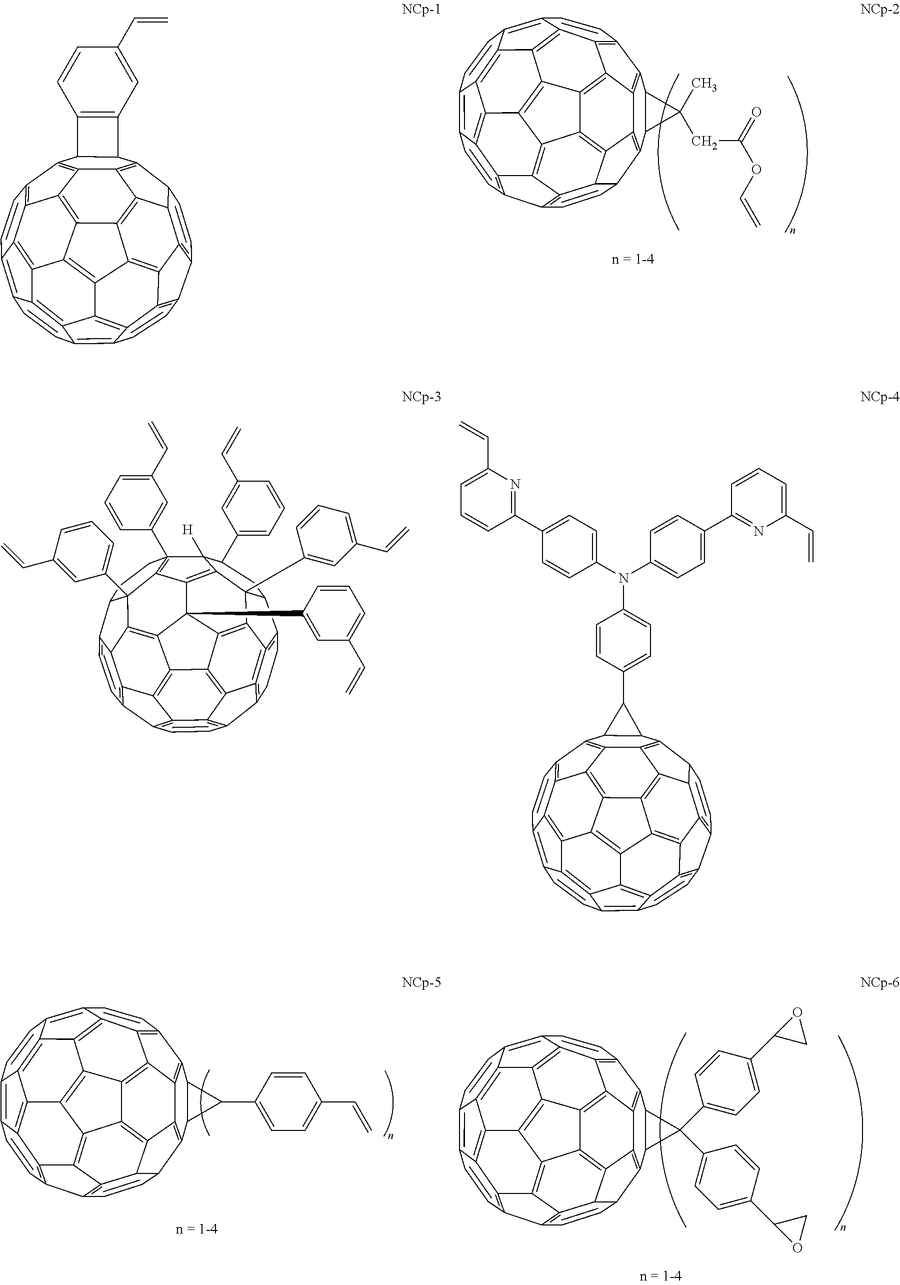

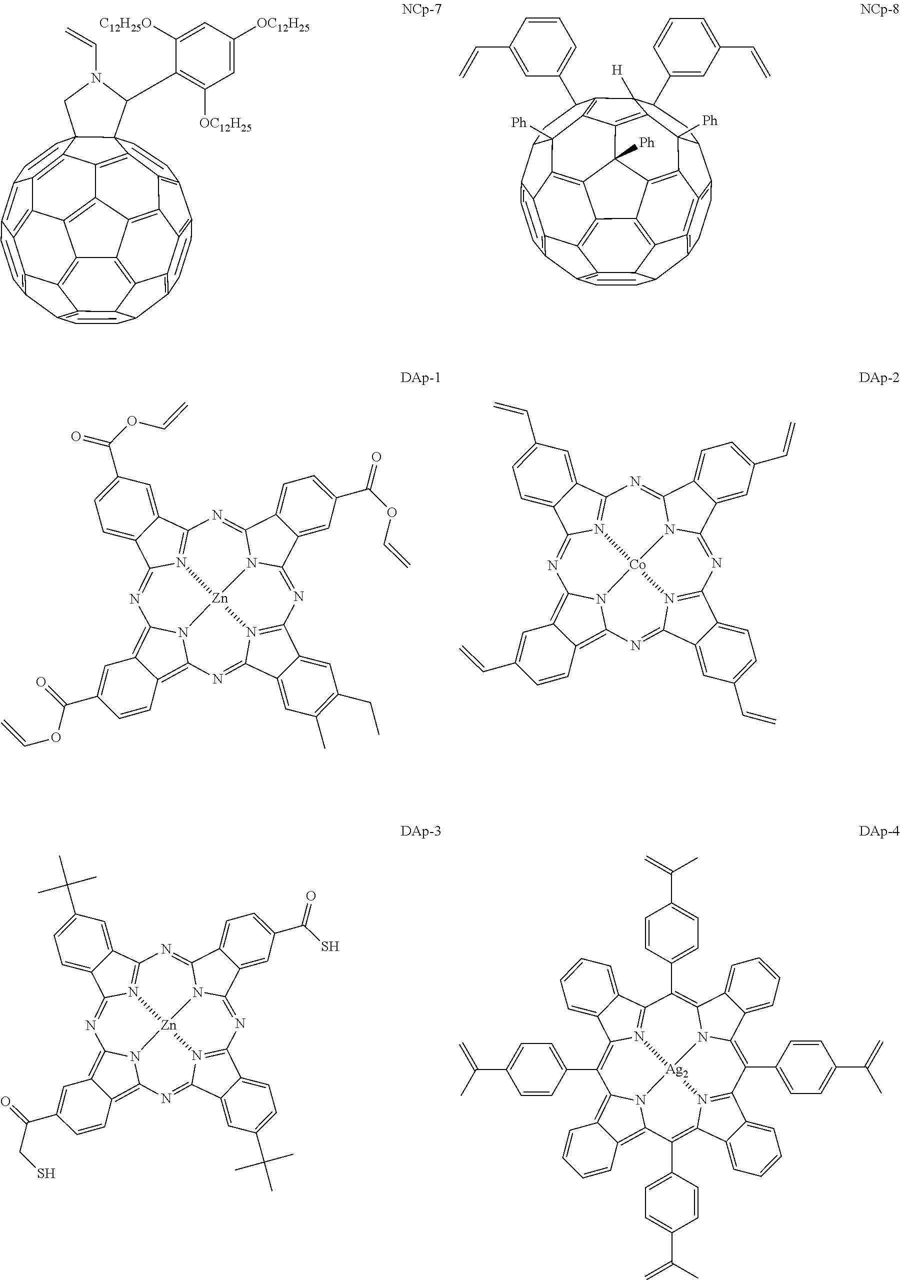

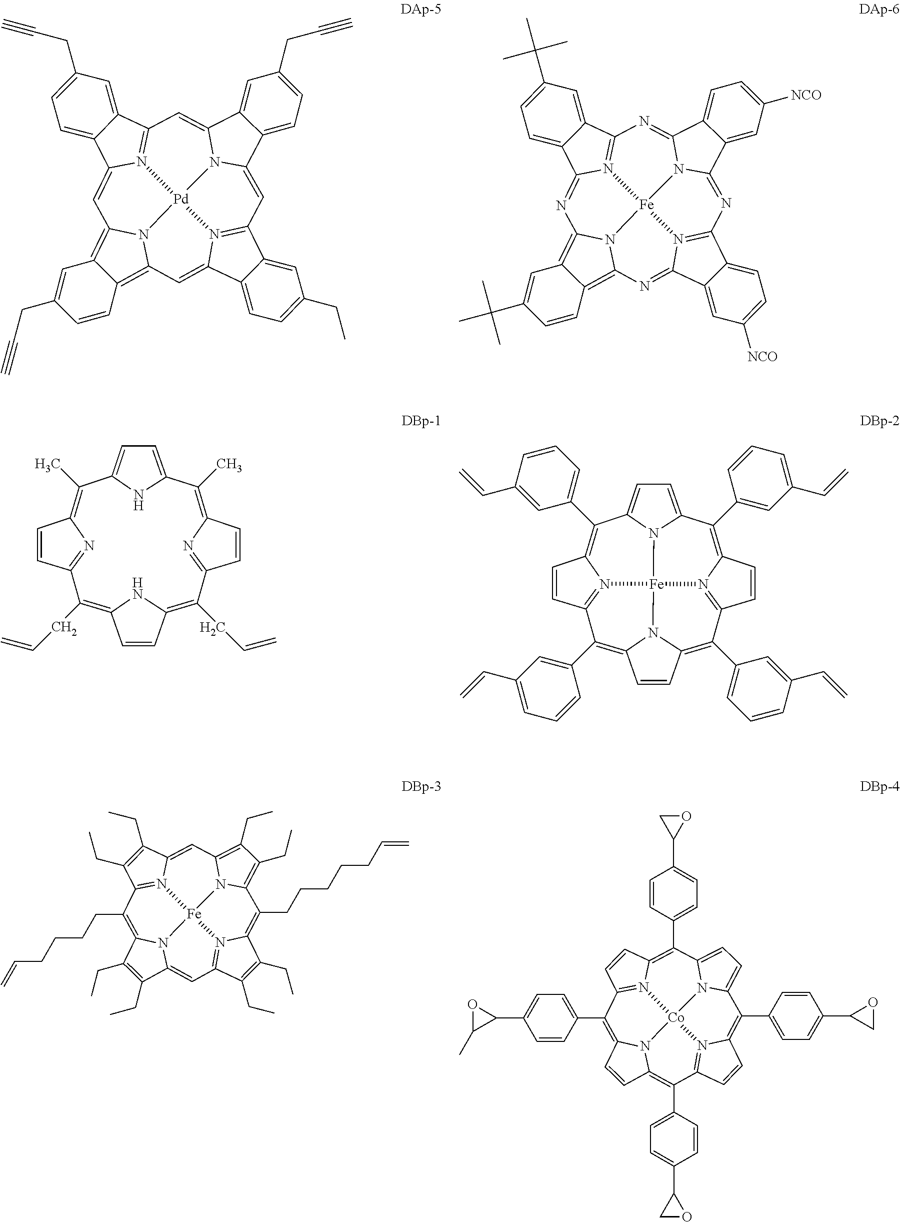

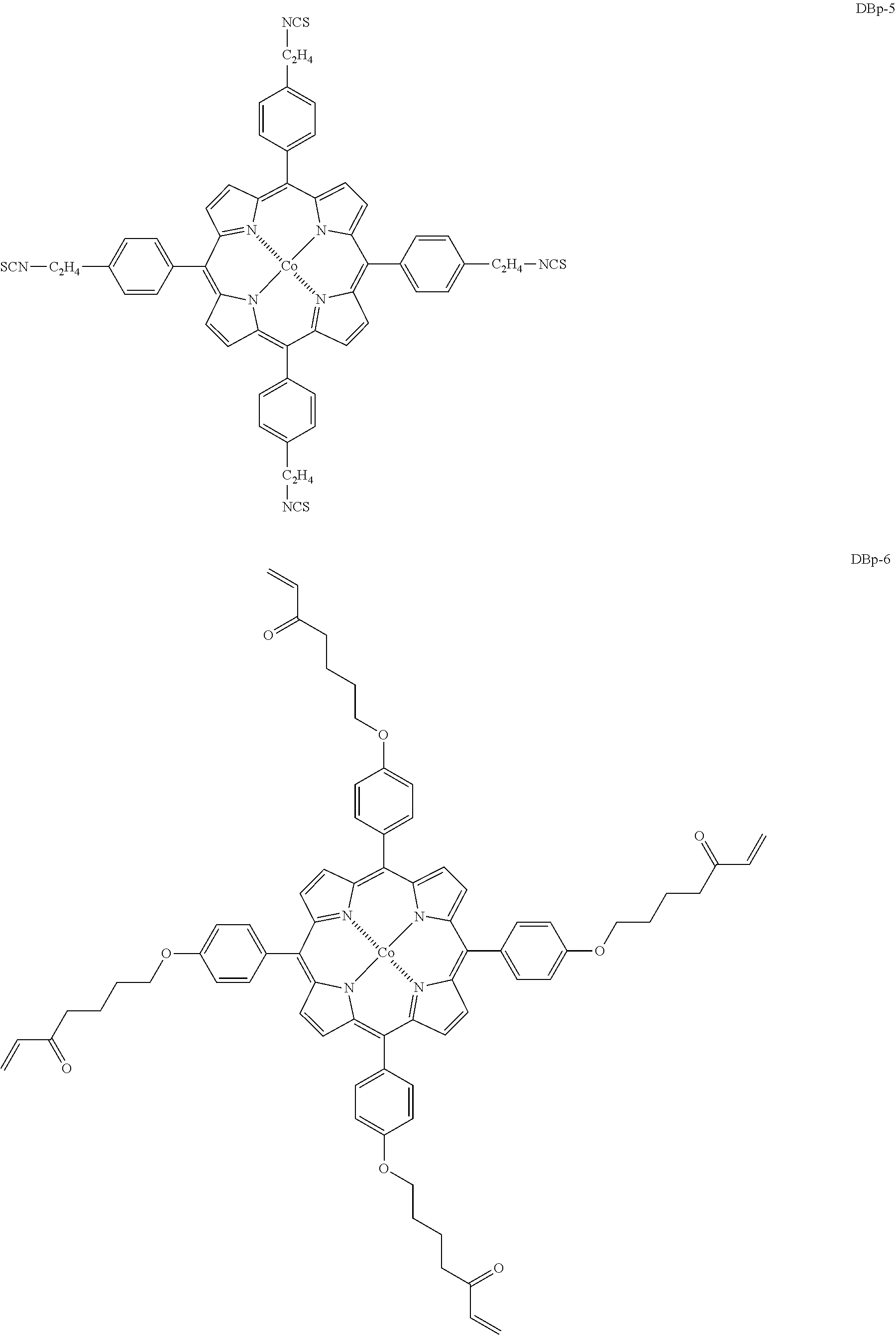

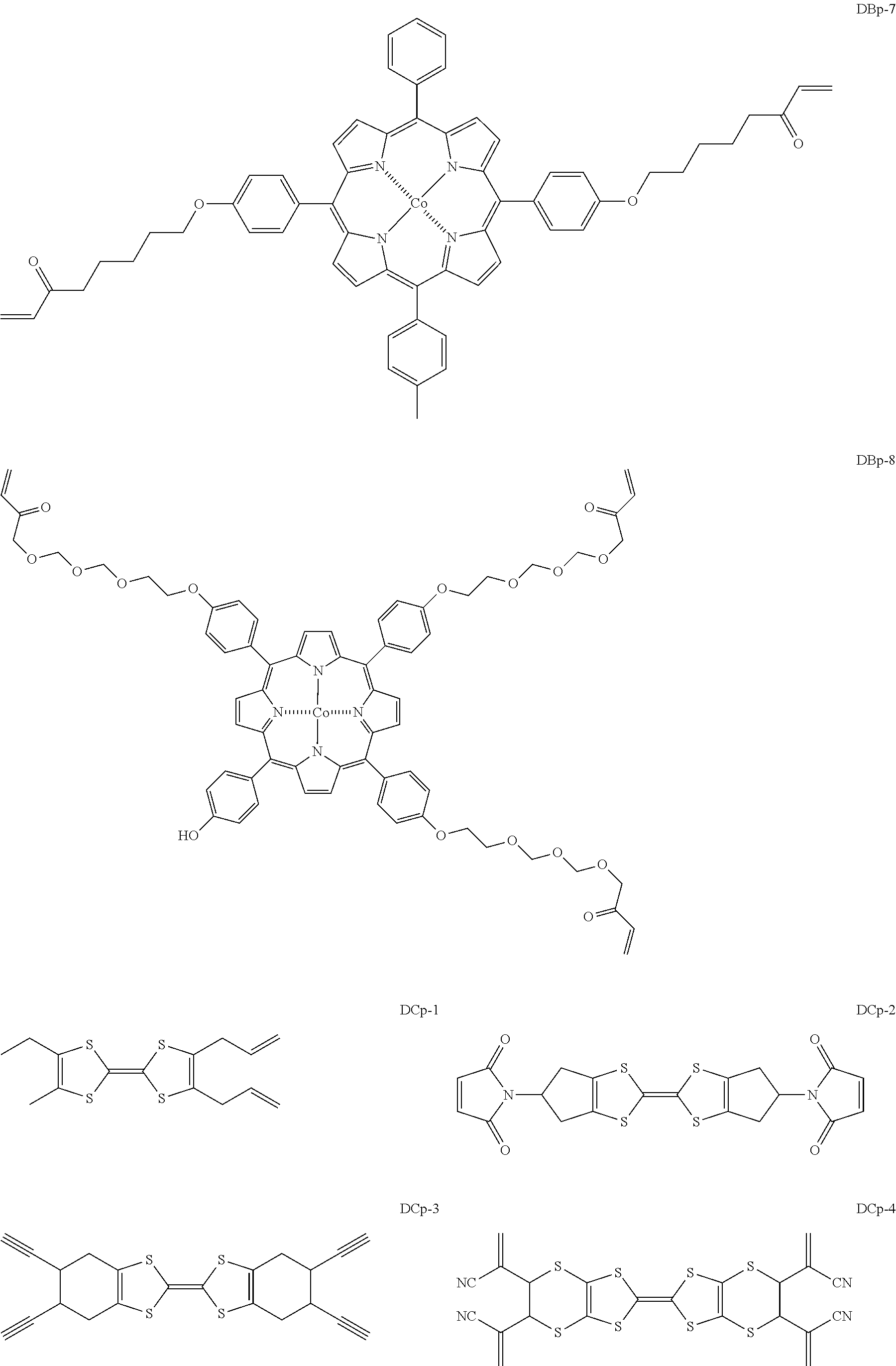

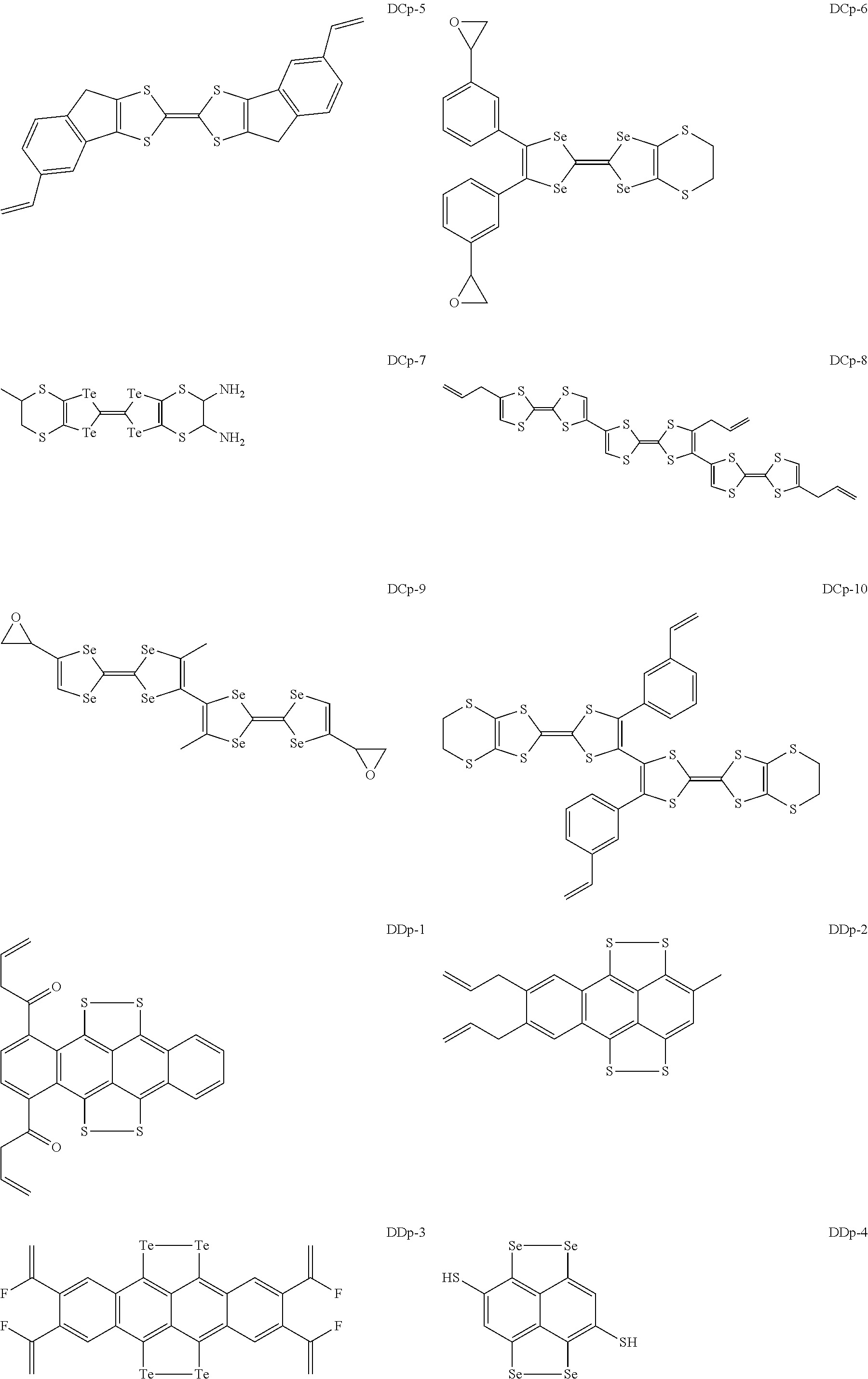

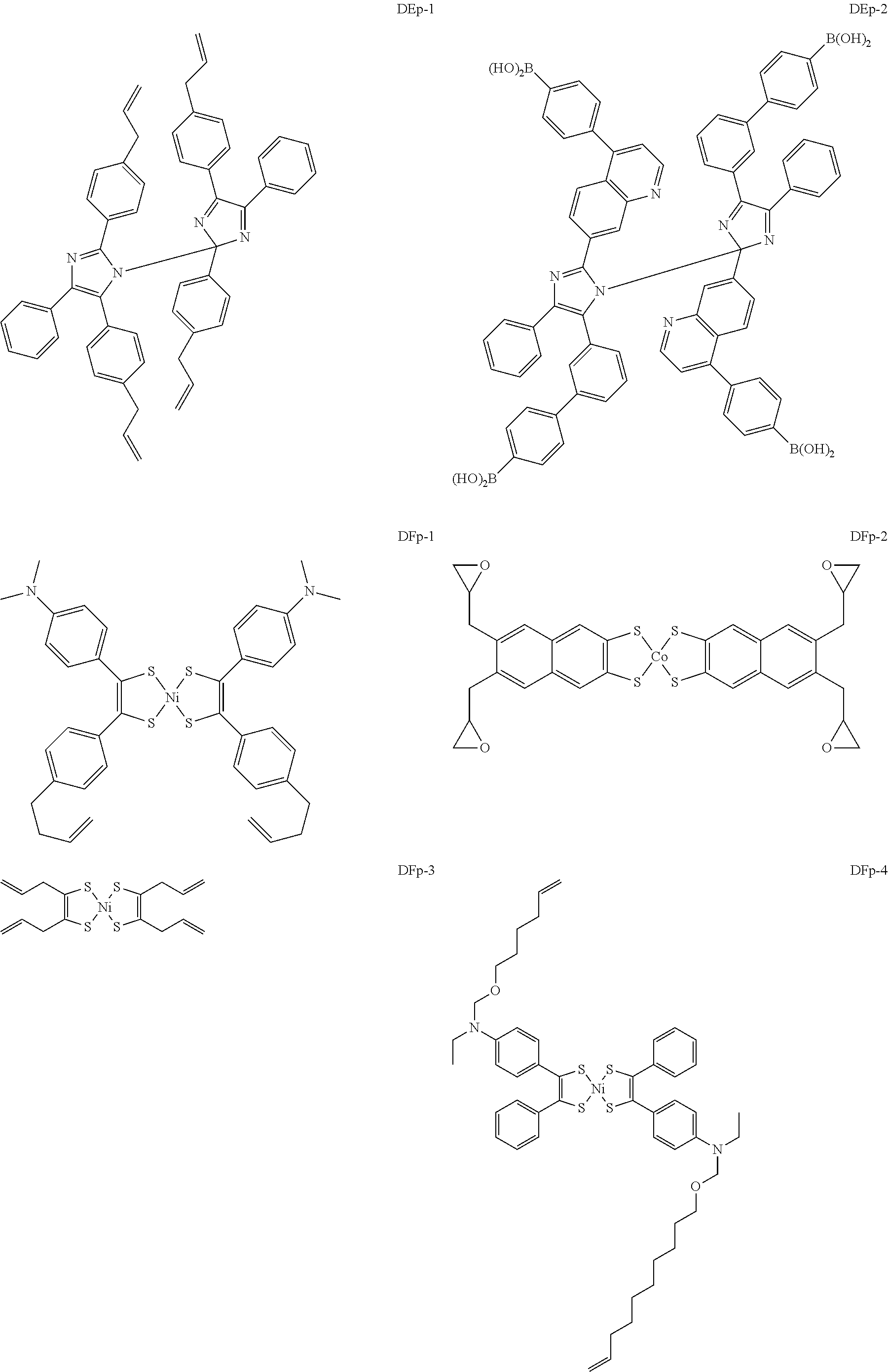

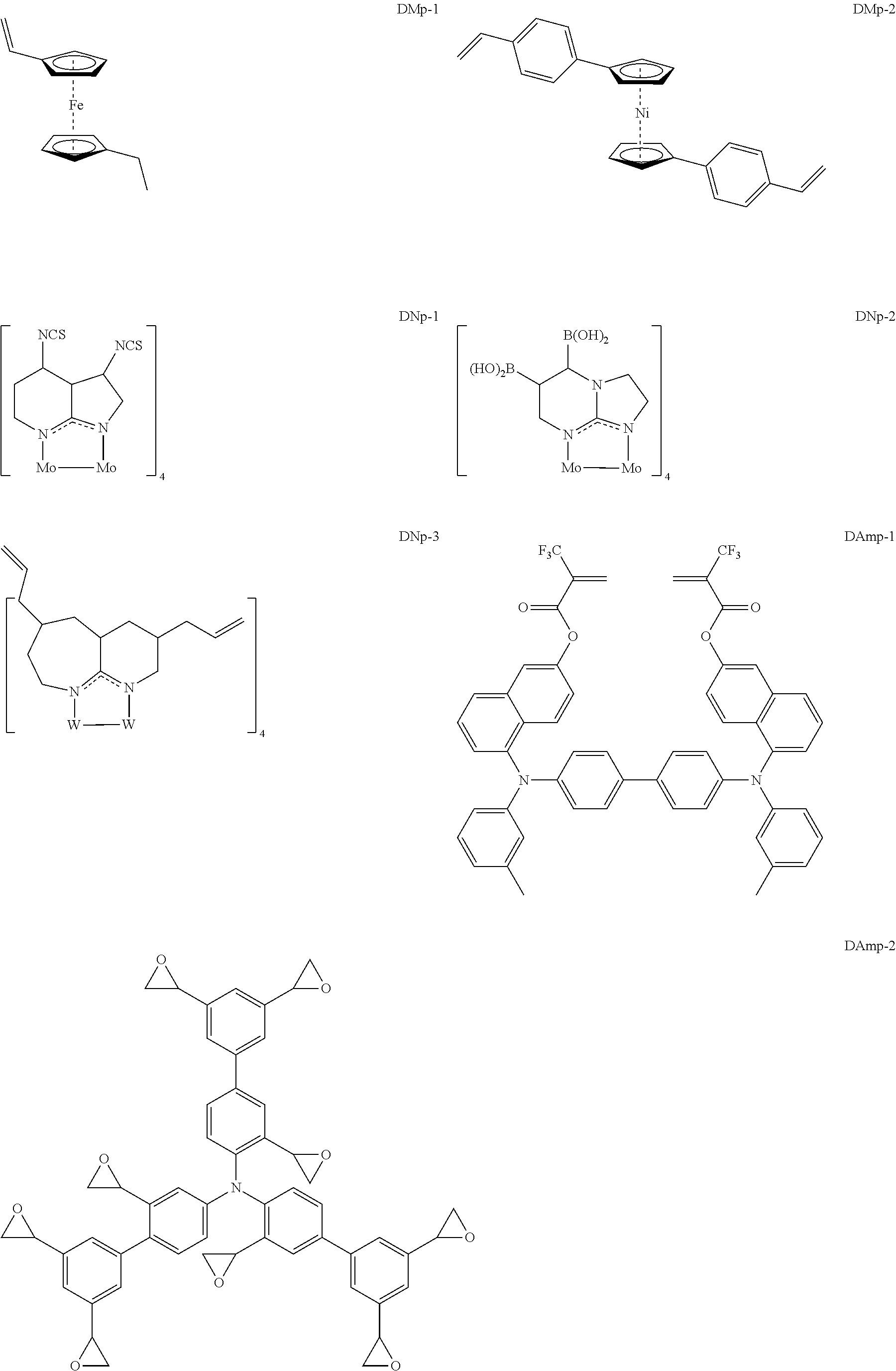

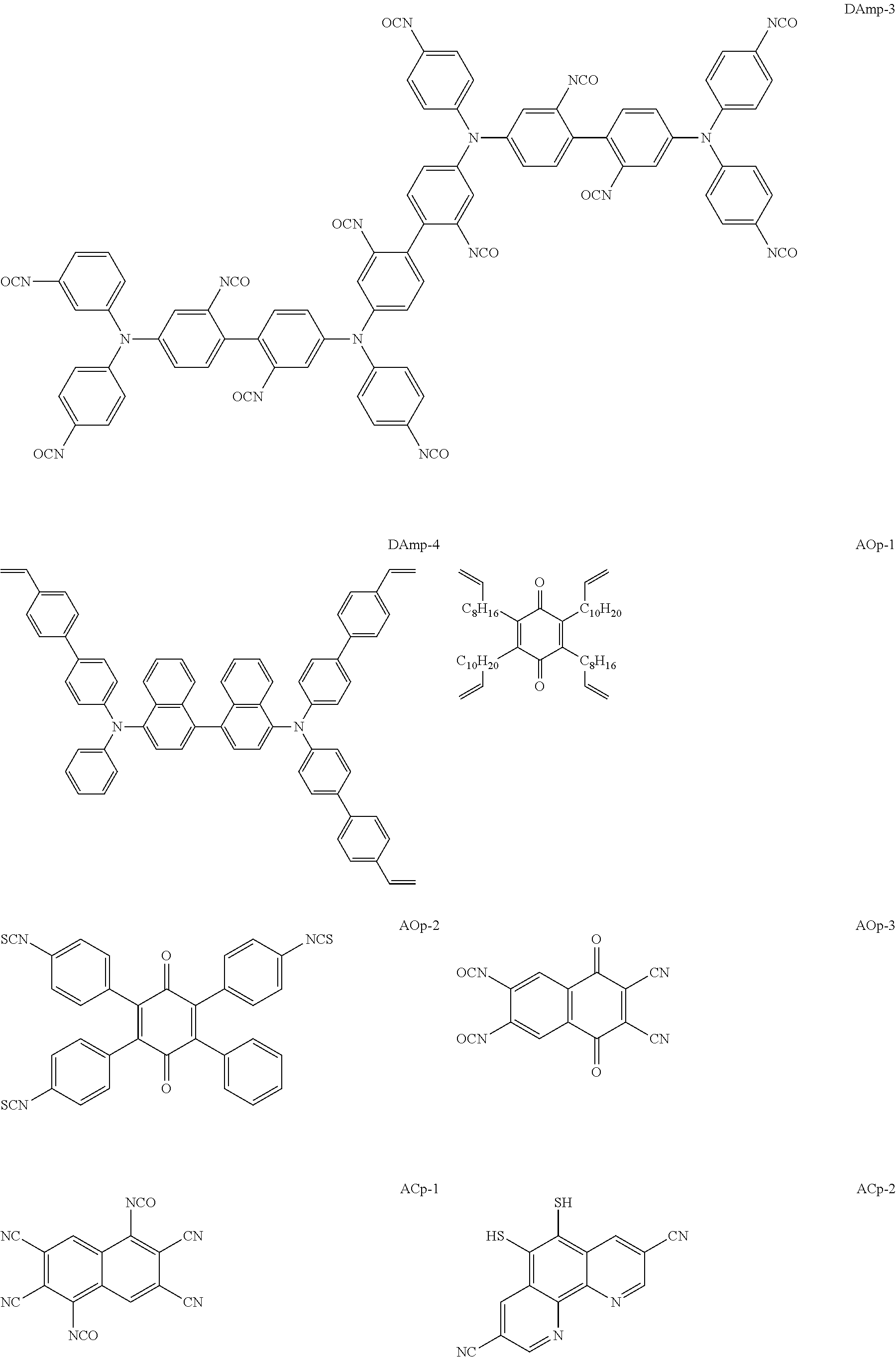

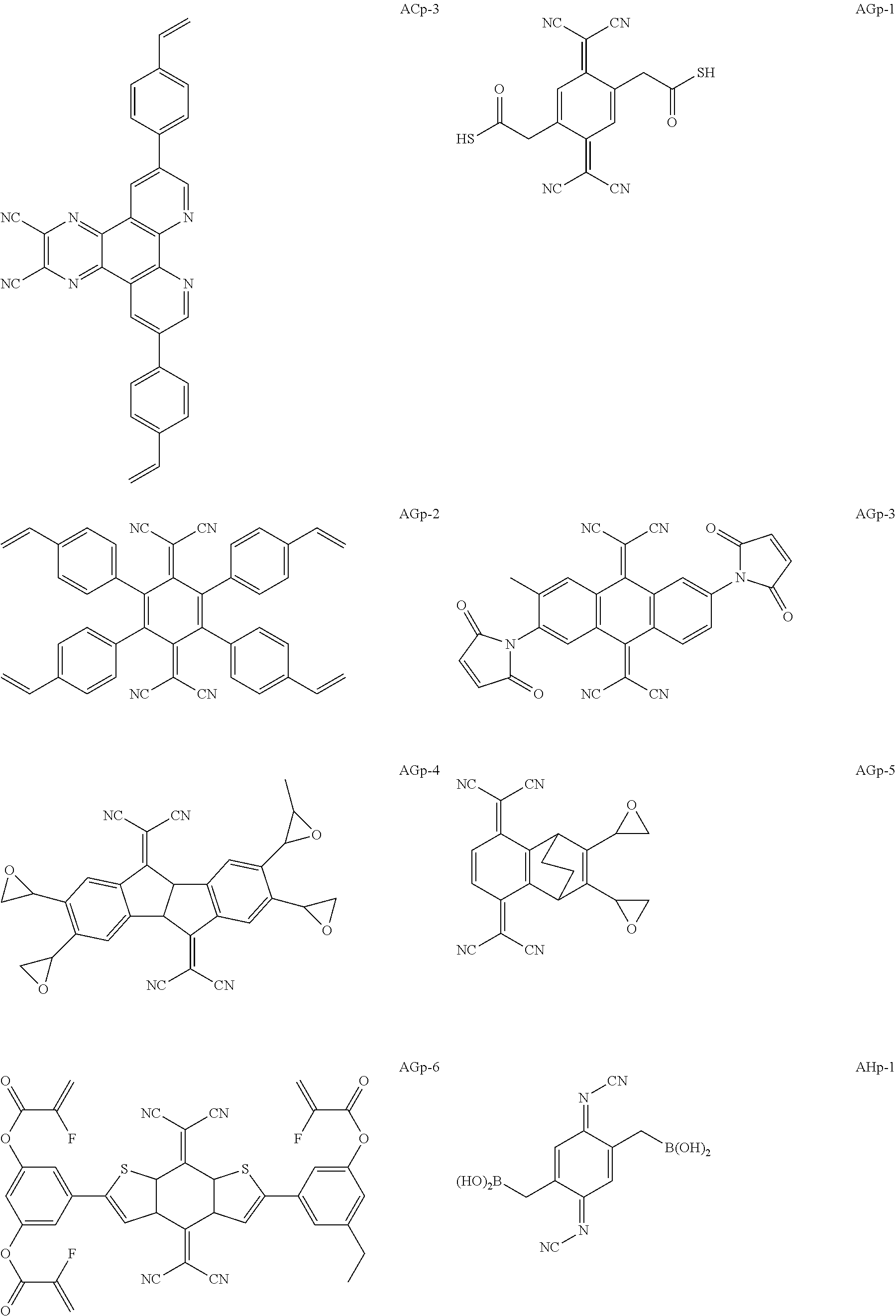

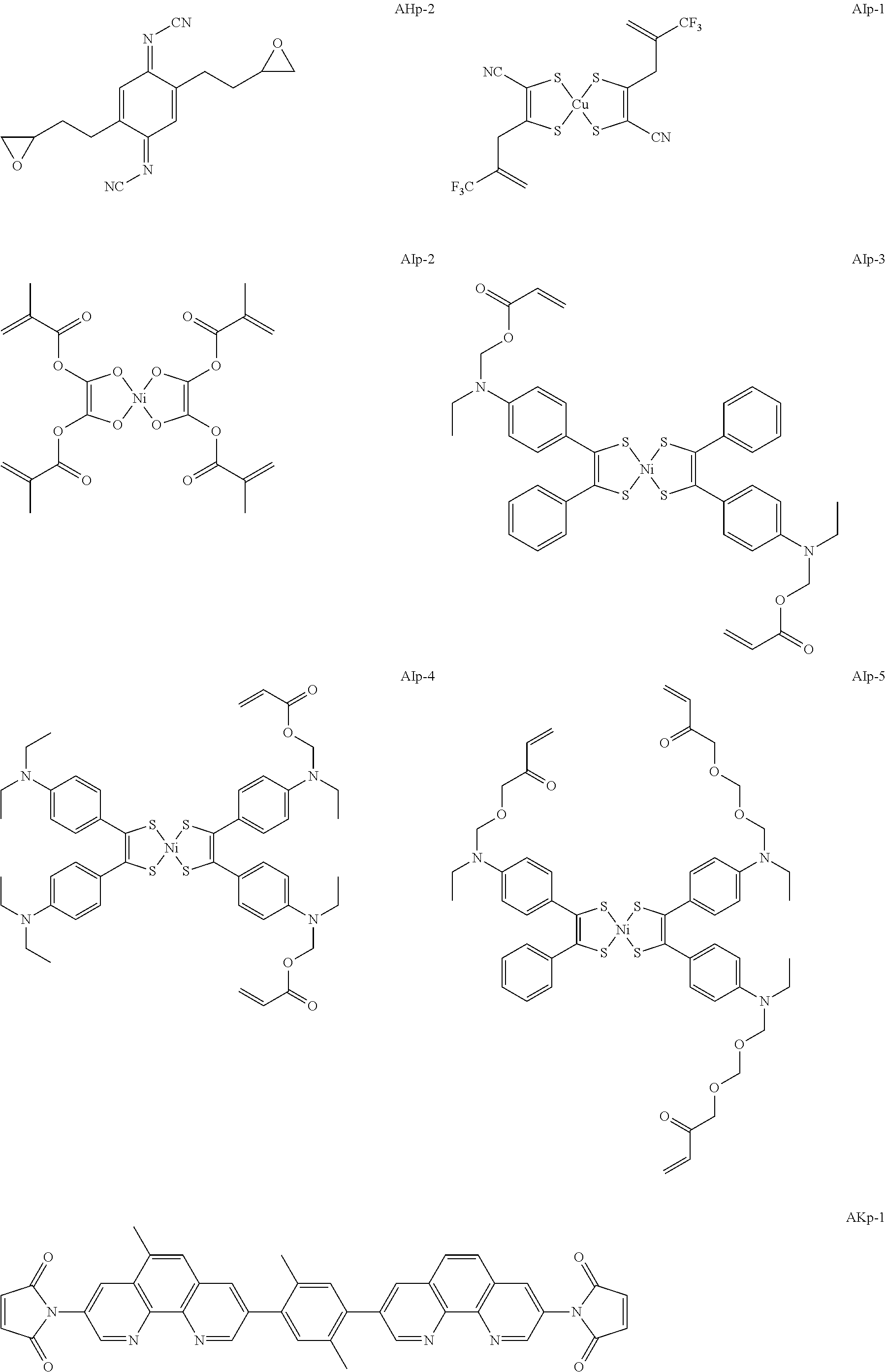

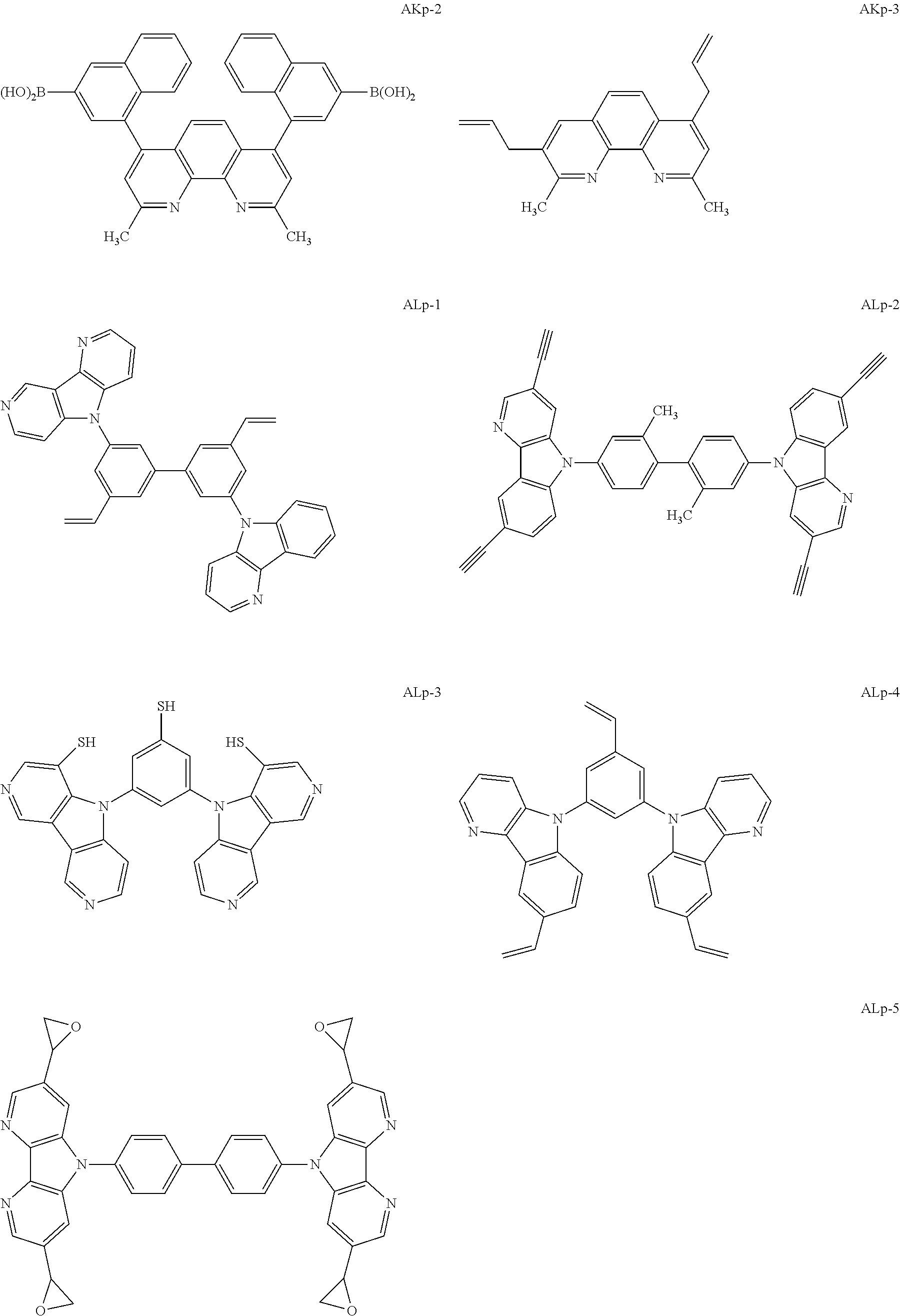

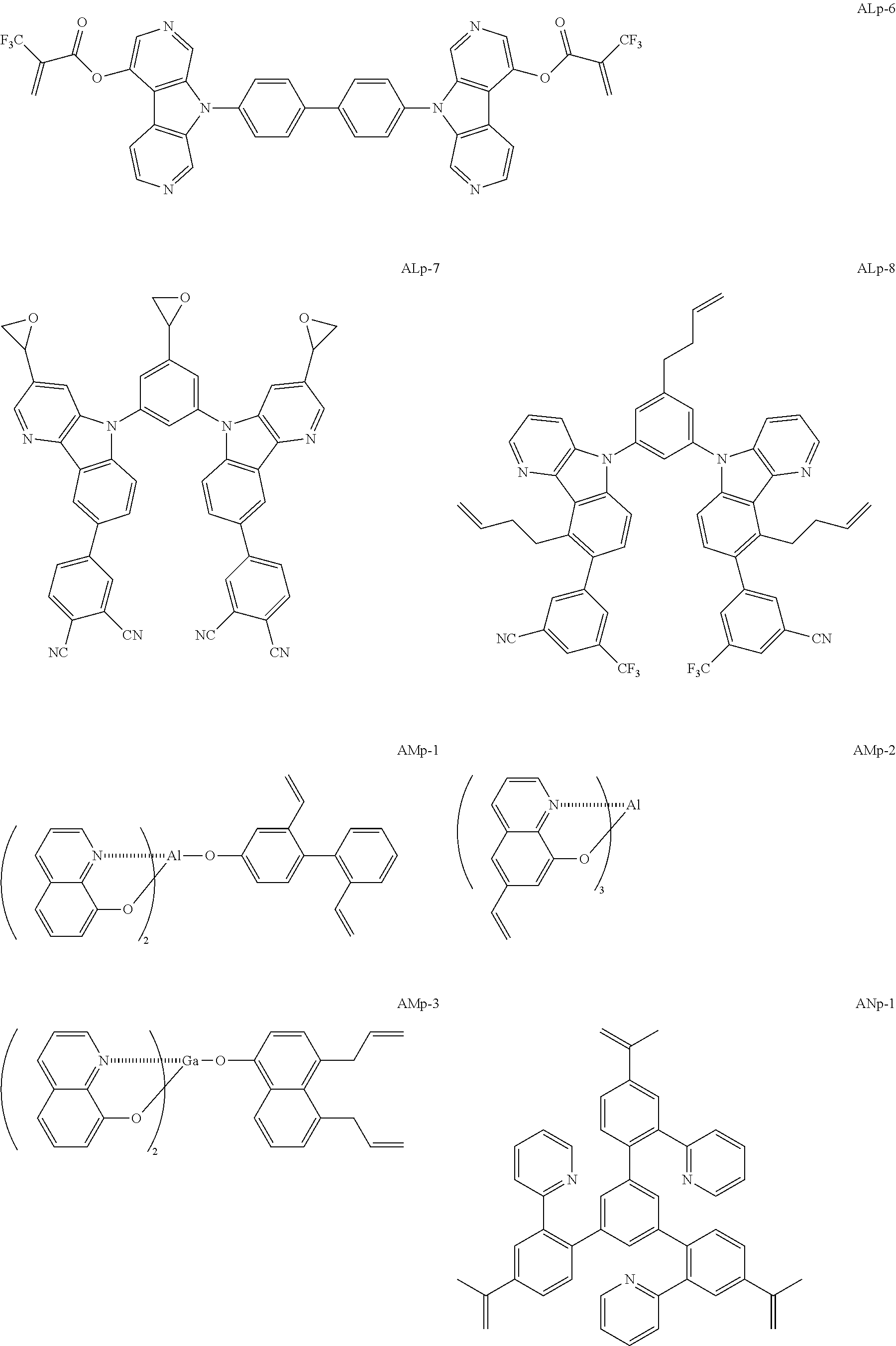

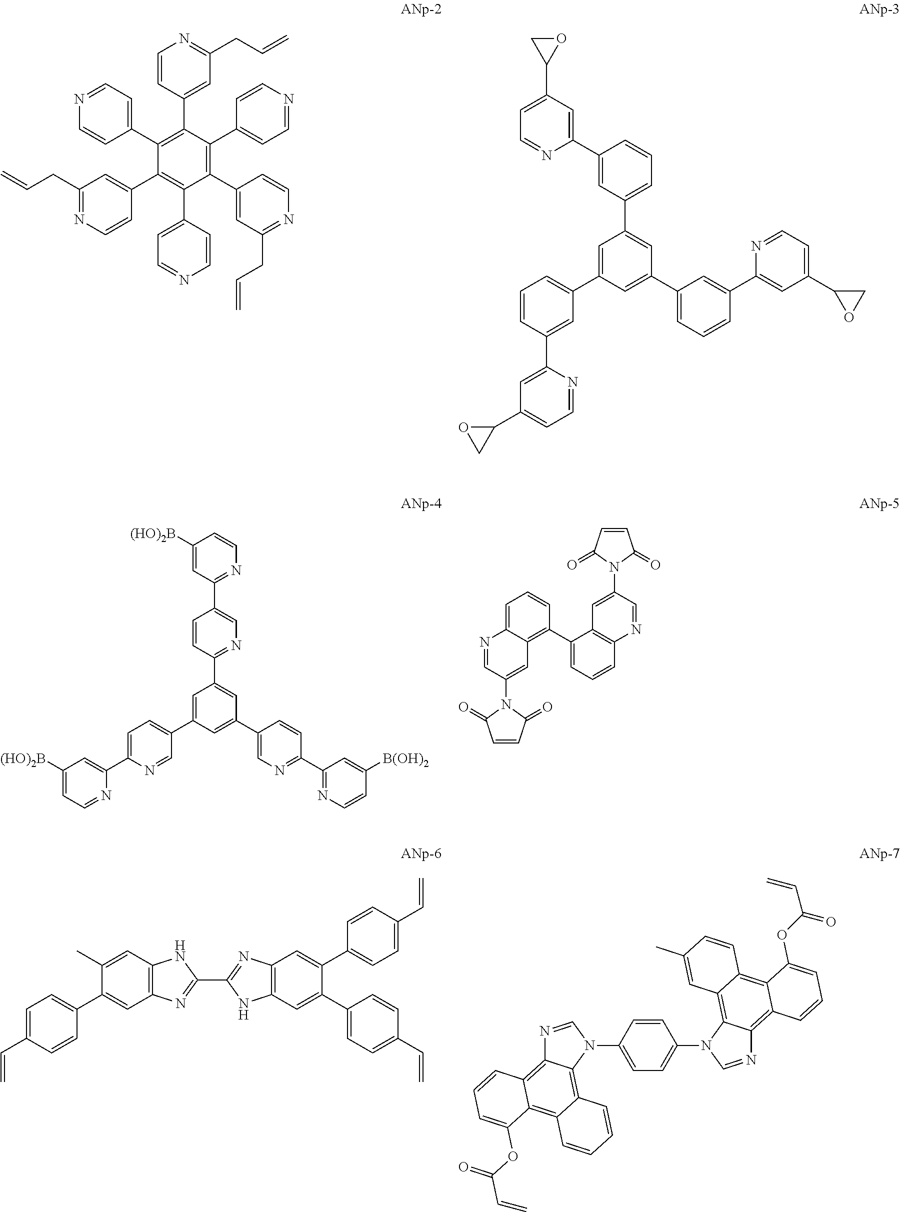

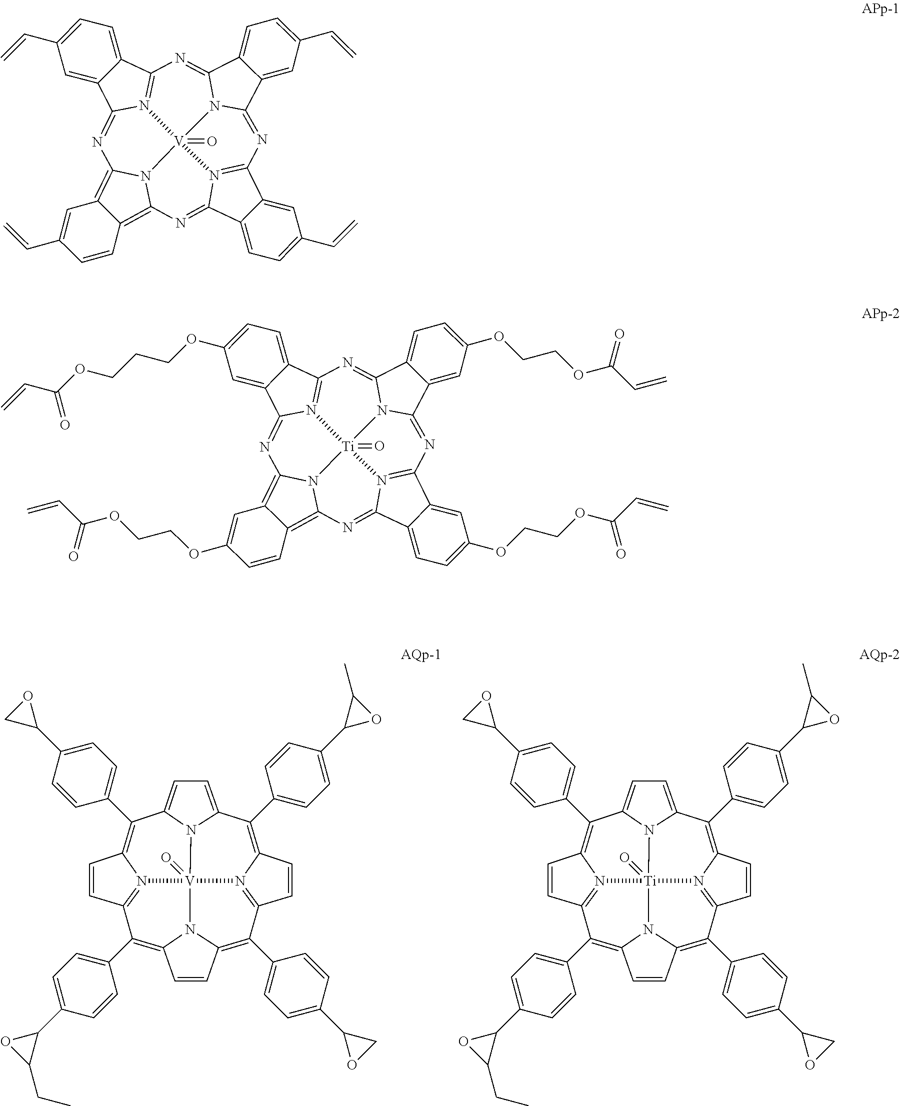

(b) Sol-Gel Reaction:

This is a chemical preparation method of ceramic (metal oxide) by a hydrolytic dehydration condensation (sol-gel reaction) of a metal alkoxide.

(c) Complex Forming Reaction:

Insolubilization is performed by a reaction of a metal species and a multidentate ligand to promote formation of a metal cross-linking polymer (coordinate bonded polymer complex) which contains a coordinate bonded cross-linkage. The metal species include: Group 1 of the Periodic table (alkali metal), Group 2 (alkali earth metal), metal elements from Group 12 to Group 15, and transition metals from Group 4 to Group 11. Examples thereof are: Cs, Mg, Ca, Ba, Ti, V, Mo, W, Fe, Co, Ir, Ni, Pt, Cu, Zn, Al and Sn.

Any ligand can be used without problems as long as it contains a substituent having a lone pair, and this substituent can form a complex by a coordinate bond with a metal, and further, it contains two or more substituents capable of forming a coordinate bond. Examples of the aforesaid substituent are: an amino group, an ethylenediamino group, a pyridyl group, a bipyridyl group, a terpyridyl group, a carbonyl group, a carboxyl group, a thiol group, a porphyrin ring, a crown ether and a carbene.

Hereafter, there are listed specific examples of a metal cross-linking polymer containing a coordinate bonded cross-linkage which can be used in the present invention, however, the present invention is not limited to these.

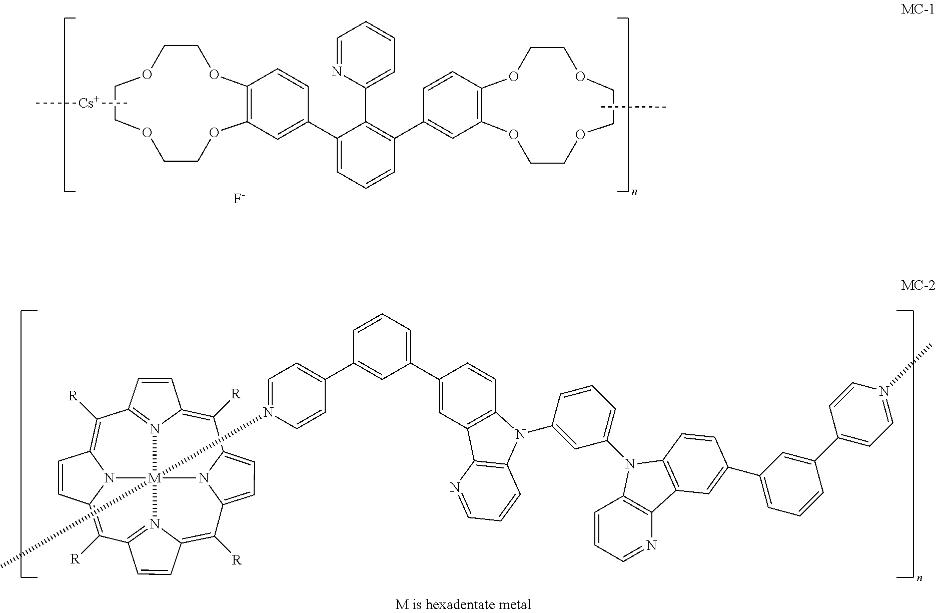

(d) Use of Precursor:

After coating a soluble precursor compound to form a film, the coated film is changed into a compound which cannot be re-dissolved by applying an inner or external stimulus of heat, light or electromagnetic wave to produce chemical or physical change or substitution.

Examples of a precursor suitably used in the present invention are compounds described in JP-A 2008-135198.

(3) Coating and Film Formation of Insoluble Material.

(a) Film Formation of Dispersion Material

A dispersion liquid of an insoluble material is prepared: by using a solvent dispersion method after producing fine particles of an insoluble material; or by a method in which a soluble precursor is changed into insoluble fine particles in a solvent. Then, thus prepared dispersion liquid is coated to form a film resulting in producing a insoluble thin film. The formation of insoluble fine particles of a soluble precursor can be done by coating a soluble precursor in a solvent to form a film, followed by applying an inner or external stimulus of heat, light or electromagnetic wave to produce chemical change of the precursor.

Moreover, “a solvent” as used in the present invention is the name of a liquid which dissolves a solid and a liquid. Especially, in the case of describing as “a test solvent”, it is a solvent of: aromatic hydrocarbons (toluene, chlorobenzene and pyridine), saturated hydrocarbons (cyclohexane, decane and perfluoro octane), alcohols (isopropyl alcohol and hexafluoroisopropanol), ketones (methyl ethyl ketone and cyclohexanone), esters (butyl acetate and phenyl acetate), dichloroethane, tetrahydrofuran, and acetonitrile. Further “an inert state” indicates the sate of fulfilling the evaluation criteria later described for at least one of the following items: (i) the layer thickness change measured with UV absorption change; (ii) the state change of the light emitting layer measured with PL (photoluminescence) change; and (iii) the rectification ratio.

### <<Preparation Method of Organic EL Element>>

As an example of the preparation method of the organic EL element of the present invention, a preparation method of an organic EL element composed of an anode/a hole injecting layer/a hole transporting layer/a light emitting layer/a hole blocking layer/an electron transporting layer/an electron injecting layer/a cathode is described below.

First, a thin film composed of desired electrode materials, such as anode materials, is formed on a suitable substrate via a vacuum deposition or sputtering method to at most 1 μm, preferably 10 nm to 200 nm in a film thickness to prepare an anode.

Subsequently, on the above anode, thin films of organic compounds composed of a hole injecting layer, a hole transporting layer, a light emitting layer, an electron transporting layer, an electron injecting layer, and a hole blocking layer, all of which are materials for the organic EL element, are formed.

Forming methods of each of the above layers include, as described above, a vacuum deposition method and wet processes (such as a slit coating method, a spin coating method, an ink-jet method, and a printing method). In the present invention, film formation by coating methods such as a slit coating method, a spin coating method, an ink-jet method, and a printing method are preferred from viewpoints that a homogeneous film is readily formed and a pin hole is hard to be formed. Especially, a slit coating method is preferably used.

In particular, it is preferable to form the layer incorporating a compound of the present invention containing a carbazole ring as a partial structure, the aforesaid compound further containing a polymerizable group and a polymer of these compounds with the above-described methods.

Moreover, when the number of whole layers (it is a number of constituting layers of an organic EL element) which exist between an anode and cathode is set to be 100%, it is preferable that 50% or more numbers of layers among the whole layers are formed with a coating method.

For example, in the case of the organic EL element cited as an example, having a layer composition of an anode/a hole injecting layer/a hole transporting layer/a light emitting layer/a hole blocking layer/an electron transporting layer/an electron injecting layer/a cathode, since the number of whole layers is 6, it is preferable that at least three layers are formed with a coating method.

When the constituting layers of an organic EL element of the present invention are formed with a coating method, examples of liquid media for dissolving or dispersing the organic EL materials of the present invention are as follows. Usable liquid media are: ketones such as methyl ethyl ketone, and cyclohexanone; fatty acid esters such as ethyl acetate; halogenated hydrocarbons such as dichlorobenzene; aromatic hydrocarbons such as toluene, xylene, mesitylene, and cyclohexylbenzene; aliphatic hydrocarbons such as cyclohexane, decalin, and dodecane; and organic solvents such as DMF and DMSO.

The above organic EL materials may be dispersed via an ultrasonic technique, a high shearing force dispersion method, or a media dispersion method.

After formation of these layers, a thin film comprising a cathode material is formed thereon to 1 μm or less, preferably in a range of 50 nm to 200 nm in film thickness by means of such as a vacuum deposition or spattering to provide a cathode, whereby a desired organic EL element can be prepared.

Further, the above preparation order may be reversed, and preparation may be conducted in the order of the cathode, the electron injecting layer, the electron transporting layer, the light emitting layer, the hole transporting layer, the hole injecting layer, and the anode.

In the case where direct current voltage is applied to the multicolor display device prepared as above, light emission can be observed when a voltage of 2 to 40 V is applied while the anode is set to a positive polarity and the cathode is set to a negative polarity. Further, alternating current voltage may be applied, of which any waveforms of the applied alternating current may be employed.

### APPLICATIONS

The organic EL element of the present invention may be utilized as a display device, a display, or various light sources. Examples of the use of the light source include lighting device (a home lamp or a room lamp in a car), a backlight for a watch or a liquid crystal, a light source for boarding advertisement, a signal device, a light source for a photo memory medium, a light source for an electrophotographic copier, a light source for an optical communication instrument and a light source for an optical sensor, but are not limited to them. Of these, the element is particularly effectively utilized for a backlight for a liquid crystal display or a light source for lighting use.

The organic EL element of the present invention, if desired, may be subjected to patterning during film making, via a metal mask or an ink-jet printing method.

In the case of the patterning, only the electrode may be subjected to the patterning, or both the electrode and the light emitting layer may be subjected to the patterning, or all element layers may be subjected to the patterning. Commonly known conventional methods can be employed for the preparation of the element.

Color of light emitted from the organic EL element of the present invention or the chemical compounds according to the present invention is measured via a spectroradiometer CS-1000 (manufactured by Konica Minolta Sensing Inc.) and the measured values are plotted onto the CIE chromaticity diagram described in FIG. 4.16 on page 108 of “Shinpen Shikisai Kagaku Handbook” (Coloring Science Handbook, New Edition), (edited by Nihon Shikisai Gakkai, published by Todai Shuppan Kai, 1985), whereby the color is determined.

In the case where the organic EL element of the present invention is a white element, the term “white” means that the chromaticity is within a region of X=0.33±0.07, Y=0.33±0.1 according to CIE 1931 color coordinate system at 1,000 cd/m² when a front luminance at a viewing angle of 2 degrees is measured via the above method.

### <<Display Device>>

A display device of the present invention will now be explained. The display device of the present invention includes the above-described organic EL element.

A display device of the present invention may be either monochromatic or multi-colored. Here explained will be a multicolor display device. In the case of a multicolor display device, a shadow mask is provided only at the time of emission layer formation, and layers can be formed all over the surface by such as an evaporation method, a slit coating method, a cast method, a spin coat method, an inkjet method and a printing method.

When patterning is performed only for producing a light emitting layer, the method is not specifically limited; however, preferable are an evaporation method, a slit coating method, a spin coating method and a printing method.

The constitution of the organic EL element used for a display device can be selected from the embodiments of the organic EL element as described above, in accordance with the requirement.

The production method of the organic EL element was described above for one of the embodiments of the organic EL element of the present invention.

When a direct current voltage is applied on the multicolor display device thus prepared, emission can be observed by application of a voltage of approximately 2-40 V setting an anode to + polarity and a cathode to − polarity. Further, no current flows and no emission generate at all even when a voltage is applied with a reversed polarity. Further, in the case of alternate current voltage being applied, emission generates only in a state of an anode being + and a cathode being −. Herein, the wave shape of alternate current may be arbitrary.

A multicolor display device can be utilized as a display device, a display and various types of emission light sources. In a display device and a display, full-colored display is possible by employing three types of organic EL elements providing blue, red and green emissions.

A display device and a display include a TV, a personal computer, a mobile instrument, an AV instrument, a character broadcast display and an information display in a car. Particularly, the display device and the display may be also utilized as a display to playback still images and moving images, and may adopt either a simple matrix (a passive matrix) mode or an active matrix mode when being utilized as a display device for moving image playback.

An illumination light source includes a home use illumination, a car room illumination, a backlight of a watch or a liquid crystal, a panel advertisement, a signal, a light source of an optical memory medium, a light source for an electrophotographic copier, a light source for an optical telecommunication processor and a light source for a photo-sensor, however, the present invention is not limited thereto.

In the following, one example of a display device provided with an organic EL element of the present invention will be explained with reference to figures.

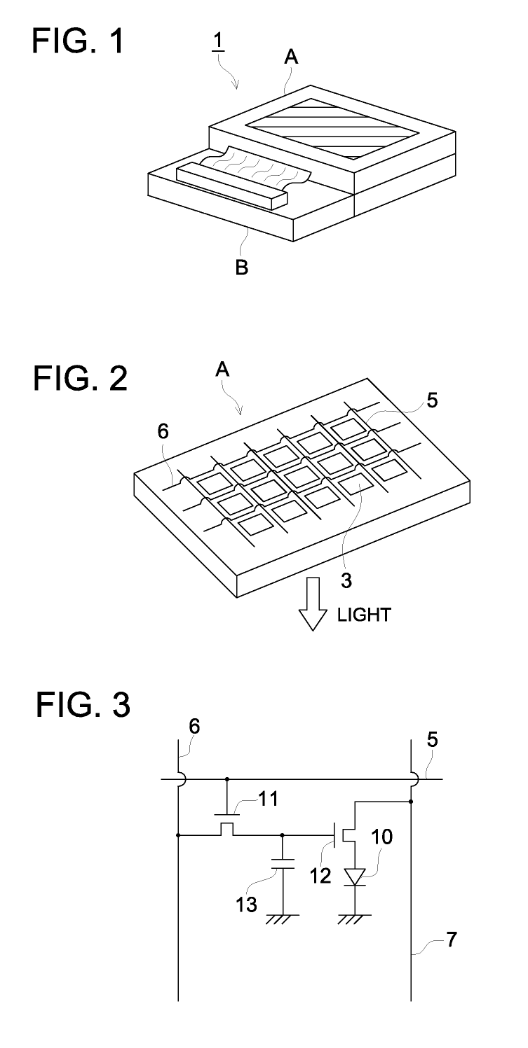

FIG. 1 is a schematic drawing to show an example of a display device constituted of an organic EL element. It is a schematic drawing of a display, which displays image information by emission of an organic EL element, such as a mobile phone.

Display 1 is constituted of display section A having plural number of pixels and control section B which performs image scanning of display section A based on image information.

Control section B, which is electrically connected to display section A, sends a scanning signal and an image data signal to plural number of pixels based on image information from the outside and pixels of each scanning line successively emit depending on the image data signal by a scanning signal to perform image scanning, whereby image information is displayed on display section A.

FIG. 2 is a schematic drawing of display section A.

Display section A is provided with such as a wiring part, which contains plural scanning lines 5 and data lines 6, and plural pixels 3 on a substrate. Primary part materials of display section A will be explained in the following.

In the drawing, shown is the case that light emitted by pixel 3 is taken out along the white allow (downward).

Scanning lines 5 and plural data lines 6 in a wiring part each are comprised of a conductive material, and scanning lines 5 and data lines 6 are perpendicular in a grid form and are connected to pixels 3 at the right-angled crossing points (details are not shown in the drawing).

Pixel 3 receives an image data from data line 6 when a scanning signal is applied from scanning line 5 and emits according to the received image data.

Full-color display device is possible by appropriately arranging pixels having an emission color in a red region, pixels in a green region and pixels in a blue region, side by side on the same substrate.

Next, an emission process of a pixel will be explained.

FIG. 3 is a schematic drawing of a pixel.

A pixel is equipped with such as organic EL element 10, switching transistor 11, operating transistor 12 and capacitor 13. Red, green and blue emitting organic EL elements are utilized as organic EL element 10 for plural pixels, and full-color display device is possible by arranging these side by side on the same substrate.

In FIG. 3, an image data signal is applied on the drain of switching transistor 11 via data line 6 from control section B. Then when a scanning signal is applied on the gate of switching transistor 11 via scanning line 5 from control section B, operation of switching transistor is on to transmit the image data signal applied on the drain to the gates of capacitor 13 and operating transistor 12.

Operating transistor 12 is on, simultaneously with capacitor 13 being charged depending on the potential of an image data signal, by transmission of an image data signal. In operating transistor 12, the drain is connected to electric source line 7 and the source is connected to the electrode of organic EL element 10, and an electric current is supplied from electric source line 7 to organic EL element 10 depending on the potential of an image data applied on the gate.

When a scanning signal is transferred to next scanning line 5 by successive scanning of control section B, operation of switching transistor 11 is off. However, since condenser 13 keeps the charged potential of an image data signal even when operation of switching transistor 11 is of operation of operating transistor 12 is kept on to continue emission of organic EL element 10 until the next scanning signal is applied. When the next scanning signal is applied by successive scanning, operating transistor 12 operates depending on the potential of an image data signal synchronized to the scanning signal and organic EL element 10 emits.

That is, emission of each organic EL element 10 of plural pixels 3 is performed by providing switching transistor 11 and operating transistor 12 against each organic EL element 10 of plural pixels 3. Such an emission method is called as an active matrix mode.

Herein, emission of organic EL element 10 may be either emission of plural gradations based on a multiple-valued image data signal having plural number of gradation potentials or on and off of a predetermined emission quantity based on a binary image data signal. Further, potential hold of capacitor 13 may be either continuously maintained until the next scanning signal application or discharged immediately before the next scanning signal application.

In the present invention, emission operation is not necessarily limited to the above-described active matrix mode but may be a passive matrix mode in which organic EL element is emitted based on a data signal only when a scanning signal is scanned.

FIG. 4 is a schematic drawing of a display device based on a passive matrix mode. In FIG. 4, plural number of scanning lines 5 and plural number of image data lines 6 are arranged grid-wise, opposing to each other and sandwiching pixels 3.

When a scanning signal of scanning line 5 is applied by successive scanning, pixel 3 connected to scanning line 5 applied with said signal emits depending on an image data signal.

Since pixel 3 is provided with no active element in a passive matrix mode, decrease of manufacturing cost is possible.

### <<Lighting Device>>

A lighting device of the present invention will now be explained. The lighting device of the present invention includes the above-described organic EL element.

An organic EL element of the present invention can be utilized as an organic EL element provided with a resonator structure, and a utilization purpose of such an organic EL element provided with a resonator structure includes such as a light source for an optical memory medium, a light source for an electrophotographic copier, a light source for a optical telecommunication processor and a light source for a photo-sensor, however, is not limited thereto. Further, the organic EL element may be utilized for the above-described applications by being made to perform laser emission.

Further, an organic EL element of the present invention may be utilized as one type of a lamp like an illumination and an exposure light, and may be also utilized as a display device of a projector of an image projecting type and a display device (a display) of a type to directly view still images and moving images.

An operating mode in the case of being utilized as a display device for playback of moving images may be either a simple matrix (a passive matrix) mode or an active matrix mode. In addition, a full-color display device can be prepared by utilizing at least two types of organic EL elements of the present invention which emit different emitting colors.

An organic EL element material of the present invention can be also applied to an organic EL element to generate emission of practically white color as a lighting device. Plural emission colors are simultaneously emitted by plural number of emission materials to obtain white light by mixing colors. A combination of plural emission colors may be either the one, in which three emission maximum wavelengths of three primary colors of blue, green and red are contained, or the other, in which two emission maximum wavelengths, utilizing a relationship of complimentary colors such as blue and yellow, or blue and orange, are contained.

Further, a combination of emission materials to obtain plural number of emission colors may be either a combination comprising plural number of materials which emit phosphoresce or fluorescence, or a combination of a material which emits phosphoresce or fluorescence and a dye material which emits by light from an emission material as exiting light, however, in a white organic electroluminescence element according to the present invention, it is enough only to mix plural light emitting dopants in combination.

A mask is provided only at the time of forming such as an emission layer, a hole transport layer or an electron transport layer, to only simply arrange the plural light emitting dopants such as by separately painting through the mask, while other layers are commonly utilized to require no patterning such as a mask. Therefore, such as an electrode can be formed all over the plane by such as an evaporation method, a cast method, a spin coat method, an inkjet method and a printing method, resulting in improvement of productivity.

According to this method, different from a white organic EL device in which plural colors of emission elements are arranged parallel in an alley form, an element itself is white emitting.

An emission material utilized in an emission layer is not specifically limited, and in the case of a backlight of a liquid crystal display element, any combination by arbitrary selection among platinum complexes according to the present invention or emission materials well known in the art can be utilized so as to be fitted to the wavelength range corresponding to CF (color filter) characteristics, whereby white emission can be obtained.

### <<One Embodiment of Lighting Device of the Present Invention>>

One embodiment of lighting devices provided with an organic EL element of the present invention will be described.

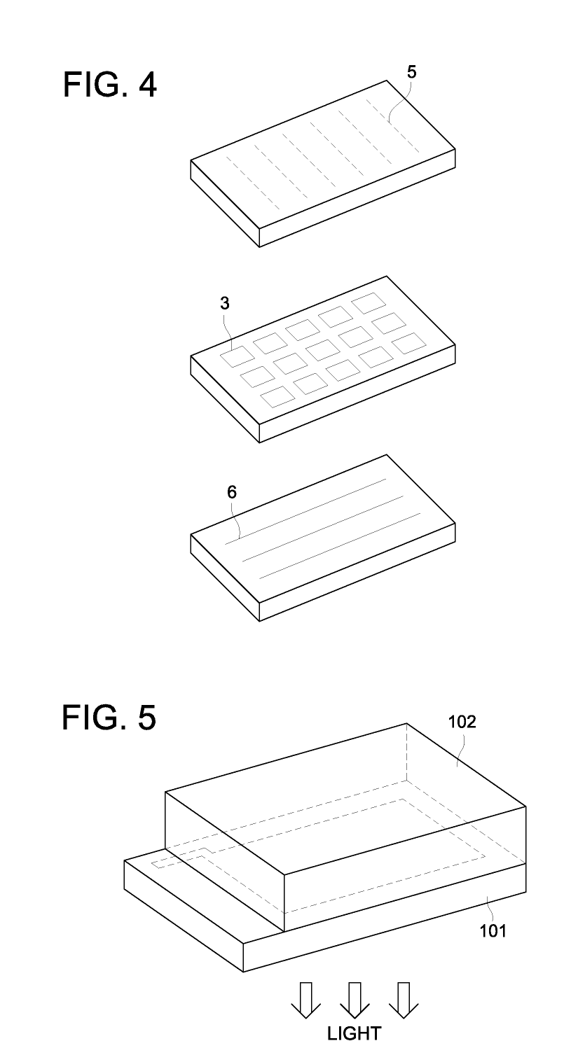

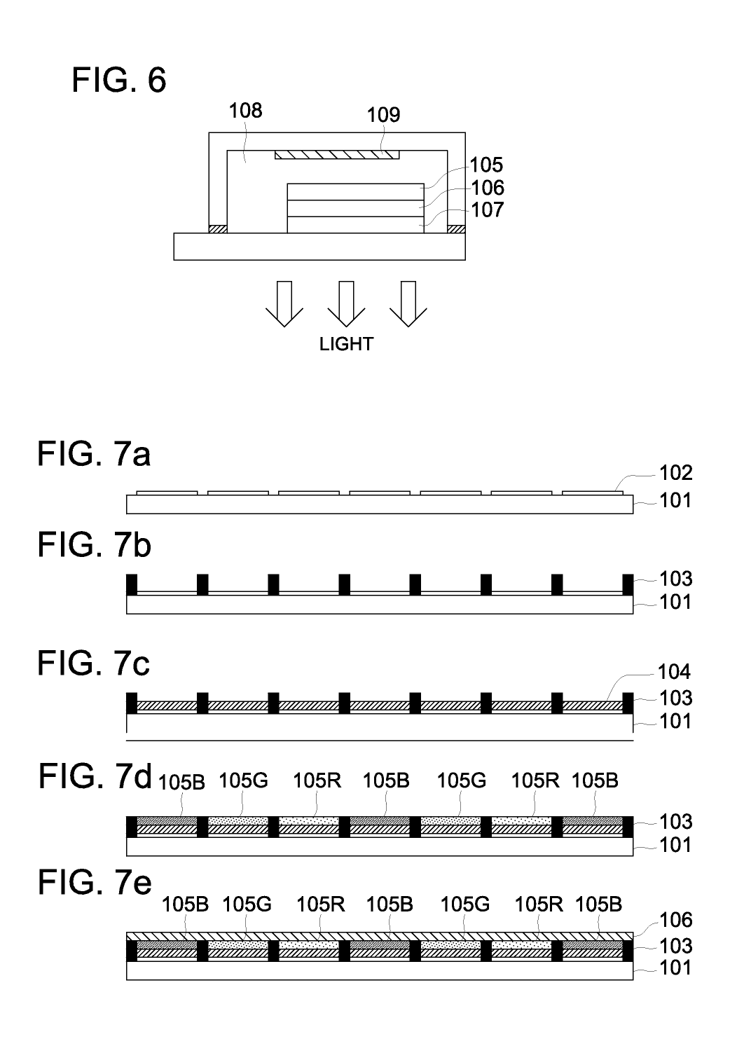

The non-light emitting surface of the organic EL element of the present invention was covered with a glass case, and a 300 μm thick glass substrate was employed as a sealing substrate. An epoxy based light curable type adhesive (LUXTRACK LC0629B produced by Toagosei Co., Ltd.) was employed in the periphery as a sealing material. The resulting one was superimposed on the aforesaid cathode to be brought into close contact with the aforesaid transparent support substrate, and curing and sealing were carried out via exposure of UV radiation onto the glass substrate side, whereby the lighting device shown in FIG. 5 and FIG. 6 was formed.

FIG. 5 is a schematic view of a lighting device and Organic EL element 201 is covered with glass cover 202 (incidentally, sealing by the glass cover was carried out in a globe box under nitrogen ambience (under an ambience of high purity nitrogen gas at a purity of at least 99.999%) so that Organic EL Element 201 was not brought into contact with atmosphere.

FIG. 6 is a cross-sectional view of a lighting device, and in FIG. 6, 205 represents a cathode, 206 represents an organic EL layer, and 207 represents a glass substrate fitted with a transparent electrode. Further, the interior of glass cover 202 is filled with nitrogen gas 208 and water catching agent 209 is provided.

### EXAMPLES

The present invention will now be described with reference to examples, however the present invention is not limited thereto. The indication of “%” is used in Examples. Unless specifically notice, this indicates “mass %”. In addition, the chemical structures of the compounds used in Examples are shown in the followings.

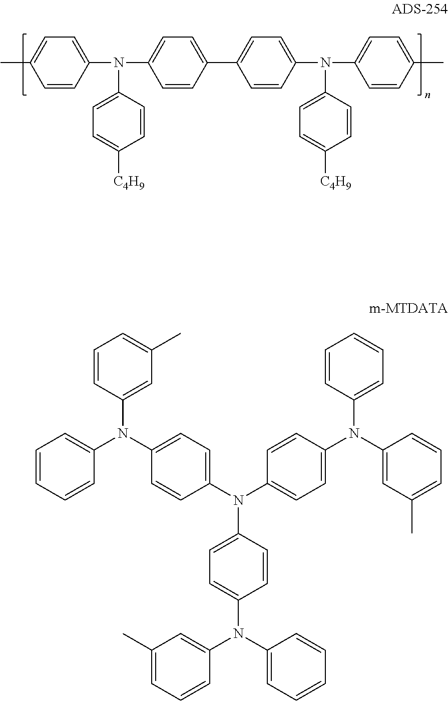

### Example 1

An acrylic clear hard coat was formed on a PEN film (30 cm×30 cm, produced by TEIJIN Co., Ld.) with a slot coater, then it was cured by UV irradiation.

Further, an ITO film of 100 nm was formed on the clear hard coat with a sputter method, then pattering was performed with a resist method. The obtained ITO film has a surface resistivity of 25 Ω/cm² and a surface roughness of 1 nm or less.

A film of PEDPT 4083 (produced by Stark Co. Ltd.) having a thickness of 30 nm was formed with a slit coating method on the ITO film. Then, it was heated to dry at 150° C. for 30 minutes.

Hereafter, an organic EL element was prepared on the obtained film of ITO/PEDOT. The organic EL element was prepared in a glove-box which was controlled water and oxygen content to be 1 ppm or less.

On the PEDOT film was formed a film using a chlorobenzene solution of Poly-N,N′-bis(4-butylphenyl)-N,N′-bis(phenyl)benzidine (ADS-254, produced by American Dye Source, Co., Ltd.) with a slit coating method. The film was heated to dry at 150° C. for 1 hour, thus there was provided with a second hole transport layer having a layer thickness of 40 nm.

On the second hole transport layer was formed a film using a butyl acetate solution of OC-25, D-1 and D-20 (each content ratio, 83.5 mass %:16 mass %:0.5 mass %) with a slit coating method. The film was heated to dry at 120° C. for 1 hour, thus there was provided with a light emitting layer having a layer thickness of 40 nm.

On this light emitting layer was formed a film using a 1,1,1,3,3,3-hexafluoro isopropanol solution of OC-107 with a slit coating method. After forming the film, a polymerizing group of OC-107 was photo-cured by UV irradiation with a low pressure mercury lamp (15 mW/cm²) at 130° C. for 30 seconds. Thus it was provided with an insolubilized electron transport layer having a thickness of 20 nm.

### <<Charge Generating Layer>>

On the electron transport layer was formed a charge generating layer composed of an n-type layer (CGL(n-type)-1 and CGL(n-type)-2)/a p-type layer (CGL(p-type)-1 and CGL(p-type)-2) by changing a preparation method as described below.

### <Charge Generating Layer Preparation Method (1): Slit Coater>

On the electron transport layer was formed a film using a chlorobenzene solution of DBp-6 and AIp-4 (each content ratio was 50.0 mass %:50.0 mass %) with a slit coating method. After forming the film, polymerizing groups of DBp-6 and AIp-4 were photo-cured by UV irradiation with a low pressure mercury lamp (15 mW/cm²) at 130° C. for 30 seconds. Thus it was provided with an insolubilized n-type layer (CGL) having a thickness of 20 nm.

Moreover, on the prepared n-type layer (CGL) was formed a film using a chlorobenzene solution of ACp-3 and ACp-2 (each content ratio was 85.0 mass %:15.0 mass %) with a slit coating method. After forming the film, polymerizing groups of ACp-3 and ACp-2 were photo-cured by UV irradiation with a low pressure mercury lamp (15 mW/cm²) at 130° C. for 30 seconds. Thus it was provided with an insolubilized p-type layer (CGL) having a thickness of 20 nm.

In the slit coating method used above, the coating was carried out while conveying the substrate at a speed of 5 m/min.

### <Charge Generating Layer Preparation Method (2): Screen Printing>

On the electron transport layer was formed a film using a chlorobenzene solution of DBp-6 and AIp-4 (each content ratio was 50.0 mass %:50.0 mass %) with a screen printing method. After forming the film, polymerizing groups of DBp-6 and AIp-4 were photo-cured by UV irradiation with a low pressure mercury lamp (15 mW/cm²) at 130° C. for 30 seconds. Thus it was provided with an insolubilized n-type layer (CGL) having a thickness of 20 nm.

Moreover, on the prepared n-type layer (CGL) was formed a film using a chlorobenzene solution of ACp-3 and ACp-2 (each content ratio was 85.0 mass %:15.0 mass %) with a screen printing method. After forming the film, polymerizing groups of ACp-3 and ACp-2 were photo-cured by UV irradiation with a low pressure mercury lamp (15 mW/cm²) at 130° C. for 30 seconds. Thus it was provided with an insolubilized p-type layer (CGL) having a thickness of 20 nm.

In the screen printing method used above, the coating was carried out while conveying the substrate at a speed of 5 m/min.

### <Charge Generating Layer Preparation Method (3): Spin Coating Method>

On the electron transport layer was formed a film using a chlorobenzene solution of DBp-6 and AIp-4 (each content ratio was 50.0 mass %:50.0 mass %) with a spin coating method. After forming the film, polymerizing groups of DBp-6 and AIp-4 were photo-cured by UV irradiation with a low pressure mercury lamp (15 mW/cm²) at 130° C. for 30 seconds. Thus it was provided with an insolubilized n-type layer (CGL) having a thickness of 20 nm.

Moreover, on the prepared n-type layer (CGL) was farmed a film using a chlorobenzene solution of ACp-3 and ACp-2 (each content ratio was 85.0 mass %:15.0 mass %) with a spin coating method. After forming the film, polymerizing groups of ACp-3 and ACp-2 were photo-cured by UV irradiation with a low pressure mercury lamp (15 mW/cm²) at 130° C. for 30 seconds. Thus it was provided with an insolubilized p-type layer (CGL) having a thickness of 20 nm.

In the spin coating method used above, the coating of one sample was carried out while rotating the material at a speed of 1,500 for 30 seconds.

The coating speed can be calculated provisionally from these data (0.3 m/30 seconds). However, the size of the substrate can be increased. Although this figure is not considered to be a practical speed, it is no doubt that the spin coating production method is inferior to other methods as described above from the viewpoint of production efficiency.

### <Charge Generating Layer Preparation Method (4): Ink-Jet Method>

Subsequently, on the electron transport layer was formed a film using a chlorobenzene solution of DBp-6 and AIp-4 (each content ratio was 50.0 mass %:50.0 mass %) with an ink-jet method. After forming the film, polymerizing groups of DBp-6 and AIp-4 were photo-cured by UV irradiation with a low pressure mercury lamp (15 mW/cm²) at 130° C. for 30 seconds. Thus it was provided with an insolubilized n-type layer (CGL) having a thickness of 20 nm.

Moreover, on the prepared n-type layer (CGL) was formed a film using a chlorobenzene solution of ACp-3 and ACp-2 (each content ratio was 85.0 mass %:15.0 mass %) with an ink-jet method. After forming the film, polymerizing groups of ACp-3 and ACp-2 were photo-cured by UV irradiation with a low pressure mercury lamp (15 mW/cm²) at 130° C. for 30 seconds. Thus it was provided with an insolubilized p-type layer (CGL) having a thickness of 20 nm.

In the ink-jet method used above, the coating was carried out while conveying the substrate at a speed of 0.5 m/min with a resolution of 720 dpi. In this case, the light emitting area had a width of 250 mm and this was the same produced with other production methods.

Further, a charge generating layer was produced with a high speed ejection of 5 m/min. This is called as “Charge generating layer preparation method (5)”. In this case, the light emitting area had a width of 36 mm and this was smaller than the width produced with other coating methods.

Moreover, on this p-type layer (CGL) was formed a film using a chlorobenzene solution of ADS-254 with a slit coating method. The coated film was heated to dry at 150° C. for 1 hour. Thus it was provided with a second hole transport layer having a thickness of 40 nm.

On the second hole transport layer was formed a film using a butyl acetate solution of OC-25, D-1 and D-20 (each content ratio, 83.5 mass %:16 mass %:0.5 mass %) with a slit coating method. The film was heated to dry at 120° C. for 1 hour, thus there was provided with a light emitting layer having a layer thickness of 40 nm.

On this light emitting layer was formed a film using a 1,1,1,3,3,3-hexafluoro isopropanol solution of OC-105 with a slit coating method. Thus it was provided with an insolubilized electron transport layer having a thickness of 20 nm.

Subsequently, this was fixed in a vacuum deposition apparatus, and the pressure of the vacuum tank was reduced to 4×10⁻⁴ Pa. Then, 1.0 nm thick cesium fluoride was deposited to form an electron injection layer, then 110 nm thick aluminum was deposited to form a cathode. Thus an organic EL element having two light emitting units and one CGL was prepared. The charge generating layer was prepared using Charge generating layer preparation methods (1) to (5), whereby Organic EL elements 1-1 to 1-5 were prepared.

The EL properties of the prepared Organic EL elements were evaluated. Especially, luminescence unevenness was evaluated. The production methods were totally evaluated based on the following criteria for coating speed and handling easiness. The evaluation results are shown in the following Table 1.

### Evaluation Methods

### (Luminescence Unevenness)

Each organic EL element was allowed to emit a light with a constant electric current of 2.5 mA/cm² at 23°. The measurement of luminance was done with a spectro radiometric luminance meter CS-1000 (produced by Konica Minolta Sensing Inc.). Luminance was measured at arbitrary ten points and from the measured values, “Luminescence unevenness” was determined as a value of “Lowest luminance in the surface/Highest luminance in the surface”.

### (EL Performance)

Each organic EL element was subjected to measurement and calculation of “external quantum efficiency (%)”, “driving voltage (V)”, and “voltage increase at driving (ΔV)”. The “Luminescence unevenness” was evaluated by using the above-described values.

In the present evaluation, “EL performance” was determined using the following scheme:

EL performance=(external quantum efficiency (%)/driving voltage (V)/voltage increase at driving (ΔV))×(luminescence unevenness).

Evaluation was done using the calculated value.

The evaluation was done based on the relative value setting the value with the ink-jet method to be 100, and it was indicated according to the following criteria.

A: 120 or more

B: 110 or more to less than 120

C: 100 or more to less than 110

D: 100 or less

### (Coating Speed)

In the same manner as described in Example 1, there were prepared on an ITO film of 30 cm width: a hole transport layer, a second hole transport layer, a light emitting layer and an electron transport layer. Then, on the aforesaid electron transport layer was formed a film of a chlorobenzene solution of DBp-6 and AIp-4 (each content ratio was 50.0 mass %:50.0 mass %) in a length of 3 m with 5 different methods of a slit coater, a screen printing, a spray coater, a spin coater and an ink-jet method. The coating speed of the film formation was changed as 0.1 m/min, 0.5 m/min, 1.0 m/min, 3.0 m/min and 5.0 m/min. Among the 3 m coated film, 0.5 m of the initial portion and the end portion each were eliminated, and the remaining 2 m section was visually observed. The maximum coating speed which enabled to form a continuous film was determined as a coating speed. In the present example, since an object is to make clear the properties of each coating method, in principle, one film forming apparatus (unit) was used for each method. However, in the case of using an ink-jet method for preparing Organic EL element 1-4, it was used an apparatus having 9 pieces of 36 mm width ink jet head used for Organic EL element 1-5 arranged in the lateral direction. Further, in the case of a spin coating method for Organic EL element 1-3, which was not possible to perform continuous coating, it was used the conversion value obtained from film formation of 30 cm square in sheet.

### (Productivity)

The productivity was evaluated with fours ranks A, B, C and D from the following viewpoints.

A: Coating speed (speed) is 5 m/min or more, and the defects of unevenness, stripes, and dropout of dots are not recognized in the dried film with visual inspection.

B: Coating speed (speed) is 1 m/min or more, and the defects of unevenness, stripes, and dropout of dots are not recognized in the dried film with visual inspection.

C: Coating speed (speed) is 0.5 m/min or more, and the defects of unevenness, stripes, and dropout of dots are not recognized in the dried film with visual inspection.

D: Coating speed (speed) is less than 0.5 m/min, or one the defects of unevenness, stripes, and dropout of dots is recognized in the dried film with visual inspection.

TABLE 1

| Organic | Coating | | | EL | Luminescence | |
|---|---|---|---|---|---|---|
| EL element | method | Speed | Productivity | performance | unevenness | Remarks |
| 1-1 | Slit coater | 5 m/min | A | A | 0.9 | Present invention |
| 1-2 | Screen printing | 5 m/min | A | B | 0.8 | Present invention |
| 1-3 | Spin coater | 0.6 m/min (Conversion | C | A | 0.9 | Present invention |
| | | value: Sheet method) | | | | |
| 1-4 | Ink-jet (IJ) | 0.5 m/min | D | C | 0.5 | Comparative example |
| 1-5 | Ink-jet (IJ) | 5 m/min (36 mm width) | A | D | 0.22 | Comparative example |

From the results of the present examples, although the ink-jet method enables to keep the productivity for a relatively small sized sample, it produces luminescence unevenness seemingly caused by the unevenness of the film thickness. In the case of expansion of the coating width by using a line ink-jet head, there appears problems such as stripes seemingly caused by ejection defect, and it is clear that there are problems to be solved for increasing productivity in the ink-jet method. When Organic EL element 1-4 and Organic EL element 1-5 are compared from the viewpoint of large sizing, although the luminescence unevenness is improved (from rank D to rank C) by increasing the size of sample, the indented film forming properties for producing Organic EL element of the present invention are not fully satisfied. It is evident the superiority of the non-discharge type solution coating process of the present invention.

Subsequently, the materials in the charge generating layer (CGL): CGL(n-type)-1, CGL(n-type)-2, CGL(p-type)-1 and CGL(p-type)-2 were changed as listed in Table 1. The charge generating layer was formed with a slit coater and an ink-jet method in the same way as described above. Then the same experiment was conducted.

TABLE 2

| | CGL(n-type)-1 | CGL(n-type)-2 | CGL(p-type)-1 | CGL(p-type)-2 |
|---|---|---|---|---|
| 1 | DBp-6 | AIp-4 | ACp-3 | ACp-3 |
| 2 | DBp-6 | AIp-4 | DAmp-4 | AGp-2 |
| 3 | DM-1 | AL-8 | ACp-3 | OC-88 |
| 4 | NC-14 | NC-17 | ACp-3 | ACp-2 |
| 5 | ACp-2 | AIp-1 | ACp-3 | ACp-2 |

Namely, the charge generating layer was formed with a slit coater and an ink-jet method in the same way except that the materials were changed as described above. In addition, the coating solvent was changed from chlorobenzene to tetradecane. The prepared samples were subjected to the evaluation of “Luminescence uniformity in the light emitting surface”.

### (Luminescence Uniformity in the Light Emitting Surface)

Each organic EL element was allowed to emit a light with a constant electric current of 2.5 mA/cm² at 23°. The measurement of luminance was done with a spectro radiometric luminance meter CS-1000 (produced by Konica Minolta Sensing Inc.). Luminance was measured at arbitrary ten points in the light emitting surface and the average value thereof was determined as “Average surface luminescence”. Subsequently, “Lowest surface luminescence/Average surface luminescence” and “Highest surface luminescence/Average surface luminescence” were calculated. And the larger value among these two calculated value was determined as a value of “Luminescence uniformity in the light emitting surface”.

The evaluation results are shown in the following table.

TABLE 3

| | | Luminescence | |
|---|---|---|---|
| | | uniformity in the light | |
| CGL | Method | emitting surface | Remarks |
| 1 | Ink-jet | 0.3 | Comparison |
| 1 | Slit coater | 0.9 | Present invention |
| 2 | Ink-jet | 0.25 | Comparison |
| 2 | Slit coater | 0.95 | Present invention |
| 3 | Ink-jet | 0.35 | Comparison |
| 3 | Slit coater | 0.95 | Present invention |
| 4 | Ink-jet | 0.22 | Comparison |
| 4 | Slit coater | 0.88 | Present invention |
| 5 | Ink-jet | 0.25 | Comparison |
| 5 | Slit coater | 0.89 | Present invention |

From these results, it is clear that luminescence uniformity in the light emitting surface does not depend on the material or solvent used, but it strongly depends on the coating method. Although an ink-jet method has been attracted attention as a production method of a coating type organic EL element, it was revealed from our detailed examination that an ink-jet method was not appropriate for a large-sized production which was intended by the present invention.

### Example 2-1

An EL element having a charge generating layer composed of n and p bilayer was subjected to evaluation.

### <First Unit>

An anode was prepared by making patterning to a glass substrate of 100 mm×100 mm×1.1 mm (NA45 produced by NH Techno Glass Corp.) on which a 100 nm film of ITO (indium tin oxide) was formed. Thereafter, the above transparent support substrate provided with the ITO transparent electrode was subjected to ultrasonic washing with isopropyl alcohol, followed by drying with desiccated nitrogen gas, and was subjected to UV ozone washing for 5 minutes.

On this transparent support substrate thus prepared was applied a 70% solution of poly(3,4-ethylenedioxythiphene)-polystyrene sulfonate (PEDOT/PSS, Baytron P AI 4083 made by Bayer AG.) diluted with water by using a slit coating method to form a film and then the film was dried at 200° C. for one hour. A first hole transport layer having a thickness of 30 nm was prepared.

After the formation of the first hole transport layer, an organic EL element was prepared in a glove-box which was controlled water and oxygen content to be 1 ppm or less.

On the first hole transport layer was formed a film using a chlorobenzene solution of ADS-254 with a slit coating method. The film was heated to dry at 150° C. for 1 hour, thus there was provided with a second hole transport layer having a layer thickness of 40 nm.

On the second hole transport layer was formed a film using a butyl acetate solution of OC-25, D-1 and D-20 (each content ratio, 83.5 mass %:16 mass %:0.5 mass %) with a slit coating method. The film was heated to dry at 120° C. for 1 hour, thus there was provided with a light emitting layer having a layer thickness of 40 nm.

On this light emitting layer was formed a film using a 1,1,1,3,3,3-hexafluoro isopropanol solution of electron transport material OC-107 with a slit coating method. After forming the film, a polymerizing group of OC-107 was photo-cured by UV irradiation with a low pressure mercury lamp (15 mW/cm²) at 130° C. for 30 seconds. Thus it was provided with an insolubilized electron transport layer having a thickness of 20 nm.

### <<Charge Generating Layer>>

### <Charge Generating Layer Preparation Method 1>

On this electron transport layer was formed a film using a chlorobenzene solution of BCP (AK-3) and metal Li (each content ratio was 80.0 mass %:20.0 mass %) with a slit coating method. Thus it was provided with an n-type layer (CGL) having a thickness of 20 nm.

Further, on this n-type layer (CGL) was formed a film using a chlorobenzene solution of m-MTDATA and F4TCNQ (AG-6) (each content ratio was 50.0 mass %:50.0 mass %) with a slit coating method. Thus it was provided with a p-type layer (CGL) having a thickness of 20 nm.

### <Second Unit>

On this p-type layer (CGL) was formed a film using a chlorobenzene solution of ADS-254 with a slit coating method. The film was heated to dry at 150° C. for 1 hour, thus there was provided with a second hole transport layer having a layer thickness of 40 nm.

On the second hole transport layer was formed a film using a butyl acetate solution of OC-25, D-1 and D-20 (each content ratio, 83.5 mass %:16 mass %:0.5 mass %) with a slit coating method. The film was heated to dry at 120° C. for 1 hour, thus there was provided with a light emitting layer having a layer thickness of 40 nm.

On this light emitting layer was formed a film using a 1,1,1,3,3,3-hexafluoro isopropanol solution of an electron transport material OC-105 with a slit coating method. Thus it was provided with an election transport layer having a thickness of 20 nm.

Subsequently, this was fixed in a vacuum deposition apparatus, and the pressure of the vacuum tank was reduced to 4×10⁻⁴ Pa. Then, 1.0 nm thick cesium fluoride was deposited to form an electron injection layer, then 110 nm thick aluminum was deposited to form a cathode,

However, when the p-type layer (CGL) was formed on the n-type layer (CGL), and when the second hole transport layer was formed on the p-type layer (CGL), there was observed effluence of material caused by dissolution of the under layer. As a result, it was not possible to obtain Organic EL element 2-2.

### Example 2-2

An organic EL element having a charge generating layer composed of n/p bilayer GCL was prepared and evaluated.

### <First Unit>

An anode was prepared by making patterning to a glass substrate of 100 mm×100 mm×1.1 mm (NA45 produced by NH Techno Glass Corp.) on which a 100 nm film of ITO (indium tin oxide) was formed. Thereafter, the above transparent support substrate provided with the ITO transparent electrode was subjected to ultrasonic washing with isopropyl alcohol, followed by drying with desiccated nitrogen gas, and was subjected to UV ozone washing for 5 minutes.

On this transparent support substrate thus prepared was applied a 70% solution of poly(3,4-ethylenedioxythiphene)-polystyrene sulfonate (PEDOT/PSS, Baytron P AI 4083 made by Bayer AG.) diluted with water by using a slit coating method to form a film and then the film was dried at 200° C. for one hour. A first hole transport layer having a thickness of 30 nm was prepared.

After the formation of the first hole transport layer, an organic EL element was prepared in a glove-box which was controlled water and oxygen content to be 1 ppm or less.

On the first hole transport layer was formed a film using a chlorobenzene solution of ADS-254 with a slit coating method. The film was heated to dry at 150° C. for 1 hour, thus there was provided with a second hole transport layer having a layer thickness of 40 nm.

On the second hole transport layer was formed a film using a butyl acetate solution of OC-25, D-1 and D-20 (each content ratio, 83.5 mass %:16 mass %:0.5 mass %) with a slit coating method. The film was heated to dry at 120° C. for 1 hour, thus there was provided with a light emitting layer having a layer thickness of 40 nm.

On this light emitting layer was formed a film using a 1,1,1,3,3,3-hexafluoro isopropanol solution of electron transport material OC-107 with a slit coating method. After forming the film, a polymerizing group of OC-107 was photo-cured by UV irradiation with a low pressure mercury lamp (15 mW/cm²) at 130° C. for 30 seconds. Thus it was provided with an insolubilized electron transport layer having a thickness of 20 nm.

### <Charge Generating Layer Preparation Method 2>

Tetra-n-butyl titanate was mixed with 1-butanol under a nitrogen gas to obtain a butanol solution.

The obtained butanol solution was left open for 90 seconds in a room at 25° C. and 50% RH and was stirred. Then, it was transferred in a glove-box controlled under a nitrogen gas, and further it was stirred for 5 minutes under a nitrogen gas.

This butanol solution was applied on an electron transport layer with a slit coating method to form a film. After forming the film, it was irradiated with UV lights using a low pressure mercury lamp (15 mW/cm²) at 130° C. for 30 seconds. Thus it was provided with an insolubilized metal oxide n-type layer (CGL) having a thickness of 20 nm.

In the same mariner as described above, tetraisopropoxystannane was mixed with 1-butanol under a nitrogen gas to obtain a butanol solution.

The obtained butanol solution was left open for 30 seconds in a room at 25° C. and 50% RH and was stirred. Then, it was transferred in a glove-box controlled under a nitrogen gas, and further it was stirred for 5 minutes under a nitrogen gas.

This butanol solution was applied on the p-type layer (CGL) with a slit coating method to form a film. After forming the film, it was irradiated with UV lights using a low pressure mercury lamp (15 mW/cm²) at 130° C. for 30 seconds. Thus it was provided with an insolubilized metal oxide p-type layer (CGL) having a thickness of 20 nm.

### <Second Unit>

Further, on this p-type layer (CGL) was formed a film using a chlorobenzene solution of ADS-254 with a slit coating method. The film was heated to dry at 150° C. for 1 hour, thus there was provided with a hole transport layer having a layer thickness of 40 nm.

On this hole transport layer was formed a film using a butyl acetate solution of OC-25, D-1 and D-20 (each content ratio, 83.5 mass %:16 mass %:0.5 mass %) with a slit coating method. The film was heated to thy at 120° C. for 1 hour, thus there was provided with a light emitting layer having a layer thickness of 40 nm.

On this light emitting layer was formed a film using a 1,1,1,3,3,3-hexafluoro isopropanol solution of an electron transport material OC-105 with a slit coating method. Thus it was provided with an electron transport layer having a thickness of 20 nm.

This was fixed in a vacuum deposition apparatus, and the pressure of the vacuum tank was reduced to 4×10⁻⁴ Pa. Then, 1.0 nm thick cesium fluoride was deposited to form an electron injection layer, then 110 nm thick aluminum was deposited to form a cathode. Thus Organic EL element 2-4 having two light emitting units and one CGL was prepared.

Organic EL element 2-5 was prepared in the same manner as described above except that tetra-n-butyl titanate was replaced with tetra-n-butyl zirconate for producing an n-type layer in a charge generating layer.

Organic EL element 2-3 was prepared in the same manner as described above except that a metal oxide layer prepared from tetra-n-butyl titanate was used

### Example 2-3

An organic EL element having a charge generating layer composed of n/p bilayer GCL was prepared and evaluated.

### <First Unit>

An anode was prepared by making patterning to a glass substrate of 100 mm×100 mm×1.1 mm (NA45 produced by NH Techno Glass Corp.) on which a 100 nm film of ITO (indium tin oxide) was formed. Thereafter, the above transparent support substrate provided with the ITO transparent electrode was subjected to ultrasonic washing with isopropyl alcohol, followed by drying with desiccated nitrogen gas, and was subjected to UV ozone washing for 5 minutes.

On this transparent support substrate thus prepared was applied a 70% solution of poly(3,4-ethylenedioxythiphene)-polystyrene sulfonate (PEDOT/PSS, Baytron P AI 4083 made by Bayer AG.) diluted with water by using a slit coating method to form a film and then the film was dried at 200° C. for one hour. A first hole transport layer having a thickness of 30 nm was prepared.

After the formation of the first hole transport layer, an organic EL element was prepared in a glove-box which was controlled water and oxygen content to be 1 ppm or less.

On the first hole transport layer was formed a film using a chlorobenzene solution of ADS-254 with a slit coating method. The film was heated to dry at 150° C. for 1 hour, thus there was provided with a second hole transport layer having a layer thickness of 40 nm.

On the second hole transport layer was formed a film using a butyl acetate solution of OC-25, D-1 and D-20 (each content ratio, 83.5 mass %:16 mass %:0.5 mass %) with a slit coating method. The film was heated to dry at 120° C. for 1 hour, thus there was provided with a light emitting layer having a layer thickness of 40 nm.

On this light emitting layer was formed a film using a 1,1,1,3,3,3-hexafluoro isopropanol solution of electron transport material OC-107 with a slit coating method. After forming the film, a polymerizing group of OC-107 was photo-cured by UV irradiation with a low pressure mercury lamp (15 mW/cm²) at 130° C. for 30 seconds. Thus it was provided with an insolubilized electron transport layer having a thickness of 20 nm.

### <Charge Generating Layer Preparation Method 3>>

Tetra-n-butyl titanate was mixed with 1-butanol under a nitrogen gas to obtain a butanol solution.

The obtained butanol solution was left open for 90 seconds in a room at 25° C. and 50% RH and was stirred. Then, it was transferred in a glove-box controlled under a nitrogen gas, and further it was stirred for 5 minutes under a nitrogen gas. Then, a butanol dispersion liquid of titanium oxide was added to this liquid.

This butanol solution was applied on an electron transport layer with a slit coating method to form a film. After forming the film, it was irradiated with UV lights using a low pressure mercury lamp (15 mW/cm²) at 130° C. for 30 seconds. Thus it was provided with an insolubilized metal oxide n-type layer (CGL) having a thickness of 20 nm.

In the same manner as described above, tetraisopropoxystannane was mixed with 1-butanol under a nitrogen gas to obtain a butanol solution.

The obtained butanol solution was left open for 30 seconds in a room at 25° C. and 50% RH and was stirred. Then, it was transferred in a glove-box controlled under a nitrogen gas, and further it was stirred for 5 minutes under a nitrogen gas.

This butanol solution was applied on the p-type layer (CGL) with a slit coating method to form a film. After forming the film, it was irradiated with UV lights using a low pressure mercury lamp (15 mW/cm²) at 130° C. for 30 seconds. Thus it was provided with an insolubilized metal oxide p-type layer (CGL).

### <Second Unit>

Further, on this p-type layer (CGL) was formed a film using a chlorobenzene solution of ADS-254 with a slit coating method. The film was heated to dry at 150° C. for 1 hour, thus there was provided with a hole transport layer having a layer thickness of 40 nm.

On this hole transport layer was formed a film using a butyl acetate solution of OC-25, D-1 and D-20 (each content ratio, 83.5 mass %:16 mass %:0.5 mass %) with a slit coating method. The film was heated to dry at 120° C. for 1 hour, thus there was provided with a light emitting layer having a layer thickness of 40 nm.

On this light emitting layer was formed a film using a 1,1,1,3,3,3-hexafluoro isopropanol solution of electron transport material OC-105 with a slit coating method. Thus it was provided with an electron transport layer having a thickness of 20 nm.

This was fixed in a vacuum deposition apparatus, and the pressure of the vacuum tank was reduced to 4×10⁻⁴ Pa. Then, 1.0 nm thick cesium fluoride was deposited to form an electron injection layer, then 110 nm thick aluminum was deposited to form a cathode. Thus Organic EL element 2-6 having two light emitting units and one CGL was prepared.

Organic EL element 2-7 was prepared in the same manner as described above except that tetra-n-butyl titanate was replaced with tetra-n-butyl zirconate and titanium oxide butanol dispersion liquid was replaced with zirconia dispersion liquid for producing an n-type layer in a charge generating layer.

### Example 2-4 (Comparative example)

An anode was prepared by making patterning to a glass substrate of 100 mm×100 mm×1.1 mm (NA45 produced by NH Techno Glass Corp.) on which a 100 nm film of ITO (indium tin oxide) was formed. Thereafter, the above transparent support substrate provided with the ITO transparent electrode was subjected to ultrasonic washing with isopropyl alcohol, followed by drying with desiccated nitrogen gas, and was subjected to UV ozone washing for 5 minutes.

On this transparent support substrate thus prepared was applied a 70% solution of poly(3,4-ethylenedioxythiphene)-polystyrene sulfonate (PEDOT/PSS, Baytron P AI 4083 made by Bayer AG.) diluted with water by using a slit coating method to form a film and then the film was dried at 200° C. for one hour. A first hole transport layer having a thickness of 30 nm was prepared.

After the formation of the first hole transport layer, an organic EL element was prepared in a glove-box which was controlled water and oxygen content to be 1 ppm or less.

On the first hole transport layer was formed a film using a chlorobenzene solution of ADS-254 with a slit coating method. The film was heated to dry at 150° C. for 1 hour, thus there was provided with a second hole transport layer having a layer thickness of 40 nm.

On the second hole transport layer was formed a film using a butyl acetate solution of OC-25, D-1 and D-20 (each content ratio, 83.5 mass %:16 mass %:0.5 mass %) with a slit coating method. The film was heated to dry at 120° C. for 1 hour, thus there was provided with a light emitting layer having a layer thickness of 40 nm.

On this light emitting layer was formed a film using a 1,1,1,3,3,3-hexafluoro isopropanol solution of electron transport material OC-107 with a slit coating method. After forming the film, a polymerizing group of OC-107 was photo-cured by UV irradiation with a low pressure mercury lamp (15 mW/cm²) at 130° C. for 30 seconds. Thus it was provided with an insolubilized electron transport layer having a thickness of 20 nm.

### <Charge Generating Layer Preparation Method 4>

Subsequently, this was fixed in a vacuum deposition apparatus, and the pressure of the vacuum tank was reduced to 4×10⁻⁴ Pa.

Then, a vacuum co-deposition film of BCP (AK-3) and Li (each content ratio was 99:1 vol %) was formed with a thickness of 20 nm to make an n-type layer. The vacuum deposition of Li was made with a Li source boat made by SAES Getters Co., Ltd.

Further, on this n-type layer (CGL) was formed a vacuum co-deposition film of m-MTDATA and F4TCNQ (AG-6) (each content ratio was 90:10 vol %) with a thickness of 10 nm to make a p-type layer.

Further, α-NPD (Dam-1) was vacuum deposited to make a second hole transport layer with a thickness of 40 nm.

On the α-NPD layer was vacuum deposited using 3 elements of OC-25, D-1 and D-20 (each content ratio, 83.5 mass %:16 mass %:0.5 mass %) to make a second light emitting layer with a thickness of 40 nm.

Further, an electron transport material BCP (AK-3) was vacuum deposited on the second light emitting layer to make a layer of 20 nm.

Then, 1.0 nm thick cesium fluoride was deposited to form an electron injection layer, then 110 nm thick aluminum was deposited to form a cathode. Thus Organic EL element 2-1 (comparative sample) having two light emitting units and one CGL was prepared.

### <<Evaluation of Organic EL Elements 2-1 to 2-7>>

In order to evaluate the obtained organic EL elements, the following processes were done to them. The non-light emitting surface of each of the organic EL elements was covered with a glass cover having a thickness of 300 μm. As a sealing material, an epoxy based light curable type adhesive (LUXTRACK LC0629B produced by Toagosei Co., Ltd.) was applied to the periphery of the glass cover where the glass cover and the grass substrate prepared thereon Organic EL element were contacted. The resulting one was superimposed on the aforesaid cathode side to be brought into close contact with the aforesaid transparent support substrate, and curing and sealing were carried out via exposure of UV radiation onto the glass substrate side, whereby the lighting device shown in FIG. 5 and FIG. 6 was formed. The organic EL elements were evaluated using the lighting devices. External quantum efficiency, driving voltage, initial luminescence change and voltage increase during driving of the Organic EL elements were evaluated. The evaluation conditions for each evaluation item will be shown below.

Initial luminescence change “ΔL” indicates a luminescence change after 100 hr of driving with a constant electric current at initial luminescence 3,000 cd/m².

ΔL={(Luminescence after driving for 100 hr/Initial luminescence (3,000 cd/m²)}×100

The luminescence change “ΔL” was represented by a relative value when luminescence change “ΔL” of a comparative organic EL element was set to be 100.

“Voltage increase during driving” indicates a ratio of a voltage at a half decreased luminescence to a voltage of a constant electric current at an initial luminescence of 3,000 cd/m².

ΔV=(Voltage at a half decreased luminescence/Initial voltage)×100

### <<External Quantum Efficiency>>

Each organic EL element was allowed to emit a light with a constant electric current of 2.5 mA/cm² at room temperature 23° C. under a nitrogen gas. The external quantum efficiency (%) was determined. Here, the measurement of luminance was done with a spectro radiometric luminance meter CS-1000 (produced by Konica Minolta Sensing Inc.). The external quantum efficiency was represented by the relative value when the external quantum efficiency of Comparative example 1 was set to be 100 (EQE).

### <<Driving Voltage>>

Each organic EL element was allowed to emit a light with a constant electric current of 2.5 mA/cm² at room temperature 23° C. under a nitrogen gas and its voltage was measured. A relative evaluation was done using a relative value when the voltage value of Comparative example 1 was set to be 100.

The obtained results are shown in Table 4.

TABLE 4

| Organic | Charge generating layer | | Charge generating | | External | Driving | Initial | Voltage | |
|---|---|---|---|---|---|---|---|---|---|
| EL | n-type layer | p-type layer | layer preparation | Production | quantum | voltage | luminescence | increase during | |
| element | (CGL) | (CGL) | method | method | efficiency | V | change ΔL | driving ΔV | Remarks |
| 2-1 | BCP:Li | m-MTDATA: | Vacuum | Vacuum | 100 | 100 | 100 | 100 | Comparative |
| | | F4TCNQ | deposition | deposition | | | | | example |
| 2-2 | BCP:Li | m-MTDATA: | 1 | Coating | (Unable to produce) | | | | Comparative |
| | | F4TCNQ | | | | | | | example |
| 2-3 | TiO₂ | | 2 | Coating | 100 | 101 | 105 | 95 | Present invention |
| 2-4 | TiO₂ | SnO₂ | 2 | Coating | 102 | 94 | 120 | 88 | Present invention |
| 2-5 | ZrO₂ | SnO₂ | 2 | Coating | 100 | 95 | 115 | 90 | Present invention |
| 2-6 | TiO₂ nano | SnO₂ | 3 | Coating | 103 | 92 | 135 | 85 | Present invention |
| | particles: | | | | | | | | |
| | TiO₂ sol-gel | | | | | | | | |
| 2-7 | ZrO₂ nano | SnO₂ | 3 | Coating | 102 | 89 | 138 | 83 | Present invention |
| | particles: | | | | | | | | |
| | ZrO₂ sol-gel | | | | | | | | |

In the present invention, there is almost no difference of performance of organic EL element between the light emitting unit prepared by vacuum deposition an the light emitting unit prepared by coating. The effects of the present invention are shown in Table 4. The different performances were not resulted from the methods of coating and vacuum deposition.

### Example 2-5

Organic EL elements 2-8 to 2-115 were prepared in the same manner as used for preparation in Example 1, except that a light emitting host material, a light emitting dopant, an electron transfer material, materials of CGL(n-type) and CGL(p-type) in a charge generating layer were changed as shown in the following Table 5 to Table 22, and by using Charge generating layer preparation method 1 which is described in Example 1.

An element prepared in the same manner as Example 2-4 (Comparative example) was used as a comparative element. In the charge generating layer described in Tables, a colon (:) indicates that the material is composed of a mixture of plural kinds. The mass ratio of each material used for the mixture is indicated in the parentheses. When it is not indicated in particular, it means equal amount (in the case of two components, 50 mass %:50 mass %).

In order to evaluate the obtained organic EL elements, the following processes were done to them in the same manner as described above. The non-light emitting surface of each of the organic EL elements was covered with a glass cover having a thickness of 300 μm. As a sealing material, an epoxy based light curable type adhesive (LUXTRACK LC0629B produced by Toagosei Co., Ltd.) was applied to the periphery of the glass cover where the glass cover and the grass substrate prepared thereon Organic EL element were contacted. The resulting one was superimposed on the aforesaid cathode side to be brought into close contact with the aforesaid transparent support substrate, and curing and sealing were caned out via exposure of UV radiation onto the glass substrate side, whereby the lighting device shown in FIG. 5 and FIG. 6 was formed. The organic EL elements were evaluated using the lighting devices. External quantum efficiency, driving voltage, initial luminescence change and voltage increase during driving of the Organic EL elements were evaluated with the same evaluation methods.

The obtained results are shown in Table 5 to Table 22.

TABLE 5

| | First unit | | | Second unit | | | Charge generating | |
|---|---|---|---|---|---|---|---|---|
| | Light emitting layer | | | Light emitting layer | | | layer | |
| Organic | Light | Light | Election | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-8 | OC-25 | D-1:D-20 | OC-107 | OC-25 | D-1:D-20 | OC-105 | BCP:Li | m-MTDATA: |
| | | | | | | | | F4TCNQ |
| 2-9 | OC-25 | D-1:D-20 | OC-107 | OC-25 | D-1:D-20 | OC-105 | BCP:Li | m-MTDATA: |
| | | | | | | | | F4TCNQ |
| 2-10 | OC-25 | D-1:D-20 | OC-107 | OC-25 | D-1:D-20 | OC-105 | DAp-1: | DM-2: |
| | | | | | | | ALp-4 | AP-3 |
| 2-11 | OC-25 | D-1:D-20 | OC-107 | OC-25 | D-1:D-20 | OC-105 | DAp-2: | AC-8 |
| | | | | | | | AMp-2 | |
| 2-12 | OC-25 | D-1:D-20 | OC-107 | OC-25 | D-1:D-20 | OC-105 | DAp-3: | DAm-1: |
| | | | | | | | AM-1 | AC-7 |
| 2-13 | OC-25 | D-1:D-20 | OC-107 | OC-25 | D-1:D-20 | OC-105 | DAp-2 | DB-11: |
| | | | | | | | | AI-8 |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-8 | Vacuum | Vacuum | 100 | 100 | 100 | 100 | Comp. |
| | deposition | deposition | | | | | |
| 2-9 | 1 | Coating | (Unable to produce) | | | | Comp. |
| 2-10 | 1 | Coating | 101 | 94 | 121 | 84 | Inv. |
| 2-11 | 1 | Coating | 104 | 97 | 135 | 87 | Inv. |
| 2-12 | 1 | Coating | 102 | 92 | 134 | 80 | Inv. |
| 2-13 | 1 | Coating | 106 | 99 | 128 | 82 | Inv. |

*1: Driving voltage V,
*2: Initial luminescence change ΔL,
*3: Voltage increase during driving ΔV
Comp.: Comparative example, Inv.: Present invention

TABLE 6

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-14 | OC-15 | D-1:D-20 | OC-107 | OC-25 | D-1:D-20 | BCP | BCP:Li | m-MTDATA: |
| | | | | | | | | F4TCNQ |
| 2-15 | OC-15 | D-1:D-20 | OC-107 | OC-25 | D-1:D-20 | OC-105 | BCP:Li | m-MTDATA: |
| | | | | | | | | F4TCNQ |
| 2-16 | OC-15 | D-1:D-20 | OC-107 | OC-25 | D-1:D-20 | OC-105 | DBp-1: | ACp-3 |
| | | | | | | | ANp-3 | |
| 2-17 | OC-15 | D-1:D-20 | OC-107 | OC-25 | D-1:D-20 | OC-105 | DBp-1: | DFp-1: |
| | | | | | | | APp-2 | AG-6 |
| 2-18 | OC-15 | D-1:D-20 | OC-107 | OC-25 | D-1:D-20 | OC-105 | DBp-1: | DFp-1: |
| | | | | | | | AN-9 | AOp-2 |
| 2-19 | OC-15 | D-1:D-20 | OC-107 | OC-25 | D-1:D-20 | OC-105 | DBp-1: | DAp-2: |
| | | | | | | | AC-8 | APp-2 |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-14 | Vacuum | Vacuum | 100 | 100 | 100 | 100 | Comp. |
| | deposition | deposition | | | | | |
| 2-15 | 1 | Coating | (Unable to produce) | | | | Comp. |
| 2-16 | 1 | Coating | 102 | 89 | 131 | 86 | Inv. |
| 2-17 | 1 | Coating | 106 | 97 | 138 | 85 | Inv. |
| 2-18 | 1 | Coating | 106 | 98 | 137 | 89 | Inv. |
| 2-19 | 1 | Coating | 103 | 99 | 125 | 81 | Inv. |

*1: Driving voltage V,
*2: Initial luminescence change ΔL,
*3: Voltage increase during driving ΔV
Comp.: Comparative example, Inv.: Present invention

TABLE 7

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-20 | OC-25 | D-1:D-20 | OC-106 | OC-25 | D-1:D-20 | OC-105 | BCP:Li | m-MTDATA: |
| | | | | | | | | F4TCNQ |
| 2-21 | OC-25 | D-1:D-20 | OC-106 | OC-25 | D-1:D-20 | OC-105 | BCP:Li | m-MTDATA: |
| | | | | | | | | F4TCNQ |
| 2-22 | OC-25 | D-1:D-20 | OC-106 | OC-25 | D-1:D-20 | OC-105 | DCp-1: | DCp-1: |
| | | | | | | | AOp-1 | ACp-1 |
| 2-23 | OC-25 | D-1:D-20 | OC-106 | OC-25 | D-1:D-20 | OC-105 | DCp-6: | DMp-1: |
| | | | | | | | AG-4 | AIp-2 |
| 2-24 | OC-25 | D-1:D-20 | OC-106 | OC-25 | D-1:D-20 | OC-105 | DCp-8: | ACp-3 |
| | | | | | | | AI-7 | |
| 2-25 | OC-25 | D-1:D-20 | OC-106 | OC-25 | D-1:D-20 | OC-105 | DCp-10: | DAp-2: |
| | | | | | | | AI-2 | APp-2 |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-20 | Vacuum | Vacuum | 100 | 100 | 100 | 100 | Comp. |
| | deposition | deposition | | | | | |
| 2-21 | 1 | Coating | (Unable to produce) | | | | Comp. |
| 2-22 | 1 | Coating | 102 | 97 | 134 | 84 | Inv. |
| 2-23 | 1 | Coating | 101 | 93 | 125 | 81 | Inv. |
| 2-24 | 1 | Coating | 102 | 96 | 135 | 85 | Inv. |
| 2-25 | 1 | Coating | 102 | 98 | 128 | 92 | Inv. |

*1: Driving voltage V,
*2: Initial luminescence change ΔL,
*3: Voltage increase during driving ΔV
Comp.: Comparative example, Inv.: Present invention

TABLE 8

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-26 | OC-15 | D-1:D-20 | OC-107 | OC-25 | D-1:D-20 | OC-105 | BCP:Li | m-MTDATA: |
| | | | | | | | | F4TCNQ |
| 2-27 | OC-15 | D-1:D-20 | OC-107 | OC-25 | D-1:D-20 | OC-105 | BCP:Li | m-MTDATA: |
| | | | | | | | | F4TCNQ |
| 2-28 | OC-15 | D-1:D-20 | OC-107 | OC-25 | D-1:D-20 | OC-105 | DDp-1: | DAmp-2: |
| | | | | | | | AGp-2 | AG-6 |
| 2-29 | OC-15 | D-1:D-20 | OC-107 | OC-25 | D-1:D-20 | OC-105 | DDp-2: | ACp-3 |
| | | | | | | | AIp-3 | |
| 2-30 | OC-15 | D-1:D-20 | OC-107 | OC-25 | D-1:D-20 | OC-105 | DDp-2: | DBp-1: |
| | | | | | | | AK-7 | AOp-2 |
| 2-31 | OC-15 | D-1:D-20 | OC-107 | OC-25 | D-1:D-20 | OC-105 | DDp-1: | DFp-1: |
| | | | | | | | AL-5 | APp-1 |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-26 | Vacuum | Vacuum | 100 | 100 | 100 | 100 | Comp. |
| | deposition | deposition | | | | | |
| 2-27 | 1 | Coating | (Unable to produce) | | | | Comp. |
| 2-28 | 1 | Coating | 103 | 89 | 137 | 86 | Inv. |
| 2-29 | 1 | Coating | 105 | 98 | 135 | 83 | Inv. |
| 2-30 | 1 | Coating | 105 | 89 | 137 | 83 | Inv. |
| 2-31 | 1 | Coating | 104 | 87 | 127 | 87 | Inv. |

*1: Driving voltage V,
*2: Initial luminescence change ΔL,
*3: Voltage increase during driving ΔV
Comp.: Comparative example, Inv.: Present invention

TABLE 9

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-32 | OC-25 | D-1:D-20 | OC-107 | OC-25 | D-1:D-20 | OC-104 | BCP:Li | m-MTDATA: |
| | | | | | | | | F4TCNQ |
| 2-33 | OC-25 | D-1:D-20 | OC-107 | OC-25 | D-1:D-20 | OC-104 | BCP:Li | m-MTDATA: |
| | | | | | | | | F4TCNQ |
| 2-34 | OC-25 | D-1:D-20 | OC-107 | OC-25 | D-1:D-20 | OC-104 | DEp-1: | DA-2: |
| | | | | | | | ALp-4 | AC-7 |
| 2-35 | OC-25 | D-1:D-20 | OC-107 | OC-25 | D-1:D-20 | OC-104 | DEp-2: | DCp-1: |
| | | | | | | | ANp-3 | AIp-1 |
| 2-36 | OC-25 | D-1:D-20 | OC-107 | OC-25 | D-1:D-20 | OC-104 | DEp-2: | ACp-3 |
| | | | | | | | AM-1 | |
| 2-37 | OC-25 | D-1:D-20 | OC-107 | OC-25 | D-1:D-20 | OC-104 | DEp-1: | DMp-1: |
| | | | | | | | AN-9 | AG-6 |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-32 | Vacuum | Vacuum | 100 | 100 | 100 | 100 | Comp. |
| | deposition | deposition | | | | | |
| 2-33 | 1 | Coating | (Unable to produce) | | | | Comp. |
| 2-34 | 1 | Coating | 102 | 99 | 129 | 81 | Inv. |
| 2-35 | 1 | Coating | 103 | 91 | 131 | 88 | Inv. |
| 2-36 | 1 | Coating | 104 | 98 | 139 | 86 | Inv. |
| 2-37 | 1 | Coating | 105 | 97 | 134 | 84 | Inv. |

*1: Driving voltage V,
*2: Initial luminescence change ΔL,
*3: Voltage increase during driving ΔV
Comp.: Comparative example, Inv.: Present invention

TABLE 10

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-38 | OC-25 | D-1:D-20 | OC-107 | OC-15 | D-1:D-20 | OC-105 | BCP:Li | m-MTDATA: |
| | | | | | | | | F4TCNQ |
| 2-39 | OC-25 | D-1:D-20 | OC-107 | OC-15 | D-1:D-20 | OC-105 | BCP:Li | m-MTDATA: |
| | | | | | | | | F4TCNQ |
| 2-40 | OC-25 | D-1:D-20 | OC-107 | OC-15 | D-1:D-20 | OC-105 | DFp-1: | ACp-3 |
| | | | | | | | APp-2 | |
| 2-41 | OC-25 | D-1:D-20 | OC-107 | OC-15 | D-1:D-20 | OC-105 | DFp-1: | DAmp-1: |
| | | | | | | | AOp-1 | AOp-2 |
| 2-42 | OC-25 | D-1:D-20 | OC-107 | OC-15 | D-1:D-20 | OC-105 | DFp-2: | DFp-2: |
| | | | | | | | AC-8 | APp-1 |
| 2-43 | OC-25 | D-1:D-20 | OC-107 | OC-15 | D-1:D-20 | OC-105 | DFp-1: | DFp-2: |
| | | | | | | | AH-4 | ACp-3 |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-38 | Vacuum | Vacuum | 100 | 100 | 100 | 100 | Comp. |
| | deposition | deposition | | | | | |
| 2-39 | 1 | Coating | (Unable to produce) | | | | Comp. |
| 2-40 | 1 | Coating | 102 | 99 | 126 | 86 | Inv. |
| 2-41 | 1 | Coating | 104 | 88 | 120 | 84 | Inv. |
| 2-42 | 1 | Coating | 102 | 99 | 139 | 89 | Inv, |
| 2-43 | 1 | Coating | 103 | 92 | 126 | 80 | Inv. |

*1: Driving voltage V,
*2: Initial luminescence change ΔL,
*3: Voltage increase during driving ΔV
Comp.: Comparative example, Inv.: Present invention

TABLE 11

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-44 | OC-25 | D-1:D-20 | OC-107 | OC-25 | D-1:D-20 | OC-104 | BCP:Li | m-MTDATA: |
| | | | | | | | | F4TCNQ |
| 2-45 | OC-25 | D-1:D-20 | OC-107 | OC-25 | D-1:D-20 | OC-104 | BCP:Li | m-MTDATA: |
| | | | | | | | | F4TCNQ |
| 2-46 | OC-25 | D-1:D-20 | OC-107 | OC-25 | D-1:D-20 | OC-104 | DNp-1: | DAp-2: |
| | | | | | | | AGp-2 | ACp-2 |
| 2-47 | OC-25 | D-1:D-20 | OC-107 | OC-25 | D-1:D-20 | OC-104 | DNp-1: | ACp-3 |
| | | | | | | | AIp-3 | |
| 2-48 | OC-25 | D-1:D-20 | OC-107 | OC-25 | D-1:D-20 | OC-104 | DNp-2: | DCp-2: |
| | | | | | | | AI-7 | AIp-2 |
| 2-49 | OC-25 | D-1:D-20 | OC-107 | OC-25 | D-1:D-20 | OC-104 | DNp-2: | DMp-1: |
| | | | | | | | AK-7 | AGp-2 |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-44 | Vacuum | Vacuum | 100 | 100 | 100 | 100 | Comp. |
| | deposition | deposition | | | | | |
| 2-45 | 1 | Coating | (Unable to produce) | | | | Comp. |
| 2-46 | 1 | Coating | 101 | 89 | 137 | 87 | Inv. |
| 2-47 | 1 | Coating | 102 | 98 | 124 | 84 | Inv. |
| 2-48 | 1 | Coating | 103 | 100 | 122 | 81 | Inv. |
| 2-49 | 1 | Coating | 101 | 91 | 131 | 82 | Inv. |

*1: Driving voltage V,
*2: Initial luminescence change ΔL,
*3: Voltage increase during driving ΔV
Comp.: Comparative example, Inv.: Present invention

TABLE 12

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-50 | OC-16 | D-1:D-20 | OC-107 | OC-25 | D-1:D-20 | BCP | BCP:Li | m-MTDATA: |
| | | | | | | | | F4TCNQ |
| 2-51 | OC-16 | D-1:D-20 | OC-107 | OC-25 | D-1:D-20 | OC-105 | BCP:Li | m-MTDATA: |
| | | | | | | | | F4TCNQ |
| 2-52 | OC-16 | D-1:D-20 | OC-107 | OC-25 | D-1:D-20 | OC-105 | DAmp-1: | DAmp-2: |
| | | | | | | | ALp-4 | AOp-1 |
| 2-53 | OC-16 | D-1:D-20 | OC-107 | OC-25 | D-1:D-20 | OC-105 | DAmp-3: | DBp-1: |
| | | | | | | | AMp-2 | APp-2 |
| 2-54 | OC-16 | D-1:D-20 | OC-107 | OC-25 | D-1:D-20 | OC-105 | DAmp-4: | DCp-9: |
| | | | | | | | AL-5 | ACp-3 |
| 2-55 | OC-16 | D-1:D-20 | OC-107 | OC-25 | D-1:D-20 | OC-105 | DAmp-3: | ACp-3 |
| | | | | | | | AM-1 | |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-50 | Vacuum | Vacuum | 100 | 100 | 100 | 100 | Comp. |
| | deposition | deposition | | | | | |
| 2-51 | 1 | Coating | (Unable to produce) | | | | Comp. |
| 2-52 | 1 | Coating | 103 | 100 | 137 | 85 | Inv. |
| 2-53 | 1 | Coating | 103 | 91 | 135 | 82 | Inv. |
| 2-54 | 1 | Coating | 103 | 90 | 135 | 84 | Inv. |
| 2-55 | 1 | Coating | 101 | 97 | 127 | 86 | Inv. |

*1: Driving voltage V,
*2: Initial luminescence change ΔL,
*3: Voltage increase during driving ΔV
Comp.: Comparative example, Inv.: Present invention

TABLE 13

| | First unit | | | Second unit | | | | |
|---|---|---|---|---|---|---|---|---|
| | Light emitting layer | | | Light emitting layer | | | Charge generating layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-56 | OC-25 | D-2:D-20 | OC-107 | OC-25 | D-1:D-20 | OC-105 | BCP:Li | m-MTDATA: |
| | | | | | | | | F4TCNQ |
| 2-57 | OC-25 | D-2:D-20 | OC-107 | OC-25 | D-1:D-20 | OC-105 | BCP:Li | m-MTDATA: |
| | | | | | | | | F4TCNQ |
| 2-58 | OC-25 | D-2:D-20 | OC-107 | OC-25 | D-1:D-20 | OC-105 | DMp-1: | DAp-2: |
| | | | | | | | ANp-3 | AG-6 |
| 2-59 | OC-25 | D-2:D-20 | OC-107 | OC-25 | D-1:D-20 | OC-105 | DMp-1: | DCp-1: |
| | | | | | | | APp-2 | AOp-1 |
| 2-60 | OC-25 | D-2:D-20 | OC-107 | OC-25 | D-1:D-20 | OC-105 | DMp-2: | DMp-1: |
| | | | | | | | AN-9 | APp-1 |
| 2-61 | OC-25 | D-2:D-20 | OC-107 | OC-25 | D-1:D-20 | OC-105 | DMp-2: | ACp-3 |
| | | | | | | | AC-8 | |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-56 | Vacuum | Vacuum | 100 | 100 | 100 | 100 | Comp. |
| | deposition | deposition | | | | | |
| 2-57 | 1 | Coating | (Unable to produce) | | | | Comp. |
| 2-58 | 1 | Coating | 102 | 99 | 131 | 86 | Inv. |
| 2-59 | 1 | Coating | 102 | 93 | 126 | 80 | Inv. |
| 2-60 | 1 | Coating | 106 | 91 | 137 | 81 | Inv. |
| 2-61 | 1 | Coating | 103 | 98 | 135 | 83 | Inv. |

*1: Driving voltage V,
*2: Initial luminescence change ΔL,
*3: Voltage increase during driving ΔV
Comp.: Comparative example, Inv.: Present invention

TABLE 14

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-62 | OC-15 | D-1:D-20 | OC-107 | OC-15 | D-1:D-20 | BCP | BCP:Li | m-MTDATA: |
| | | | | | | | | F4TCNQ |
| 2-63 | OC-15 | D-1:D-20 | OC-107 | OC-15 | D-1:D-20 | OC-105 | BCP:Li | m-MTDATA: |
| | | | | | | | | F4TCNQ |
| 2-64 | OC-15 | D-1:D-20 | OC-107 | OC-15 | D-1:D-20 | OC-105 | DAp-1: | ACp-3 |
| | | | | | | | AOp-1 | |
| 2-65 | OC-15 | D-1:D-20 | OC-107 | OC-15 | D-1:D-20 | OC-105 | DDp-3: | DBp-1: |
| | | | | | | | AOp-2 | AIp-3 |
| 2-66 | OC-15 | D-1:D-20 | OC-107 | OC-15 | D-1:D-20 | OC-105 | DAm-1: | DAmp-1: |
| | | | | | | | AOp-3 | Acp-1 |
| 2-67 | OC-15 | D-1:D-20 | OC-107 | OC-15 | D-1:D-20 | OC-105 | DE-6: | DFp-1: |
| | | | | | | | AOp-2 | AG-6 |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-62 | Vacuum | Vacuum | 100 | 100 | 100 | 100 | Comp. |
| | deposition | deposition | | | | | |
| 2-63 | 1 | Coating | (Unable to produce) | | | | Comp. |
| 2-64 | 1 | Coating | 102 | 91 | 139 | 87 | Inv. |
| 2-65 | 1 | Coating | 106 | 92 | 130 | 83 | Inv. |
| 2-66 | 1 | Coating | 104 | 98 | 133 | 85 | Inv. |
| 2-67 | 1 | Coating | 104 | 88 | 132 | 87 | Inv. |

*1: Driving voltage V,
*2: Initial luminescence change ΔL,
*3: Voltage increase during driving ΔV
Comp.: Comparative example, Inv.: Present invention

TABLE 15

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-68 | OC-25 | D-1:D-20 | OC-107 | OC-25 | D-2:D-20 | OC-105 | BCP:Li | m-MTDATA: |
| | | | | | | | | F4TCNQ |
| 2-69 | OC-25 | D-1:D-20 | OC-107 | OC-25 | D-2:D-20 | OC-105 | BCP:Li | m-MTDATA: |
| | | | | | | | | F4TCNQ |
| 2-70 | OC-25 | D-1:D-20 | OC-107 | OC-25 | D-2:D-20 | OC-105 | DBp-1: | DAp-1: |
| | | | | | | | AGp-2 | AOp-2 |
| 2-71 | OC-25 | D-1:D-20 | OC-107 | OC-25 | D-2:D-20 | OC-105 | DEp-1: | DCp-1: |
| | | | | | | | AGp-2 | APp-1 |
| 2-72 | OC-25 | D-1:D-20 | OC-107 | OC-25 | D-2:D-20 | OC-105 | DN-1: | DMp-1: |
| | | | | | | | AGp-4 | ACp-3 |
| 2-73 | OC-25 | D-1:D-20 | OC-107 | OC-25 | D-2:D-20 | OC-105 | DD-2: | ACp-3 |
| | | | | | | | AGp-4 | |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-68 | Vacuum | Vacuum | 100 | 100 | 100 | 100 | Comp. |
| | deposition | deposition | | | | | |
| 2-69 | 1 | Coating | (Unable to produce) | | | | Comp. |
| 2-70 | 1 | Coating | 105 | 92 | 134 | 86 | Inv. |
| 2-71 | 1 | Coating | 102 | 88 | 136 | 90 | Inv. |
| 2-72 | 1 | Coating | 103 | 93 | 135 | 86 | Inv. |
| 2-73 | 1 | Coating | 102 | 99 | 128 | 83 | Inv. |

*1: Driving voltage V,
*2: Initial luminescence change ΔL,
*3: Voltage increase during driving ΔV
Comp.: Comparative example, Inv.: Present invention

TABLE 16

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-74 | OC-36 | D-1:D-20 | OC-107 | OC-25 | D-1:D-20 | OC-105 | BCP:Li | m-MTDATA: |
| | | | | | | | | F4TCNQ |
| 2-75 | OC-36 | D-1:D-20 | OC-107 | OC-25 | D-1:D-20 | OC-105 | BCP:Li | m-MTDATA: |
| | | | | | | | | F4TCNQ |
| 2-76 | OC-36 | D-1:D-20 | OC-107 | OC-25 | D-1:D-20 | OC-105 | DAmp-3: | DMp-1: |
| | | | | | | | AIp-1 | AIp-3 |
| 2-77 | OC-36 | D-1:D-20 | OC-107 | OC-25 | D-1:D-20 | OC-105 | DCp-6: | DAm-1: |
| | | | | | | | AIp-2 | AGp-2 |
| 2-78 | OC-36 | D-1:D-20 | OC-107 | OC-25 | D-1:D-20 | OC-105 | DC-7: | DBp-1: |
| | | | | | | | AIp-3 | AOp-1 |
| 2-79 | OC-36 | D-1:D-20 | OC-107 | OC-25 | D-1:D-20 | OC-105 | DB-13: | ACp-3 |
| | | | | | | | AIp-3 | |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-74 | Vacuum | Vacuum | 100 | 100 | 100 | 100 | Comp. |
| | deposition | deposition | | | | | |
| 2-75 | 1 | Coating | (Unable to produce) | | | | Comp. |
| 2-76 | 1 | Coating | 103 | 94 | 137 | 86 | Inv. |
| 2-77 | 1 | Coating | 102 | 94 | 126 | 87 | Inv. |
| 2-78 | 1 | Coating | 102 | 95 | 137 | 81 | Inv. |
| 2-79 | 1 | Coating | 103 | 89 | 121 | 80 | Inv. |

*1: Driving voltage V,
*2: Initial luminescence change ΔL,
*3: Voltage increase during driving ΔV
Comp.: Comparative example, Inv.: Present invention

TABLE 17

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-80 | OC-25 | D-1:D-20 | OC-107 | OC-25 | D-1:D-20 | OC-17 | BCP:Li | m-MTDATA: |
| | | | | | | | | F4TCNQ |
| 2-81 | OC-25 | D-1:D-20 | OC-107 | OC-25 | D-1:D-20 | OC-17 | BCP:Li | m-MTDATA: |
| | | | | | | | | F4TCNQ |
| 2-82 | OC-25 | D-1:D-20 | OC-107 | OC-25 | D-1:D-20 | OC-17 | DFp-1: | ACp-3 |
| | | | | | | | AKp-3 | |
| 2-83 | OC-25 | D-1:D-20 | OC-107 | OC-25 | D-1:D-20 | OC-17 | DMp-1: | DFp-1: |
| | | | | | | | AKp-3 | AQ-3 |
| 2-84 | OC-25 | D-1:D-20 | OC-107 | OC-25 | D-1:D-20 | OC-17 | DA-12: | DAp-2: |
| | | | | | | | AKp-3 | ACp-3 |
| 2-85 | OC-25 | D-1:D-20 | OC-107 | OC-25 | D-1:D-20 | OC-17 | DM-1: | DCp-1: |
| | | | | | | | AKp-3 | AIp-2 |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-80 | Vacuum | Vacuum | 100 | 100 | 100 | 100 | Comp. |
| | deposition | deposition | | | | | |
| 2-81 | 1 | Coaling | (Unable to produce) | | | | Comp. |
| 2-82 | 1 | Coating | 100 | 99 | 137 | 90 | Inv. |
| 2-83 | 1 | Coating | 102 | 89 | 124 | 80 | Inv. |
| 2-84 | 1 | Coating | 100 | 99 | 134 | 82 | Inv. |
| 2-85 | 1 | Coating | 103 | 90 | 125 | 88 | Inv. |

*1: Driving voltage V,
*2: Initial luminescence change ΔL,
*3: Voltage increase during driving ΔV
Comp.: Comparative example, Inv.: Present invention

TABLE 18

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-86 | OC-25 | D-1:D-20 | OC-107 | OC-25 | D-1:D-20 | OC-19 | BCP:Li | m-MTDATA: |
| | | | | | | | | F4TCNQ |
| 2-87 | OC-25 | D-1:D-20 | OC-107 | OC-25 | D-1:D-20 | OC-19 | BCP:Li | m-MTDATA: |
| | | | | | | | | F4TCNQ |
| 2-88 | OC-25 | D-1:D-20 | OC-107 | OC-25 | D-1:D-20 | OC-19 | DAp-1: | DFp-1: |
| | | | | | | | ALp-4 | AIp-2 |
| 2-89 | OC-25 | D-1:D-20 | OC-107 | OC-25 | D-1:D-20 | OC-19 | DDp-3: | ACp-3 |
| | | | | | | | ALp-4 | |
| 2-90 | OC-25 | D-1:D-20 | OC-107 | OC-25 | D-1:D-20 | OC-19 | DAm-1: | DAp-2: |
| | | | | | | | ALp-7 | AGp-2 |
| 2-91 | OC-25 | D-1:D-20 | OC-107 | OC-25 | D-1:D-20 | OC-19 | DF-9: | DCp-1: |
| | | | | | | | ALp-7 | AOp-2 |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-86 | Vacuum | Vacuum | 100 | 100 | 100 | 100 | Comp. |
| | deposition | deposition | | | | | |
| 2-87 | 1 | Coating | (Unable to produce) | | | | Comp. |
| 2-88 | 1 | Coating | 104 | 99 | 120 | 88 | Inv. |
| 2-89 | 1 | Coating | 403 | 94 | 127 | 83 | Inv. |
| 2-90 | 1 | Coating | 101 | 90 | 130 | 86 | Inv. |
| 2-91 | 1 | Coating | 103 | 100 | 128 | 88 | Inv. |

*1: Driving voltage V,
*2: Initial luminescence change ΔL,
*3: Voltage increase during driving ΔV
Comp.: Comparative example, Inv.: Present invention

TABLE 19

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-92 | OC-25 | D-1:D-20 | OC-107 | OC-30 | D-1:D-20 | OC-105 | BCP:Li | M-MTDATA: |
| | | | | | | | | F4TCNQ |
| 2-93 | OC-25 | D-1:D-20 | OC-107 | OC-30 | D-1:D-20 | OC-105 | BCP:Li | M-MTDATA: |
| | | | | | | | | F4TCNQ |
| 2-94 | OC-25 | D-1:D-20 | OC-107 | OC-30 | D-1:D-20 | OC-105 | Dnp-1: | Dmp-1: |
| | | | | | | | Amp-2 | AQ-3 |
| 2-95 | OC-25 | D-1:D-20 | OC-107 | OC-30 | D-1:D-20 | OC-105 | Dbp-1: | Dbp-1: |
| | | | | | | | Amp-2 | Aip-2 |
| 2-96 | OC-25 | D-1:D-20 | OC-107 | OC-30 | D-1:D-20 | OC-105 | DE-6: | Acp-3 |
| | | | | | | | Amp-3 | |
| 2-97 | OC-25 | D-1:D-20 | OC-107 | OC-30 | D-1:D-20 | OC-105 | DN-1: | Damp-1: |
| | | | | | | | Amp-2 | Acp-3 |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-92 | Vacuum | Vacuum | 100 | 100 | 100 | 100 | Comp. |
| | deposition | deposition | | | | | |
| 2-93 | 1 | Coating | (Unable to produce) | | | | Comp. |
| 2-94 | 1 | Coating | 102 | 98 | 126 | 85 | Inv. |
| 2-95 | 1 | Coating | 104 | 87 | 130 | 86 | Inv. |
| 2-96 | 1 | Coating | 103 | 99 | 134 | 89 | Inv. |
| 2-97 | 1 | Coating | 101 | 100 | 132 | 82 | Inv. |

*1: Driving voltage V,
*2: Initial luminescence change ΔL,
*3: Voltage increase during driving ΔV
Comp.: Comparative example, Inv.: Present invention

TABLE 20

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-98 | OC-22 | D-1:D-20 | OC-107 | OC-22 | D-1:D-20 | OC-105 | BCP:Li | m-MTDATA: |
| | | | | | | | | F4TCNQ |
| 2-99 | OC-22 | D-1:D-20 | OC-107 | OC-22 | D-1:D-20 | OC-105 | BCP:Li | m-MTDATA: |
| | | | | | | | | F4TCNQ |
| 2-100 | OC-22 | D-1:D-20 | OC-107 | OC-22 | D-1:D-20 | OC-105 | DEp-1: | DFp-1: |
| | | | | | | | ANp-2 | AHp-2 |
| 2-101 | OC-22 | D-1:D-20 | OC-107 | OC-22 | D-1:D-20 | OC-105 | DAmp-3: | DAp-2: |
| | | | | | | | ANp-2 | AOp-2 |
| 2-102 | OC-22 | D-1:D-20 | OC-107 | OC-22 | D-1:D-20 | OC-105 | DD-2: | DCp-2: |
| | | | | | | | ANp-3 | AQ-3 |
| 2-103 | OC-22 | D-1:D-20 | OC-107 | OC-22 | D-1:D-20 | OC-105 | DC-7: | ACp-3 |
| | | | | | | | ANp-3 | |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-98 | Vacuum | Vacuum | 100 | 100 | 100 | 100 | Comp. |
| | deposition | deposition | | | | | |
| 2-99 | 1 | Coating | (Unable to produce) | | | | Comp. |
| 2-100 | 1 | Coating | 103 | 88 | 120 | 82 | Inv. |
| 2-101 | 1 | Coating | 104 | 98 | 122 | 82 | Inv. |
| 2-102 | 1 | Coating | 103 | 87 | 125 | 89 | Inv. |
| 2-103 | 1 | Coating | 102 | 100 | 134 | 84 | Inv. |

*1: Driving voltage V,
*2: Initial luminescence change ΔL,
*3: Voltage increase during driving ΔV
Comp.: Comparative example, Inv.: Present invention

TABLE 21

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-104 | OC-36 | D-1:D-20 | OC-107 | OC-36 | D-1:D-20 | OC-105 | BCP:Li | m-MTDATA: |
| | | | | | | | | F4TCNQ |
| 2-105 | OC-36 | D-1:D-20 | OC-107 | OC-36 | D-1:D-20 | OC-105 | BCP:Li | m-MTDATA: |
| | | | | | | | | F4TCNQ |
| 2-106 | OC-36 | D-1:D-20 | OC-107 | OC-36 | D-1:D-20 | OC-105 | DCp-6: | AC-8 |
| | | | | | | | APp-2 | |
| 2-107 | OC-36 | D-1:D-20 | OC-107 | OC-36 | D-1:D-20 | OC-105 | DFp-1: | DM-2: |
| | | | | | | | APp-2 | AC-7 |
| 2-108 | OC-36 | D-1:D-20 | OC-107 | OC-36 | D-1:D-20 | OC-105 | DB-1: | DAm-1: |
| | | | | | | | APp-1 | AI-6 |
| 2-109 | OC-36 | D-1:D-20 | OC-107 | OC-36 | D-1:D-20 | OC-105 | DA-12: | DB-1: |
| | | | | | | | APp-1 | AG-6 |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-104 | Vacuum | Vacuum | 100 | 100 | 100 | 100 | Comp. |
| | deposition | deposition | | | | | |
| 2-105 | 1 | Coating | (Unable to produce) | | | | Comp. |
| 2-106 | 1 | Coating | 104 | 88 | 132 | 82 | Inv. |
| 2-107 | 1 | Coating | 103 | 96 | 121 | 83 | Inv. |
| 2-108 | 1 | Coating | 104 | 87 | 126 | 87 | Inv. |
| 2-109 | 1 | Coating | 103 | 88 | 138 | 88 | Inv. |

*1: Driving voltage V,
*2: Initial luminescence change ΔL,
*3: Voltage increase during driving ΔV
Comp.: Comparative example, Inv.: Present invention

TABLE 22

| | First unit | | | Second unit | | | Charge generating | |
|---|---|---|---|---|---|---|---|---|
| | Light emitting layer | | | Light emitting layer | | | layer | |
| Organic | Light | Light | Electron | Light | Light | Electron | n-type | p-type |
| EL | emitting | emitting | transport | emitting | emitting | transport | layer | layer |
| element | host | dopant | layer | host | dopant | layer | (CGL) | (CGL) |
| 2-110 | OC-16 | D-1:D-20 | OC-107 | OC-16 | D-1:D-20 | OC-105 | BCP:Li | m-MTDATA: |
| | | | | | | | | F4TCNQ |
| 2-111 | OC-16 | D-1:D-20 | OC-107 | OC-16 | D-1:D-20 | OC-105 | BCP:Li | m-MTDATA: |
| | | | | | | | | F4TCNQ |
| 2-112 | OC-16 | D-1:D-20 | OC-107 | OC-16 | D-1:D-20 | OC-105 | DDp-1: | Damp-2: |
| | | | | | | | NCp-2 | AG-6 |
| 2-113 | OC-16 | D-1:D-20 | OC-107 | OC-16 | D-1:D-20 | OC-105 | DAmp-4: | DFp-9: |
| | | | | | | | NCp-5 | ACp-3 |
| 2-114 | OC-16 | D-1:D-20 | OC-107 | OC-16 | D-1:D-20 | OC-105 | DA-12: | DAp-2: |
| | | | | | | | NCp-4 | ACp-3 |
| 2-115 | OC-16 | D-1:D-20 | OC-107 | OC-16 | D-1:D-20 | OC-105 | DDp-3: | ACp-3 |
| | | | | | | | NCp-2 | |

| Organic | Charge generating | | | | | | |
|---|---|---|---|---|---|---|---|
| EL | layer preparation | Production | | | | | |
| element | method | method | EQE | *1 | *2 | *3 | Remarks |
| 2-110 | Vacuum | Vacuum | 100 | 100 | 100 | 100 | Comp. |
| | deposition | deposition | | | | | |
| 2-111 | 1 | Coating | (Unable to produce) | | | | Comp. |
| 2-112 | 1 | Coating | 104 | 88 | 130 | 80 | Inv. |
| 2-113 | 1 | Coating | 105 | 96 | 121 | 83 | Inv. |
| 2-114 | 1 | Coating | 104 | 93 | 129 | 87 | Inv. |
| 2-115 | 1 | Coating | 104 | 89 | 131 | 90 | Inv. |

*1: Driving voltage V,
*2: Initial luminescence change ΔL,
*3: Voltage increase during driving ΔV
Comp.: Comparative example, Inv.: Present invention

As clearly found by the results shown Table 5 to Table 22, a well known charge generating unit (BCP:Li/m-MTDATa:F4TCNQ) formed with a vacuum deposition method cannot be used for a coating process without change. This is due to the fact that: a metal dope (in this case, Li metal dope) in a wet process is hardly secured its material stability, and there is a problem in laminating with a wet process. However, as clearly found by the results of the present invention shown Table 5 to Table 22, in the present invention, it was found that it can be realized a tandem-type organic EL element having a wet process aptitude and being by no means inferior to the charge generating unit prepared with a dry process. In addition, it was found that improvement in productivity of the element could be achieved.

### DESCRIPTION OF SYMBOLS

1: display
3: pixel
5: scanning line
6: data line
7: electric source line
10: organic EL element
11: switching transistor
12: operating transistor
13: capacitor
A: display section
B: control diction
101: glass substrate
102: ITO transparent electrode
103: dividing wall
104: hole injection layer
105B, 105G and 105R: light emitting layer
207: glass substrate having a transparent electrode
206: organic EL layer
205: cathode
202: glass cover
208: nitrogen gas
209: water catching agent

1. An organic electroluminescent element comprising, between a plurality of light emitting units, one or more charge generating layers which generate a hole and an electron by applying an electric field,
wherein at least one of the charge generating layers is produced by a non-discharge type solution coating process, and the plurality of light emitting units are produced by the non-discharge type solution coating process.

2. The organic electroluminescent element of claim 1,
wherein at least one of the charge generating layers is an inorganic compound layer composed of an inorganic compound.

3. The organic electroluminescent element of claim 1,
wherein at least one of the charge generating layers is an organic compound layer composed of an organic compound.

4. The organic electroluminescent element of claim 1,
wherein at least one of the charge generating layers is an inorganic-organic mixed layer composed of an inorganic compound and an organic compound mixed with each other.

5. The organic electroluminescent element, of claim 2,
wherein the inorganic compound layer is composed of a metal, an inorganic oxide, or an inorganic salt.

6. The organic electroluminescent element of claim 2,
wherein the inorganic compound layer is an inorganic oxide film produced by a sol-gel method or a coating method using an inorganic oxide particle dispersion liquid.

7. The organic electroluminescent element of claim 2,
wherein the inorganic compound layer is a metal film produced by a coating method using a metal particle dispersion liquid.

8. The organic electroluminescent element of claim 2,
wherein the inorganic compound layer is treated with at;
least, one of heating, light irradiation, microwave exposure and plasma treatment during or after the coating process.

9. The organic electroluminescent element of claim 2,
wherein the inorganic compound layer contains an inorganic oxide selected from the group consisting of titanium oxide, zirconium oxide, tin oxide, zinc oxide and ITO.

10. The organic electroluminescent element of claim 2,
wherein the inorganic compound layer contains Ag, Al, Cu or Ni.

11. The organic electroluminescent element of claim 3,
wherein the organic compound in the organic compound layer contains an organic salt.

12. The organic electroluminescent element of claim 3,
wherein the organic compound in the organic compound layer contains a metal complex.

13. The organic electroluminescent element of claim 3,
wherein the organic compound in the organic compound layer contains a nano carbon material.

14. The organic electroluminescent element of claim 13,
wherein the nano carbon material is a fullerene derivative or a carbon nano tube derivative.

15. The organic electroluminescent element of claim 3,
wherein the organic compound layer is a donor-acceptor mixed layer containing at least an organic donor compound and an organic acceptor compound mixed with each other.

16. The organic electroluminescent element of claim 15.
wherein the organic donor compound is at least one selected from the group consisting of a phthalocyanine derivative, a porphyrin derivative, a tetrathiafulvalene (TTF) derivative, a tetrathiotetracene (TTT) derivative, a metallocene derivative, thiophene derivative, an imidazole radical derivative, a condensed multi-ring aromatic hydrocarbon, an arylamine derivative, an azine derivative and a transition metal complex salt derivative.

17. The organic electroluminescent element of claim 15,
wherein the organic acceptor compound is at least, one selected from the group consisting of a quinone derivative, a polycyano derivative, a tetracyanoquinodimethane derivative, a dicyanoquinonediimine derivative, a polynitro derivative, a transition metal complex salt derivative, a phenanthroline derivative, an azacarbazole derivative, a quinolinol metal complex derivative, a pyridine derivative, an aromatic heterocyclic derivative, a fullerene derivative, a phthalocyanine derivative, a porphyrin derivative, a fluorinated heterocyclic derivative and a fluorinated aromatic hydrocarbon ring derivative.

18. The organic electroluminescent element of claim 3,
wherein the organic compound layer contains a compound which has an organic donor compound and an organic acceptor compound combine with each other through a covalent bond or a coordination bond,
the organic donor compound is at least one selected from the group consisting of a phthalocyanine derivative a porphyrin derivative, a tetrathiafulvalene (TTF) derivative, tetrathiotetracene (TTT) derivative, a metallocene derivative, a thiophene derivative, an imidazole radical derivative, a condensed multi-ring aromatic hydrocarbon, an arylamine derivative, an azine derivative and a transition metal complex salt derivative, and
the organic acceptor compound is at least one selected from the group consisting of a quinone derivative, a polycyano derivative, a tetracyanoquinodimethane derivative, a dicyanoquinonediimine derivative, a polynitro derivative, a transition metal complex salt derivative, a phenanthroline derivative, an azacarbazole derivative, a quinolinol metal complex derivative, a pyridine derivative, an aromatic heterocyclic derivative, a fullerene derivative, a phthalocyanine derivative, a porphyrin derivative, a fluorinated heterocyclic derivative and a fluorinated aromatic hydrocarbon ring derivative.

19. The organic electroluminescent element of claim 4,
wherein the inorganic compound which composes the organic mixed layer is a metal, an inorganic oxide or an inorganic salt.

20. The organic electroluminescent element of claim 19,
wherein the metal is Ag, Al, Cu or Ni

21. The organic electroluminescent element of claim 19,
wherein the inorganic oxide is titanium oxide, zirconium oxide, tin oxide, zinc oxide or ITO.

22. The organic electroluminescent element, of claim 19,
wherein the inorganic salt is a metal azide compound, an alkali metal salt or an alkali earth metal salt.

23. The organic electroluminescent element of claim 19,
wherein the organic compound which composes the inorganic organic mixed layer is one selected from the group consisting of an organic salt, a metal complex, a nano carbon material, an organic donor compound, an organic acceptor compound and a compound which has the organic donor compound and the organic acceptor compound combined with each other through a covalent bond or a coordination bond.

24. The organic electroluminescent element of claim 4,
wherein the inorganic-organic mixed layer is formed by a coating method using a mixture liquid containing:
at least one selected from the group consisting of a metal particle dispersion liquid, an inorganic oxide particle dispersion liquid, an inorganic oxide sol-gel liquid, an inorganic salt particle dispersion liquid and an inorganic salt solution; and
at least one of an organic compound particle dispersion liquid and an organic compound solution.

25. The organic electroluminescent element of claim 4,
wherein the inorganic-organic mixed layer is treated with at least one of heating, light irradiation, microwave exposure and plasma treatment during or after the coating process.

26. The organic electroluminescent element of claim 1,
wherein the light, emitting units each contain one or more organic electroluminescent, layers, and at least one of the organic electroluminescent layers or at least one of the charge generating layers is composed of a polymer, an organic complex, or an inorganic oxide each having a high degree of covalent bond, hydrogen bond, or coordination bond.

27. The organic electroluminescent element of claim 26,
wherein the high degree of covalent bond, hydrogen bond, or coordination bond in the polymer, the organic complex or the inorganic oxide is formed by carrying out at least one treatment of heating, light irradiation, electromagnetic wave exposure, electric filed application and plasma treatment during or after the coating process of a low molecular weight material to form a high molecular compound.

28. The organic electroluminescent element of claim 26,
wherein, among the one or more organic electroluminescent layers which compose the light emitting units, the organic electroluminescent layer located under the charge generating layer is composed of the polymer, the organic complex, or the inorganic oxide each haring a high degree of covalent bond, hydrogen bond, or coordination bond.

29. The organic electroluminescent element of claim 28,
wherein, among the one or more organic electroluminescent layers which compose the light emitting units, the organic electroluminescent layer located under the charge generating layer is an electron transport layer.

30. The organic electroluminescent element of claim 29,
wherein the electron transport layer is formed by the method comprising the steps of:
forming a layer of an organic compound with a low molecular weight and having a vinyl group, an epoxy group or an oxetane group with a coating process; and
subjecting the formed organic compound layer to at least one treatment of heating, light irradiation, electromagnetic wave exposure, electric filed application and plasma treatment during or after the coating process to form a high molecular compound by forming a covalent bond between molecules of the organic compound with a low molecular weight.

31. The organic electroluminescent element of claim 1,
wherein the light emitting units emit a phosphorescent light.

32. A lighting device comprising the organic electroluminescent element of claim 1.
